(19) United States
(12) Patent Application Publication
(10) Pub. No.: US 2021/0380620 A1
(43) Pub. Date: Dec. 9, 2021

(54) ORGANOMETALLIC COMPOUND AND ORGANIC LIGHT-EMITTING DEVICE INCLUDING THE SAME

(71) Applicants: Samsung Electronics Co., Ltd., Suwon-si (KR); Kwangwoon University Industry-Academic Collaboration Foundation, Seoul (KR)

(72) Inventors: Sangmo KIM, Hwaseong-si (KR); Minsik MIN, Suwon-si (KR); Hyejin BAE, Suwon-si (KR); Jhunmo SON, Yongin-si (KR); Sangback LEE, Seoul (KR); Sanghyun LEE, Seoul (KR); Yunmi LEE, Seoul (KR); Yongsik Jung, Seoul (KR); Wataru SOTOYAMA, Kanagawa-ken (JP); Youngmok SON, Hwaseong-si (KR); Jun CHWAE, Seoul (KR)

(21) Appl. No.: 17/115,865

(22) Filed: Dec. 9, 2020

(30) Foreign Application Priority Data
Jun. 8, 2020 (KR) 10-2020-0069101

(51) Int. Cl. C07F 15/00; H01L 51/00; C07F 1/12

(52) U.S. Cl. CPC C07F 15/0086; H01L 51/0087; H01L 51/5056; C07F 1/12; C07F 15/006; H01L 51/0091

(57) ABSTRACT

Provided are an organometallic compound having a novel structure, an organic light-emitting device including the organometallic compound, and a diagnostic composition including the organometallic compound.

### CROSS-REFERENCE TO RELATED APPLICATION

This application claims priority to and the benefit of Korean Patent Application No. 10-2020-0069101, filed on Jun. 8, 2020, in the Korean Intellectual Property Office, the content of which is incorporated herein in its entirety by reference.

### BACKGROUND

### 1. Field

One or more embodiments relate to an organometallic compound and an organic light-emitting device including the same.

### 2. Description of Related Art

Organic light-emitting devices are self-emission devices, which have improved characteristics in terms of viewing angles, response time, brightness, driving voltage, and response speed, and produce full-color images.

In an example, an organic light-emitting device includes an anode, a cathode, and an organic layer between the anode and the cathode, wherein the organic layer includes an emission layer. A hole transport region may be located between the anode and the emission layer, and an electron transport region may be located between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transition from an excited state to a ground state to thereby generate light.

Meanwhile, luminescent compounds, for example, phosphorescent compounds, may be used for monitoring, sensing, and detecting biological materials such as various cells and proteins.

### SUMMARY

One or more embodiments relate to organometallic compounds, organic light-emitting devices including the same, and diagnostic compositions including the same.

Additional aspects will be set forth in part in the description which follows and, in part, will be apparent from the description, or may be learned by practice of the presented embodiments of the disclosure.

Provided is an organometallic compound represented by Formula 1,

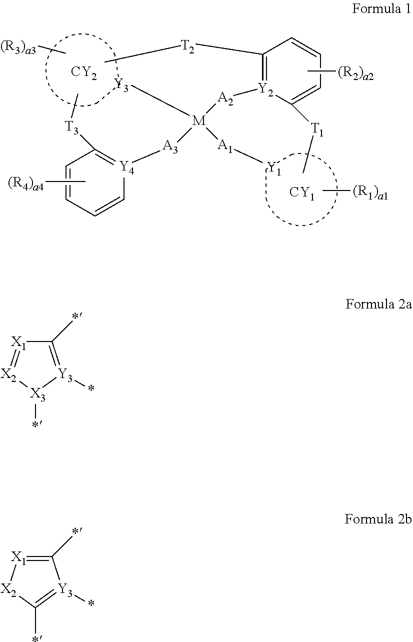

wherein, in Formulae 1, 2a, and 2b,

M is a transition metal,

Y₃ is N, and Y₁, Y₂, and Y₄ are each independently C or N,

ring CY₁ is a C₅-C₃₀ carbocyclic group or a C₁-C₃₀ heterocyclic group,

ring CY₂ is a group represented by Formula 2a or Formula 2b,

X₁, X₂, and X₃ are each independently C or N,

A₁, A₂, and A₃ are each independently a chemical bond, O, S, B(R₅), N(R₅), P(R₅), C(R₅)(R₆), Si(R₅)(R₅), Ge(R₅)(R₅), C(═O), or P(R₅)(R₅), wherein, when A₁ is a chemical bond, Y₁ and M are directly linked to each other, when A₂ is a chemical bond, Y₂ and M is directly linked to each other, and, when A₃ is a chemical bond, Y₄ and M is directly linked to each other,

at least one of A₁, A₂, and A₃ is O,

a bond between Y₃ and M is a coordination bond,

one of a bond between Y₁ or A₁ and M, a bond between Y₂ or A₂ and M, and a bond between Y₄ or A₃ and M is a coordination bond, and the other two bonds are each a covalent bond,

T₁, T₂, and T₃ are each independently a single bond, a double bond, *′—N(R₇)—*″, *′—B(R₇)—*″, *′—P(R₇)—*″, *′—C(R₇)(R₈)—*″, *′—Si(R₇)(R₈)—*″, *′—Ge(R₇)(R₈)—*″, *′—S—*″, *′—Se—*″, *′—O—*″, *′—C(═O)—*″, *′—S(═O)—*″, *′—S(═O)₂—*″, *′—C(R₇)═*″, *′═C(R₇)—*″, *′—C(R₇)═C(R₈)—*″, *′—C(═S)—*″ or *′—C≡C—*″.

R₁ to R₈ are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —B(Q₁)(Q₂), or —P(═O)(Q₁)(Q₂),

a1 is an integer from 0 to 20,

a2 is an integer from 0 to 3,

a3 is an integer from 0 to 3,

a4 is an integer from 0 to 4,

two or more of a plurality of R₁(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

R₁₀ₐ is the same as described in connection with R₁,

an R₁ and a N of ring CY₁ are optionally linked to each other to form a C₁-C₃₀ heterocyclic group that is unsubstituted or substituted with at least one R₁₀ₐ,

two or more of a plurality of R₂(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

two or more of a plurality of R₄(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

at least one of a plurality of R₁, R₂, and R₃ and at least one of a plurality of R₄(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

* indicates a binding site to metal M, and *′ and *″ each indicate a binding site to a neighboring atom,

a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted monovalent non-aromatic condensed polycyclic group, and the substituted monovalent non-aromatic condensed heteropolycyclic group is

deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group,

a C₁-C₆₀ alkyl group, a C₂-C₆₀ alkenyl group, a C₂-C₆₀ alkynyl group, or a C₁-C₆₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), —P(═O)(Q₁₈)(Q₁₉), or any combination thereof,

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group,

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), —P(═O)(Q₂₈)(Q₂₉), or any combination thereof, or

—N(Q₃₁)(Q₃₂), —Si(Q₃₃)(Q₃₄)(Q₃₅), —B(Q₃₆)(Q₃₇), or —P(═O)(Q₃₈)(Q₃₉),

wherein Q₁ to Q₉, Q₁₁ to Q₁₉, Q₂₁ to Q₂₉ and Q₃₁ to Q₃₉ are independently hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group.

According to another aspect, provided is an organic light-emitting device including a first electrode, a second electrode, and an organic layer including an emission layer located between the first electrode and the second electrode, wherein the organic layer includes at least one organometallic compound represented by Formula 1.

The organometallic compound in the organic layer may function as a dopant.

Another aspect provides a diagnostic composition including at least one organometallic compound represented by Formula 1.

### BRIEF DESCRIPTION OF THE DRAWING

The above and other aspects, features, and advantages of certain embodiments of the disclosure will be more apparent from the following description taken in conjunction with the accompanying drawing, in which

FIGURE which shows a schematic cross-sectional view of an organic light-emitting device according to an exemplary embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the FIGURES, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly on the other element or intervening elements may be present therebetween In contrast, when an element is referred to as being “directly on” another element, there are no intervening elements present

It will be understood that, although the terms “first,” “second,” “third” etc. may be used herein to describe various elements, components, regions, layers and/or sections, these elements, components, regions, layers and/or sections should not be limited by these terms These terms are only used to distinguish one element, component, region, layer or section from another element, component, region, layer or section Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise.

“Or” means “and/or.” As used herein, the term “and/or” includes any and all combinations of one or more of the associated listed items It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the FIGURES It will be understood that relative terms are intended to encompass different orientations of the device in addition to the orientation depicted in the FIGURES For example, if the device in one of the FIGURES is turned over, elements described as being on the “lower” side of other elements would then be oriented on “upper” sides of the other elements The exemplary term “lower,” can therefore, encompasses both an orientation of “lower” and “upper,” depending on the particular orientation of the FIGURE Similarly, if the device in one of the FIGURES is turned over, elements described as “below” or “beneath” other elements would then be oriented “above” the other elements The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments As such, variations from the shapes of the illustrations as a result, for example, of manufacturing techniques and/or tolerances, are to be expected Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features Moreover, sharp angles that are illustrated may be rounded Thus, the regions illustrated in the figures are schematic in nature and their shapes are not intended to illustrate the precise shape of a region and are not intended to limit the scope of the present claims.

An aspect of the present disclosure provides an organometallic compound represented by Formula 1 below:

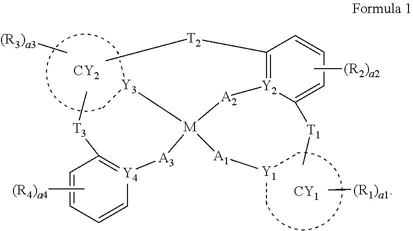

M in Formula 1 may be a transition metal.

For example, M may be a Period 1 transition metal, a Period 2 transition metal, or a Period 3 transition metal.

In an embodiment, M may be Pt, Pd, Au, or Cu, but embodiments of the present disclosure are not limited thereto. For example, M may be Pt.

Regarding Formula 1, Y₃ may be N, and Y₁, Y₂, and Y₄ may each independently be C or N.

In an embodiment, Y₃ may be N, Y₂ and Y₄ may each be C, and Y₁ may be C or N. For example, Y₂ and Y₄ may be C, Y₁ may be C or N, A₁ may be a chemical bond, one of A₂ and A₃ may be O, a bond between Y₂ or A₂ and M and a bond between Y₄ or A₃ and M may each be a covalent bond, and a bond between Y₁ and M may be a coordination bond.

Ring CY₁ in Formula 1 may be a C₅-C₃₀ carbocyclic group or a C₁-C₃₀ heterocyclic group.

In an embodiment, CY₁ may be i) a first ring, ii) a condensed cyclic group in which two or more first rings are condensed with each other, or iii) a condensed cyclic group in which at least one first ring is condensed with at least one second ring,

the first ring may be a cyclopentane group, a cyclopentadiene group, a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a 5-membered cyclic carbene group, a triazole group, a tetrazole group, an azasilole group, a diazasilole group, or a triazasilole group, and

the second ring may be an adamantane group, a norbornane group, a norbornene group, a cyclohexane group, a cyclohexene group, a benzene group, a pyridine group, a pyrimidine group, a pyrazine group, a pyridazine group, a triazine group, an oxazine group, a thiazine group, a dihydropyrazine group, a dihydropyridine group, or a dihydroazasilane group, but embodiments of the present disclosure are not limited thereto.

The term “5-membered cyclic carbene group” is a 5-membered cyclic group in which a carbon atom having two unshared electron pairs is included as a ring-forming atom, and may be represented by, for example, Formula X

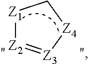

wherein Z₁ to Z₄ may each independently be C or N, and a group represented by Formula X may be substituted with at least one substituent other than hydrogen.

For example, ring CY₁ may be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a 5-membered cyclic carbene group, a benzene-condensed 5-membered cyclic carbene group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, a [1,2,4]triazolo[1,5-a]pyridine, a phenoxazine group, a phenothiazine group, a dihydrophenazine group, a dihydroacridine group, an azaphenoxazine group, an azaphenothiazine group, an azadihydrophenazine group, or an azadihydroacridine group, but embodiments of the present disclosure are not limited thereto.

For example, ring CY₁ may be a thiophene group, a furan group, an indole group, a 5-membered cyclic carbene group, a benzene-condensed 5-membered cyclic carbene group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, or a [1,2,4]triazolo[1,5-a]pyridine.

Regarding Formula 1, ring CY₂ may be a group represented by Formula 2a or Formula 2b, and X₁, X₂, and X₃ may each independently be C or N.

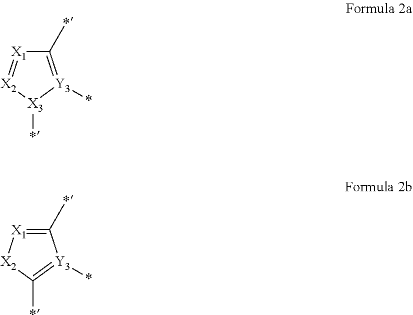

In an embodiment, at least one of X₁, X₂, and X₃ may be N. For example, at least one of X₁ and X₂ may be N.

In an embodiment, ring CY₂ may be a group represented by Formula 2a, and X₁ and X₂ may each independently be C or N, and X₃ may be C or N.

In one or more embodiments, ring CY₂ may be a group represented by Formula 2a, at least one of X₁ and X₂ may be N, and X₃ may be N.

For example, X₁ is N, X₂ is C, and X₃ is C, X₁ is N, X₂ is C, and X₃ is N, X₁ is C, X₂ is N, and X₃ is C, or Xi is C, X₂ is N, and X₃ is N.

In one or more embodiments, ring CY₂ may be a group represented by Formula 2b, and at least one of X₁ may be N and X₂ may be N. For example, X₁ may be N and X₂ may each be N.

A₁, A₂, and A₃ in Formula 1 may each independently be a chemical bond, O, S, B(R₅), N(R₅), P(R₅), C(R₅)(R₆), Si(R₅)(R₆), Ge(R₅)(R₅), C(═O), or P(R₅)(R₅), and at least one of A₁, A₂, and A₃ may be O. In this regard, R₅ and R₆ are the same as described in the present specification.

When A₁ is a chemical bond, Y₁ and M may be directly linked to each other, when A₂ is a chemical bond, Y₂ and M may be directly linked to each other, and when A₃ is a chemical bond, Y₄ and M may be may be directly linked to each other. A bond between Y₃ and M may be a coordination bond.

Regarding Formula 1, one of a bond between Y₁ or A₁ and M, a bond between Y₂ or A₂ and M, and a bond between Y₄ or A₃ and M may be a coordination bond, and the other two bonds may each be a covalent bond.

In an embodiment, one of A₂ and A₃ is O, the other one is a chemical bond, and A₁ may be a chemical bond.

For example, A₃ may be O, and each of A₁ and A₂ may be a chemical bond.

T₁, T₂, and T₃ in Formula 1 may each independently be a single bond, a double bond, *′—N(R₇)—*″, *′—B(R₇)—*″, *′—P(R₇)—*″, *′—C(R₇)(R₈)—*″, *′—Si(R₇)(R₈)—*″, *′—Ge(R₇)(R₈)—*, *′—S—*″, *′—Se—*″, *′—O—*″, *′—C(═O)—*″, *′—S(═O)—*″, *′—S(═O)₂—*″, *′—C(R)=*″, *′=C(R₇)—*″, *′—C(R₇)═C(R₈)—*″, *′—C(═S)—*″, or *′—C≡C—*″.

In one embodiment, T₁, T₂, and T₃ may be a single bond.

R₁ to R₈ in Formula 1 may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —B(Q₁)(Q₂), or —P(═O)(Q₁)(Q₂).

In an embodiment, R₁ to R₈ may each independently be hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, or a C₁-C₂₀ alkoxy group;

a C₁-C₂₀ alkyl group or a C₁-C₂₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof; or

—N(Q₁)(Q₂), —Si(Q₃)(Q₄)(Q₅), —B(Q₆)(Q₇), or —P(═O)(Q₈)(Q₉),

wherein Q₁ to Q₉ are each independently:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CH₃, —CD₂CD₃, —CD₂CD₂H, or —CD₂CDH₂;

an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group; or

an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group, each substituted with at least one deuterium, a C₁ to C₁₀ alkyl group, a phenyl group, or any combination thereof.

a1 in Formula 1 indicates the number of R₁(s), and may be an integer from 0 to 20. For example, a1 may be 1 or 2, but embodiments of the present disclosure are not limited thereto. When a1 is 2 or more, two or more of R₁(s) may be identical to or different from each other.

a2 and a3 in Formula 1 indicate the number of R₂(s) and the number of R₃(s), respectively, and may each independently be an integer from 0 to 3. When a2 is 2 or more, two or more of R₂(s) may be identical to or different from each other, and when a3 is 2 or more, two or more R₃(s) may be identical to or different from each other.

a4 in Formula 1 indicates the number of R₄(s), and may be an integer from 0 to 4. When a4 is 2 or more, two or more of R₄(s) may be identical to or different from each other.

Regarding Formula 1, at least one of R₁(s) in the number of a1 and R₃(s) in the number of a3 may each independently be a substituted or unsubstituted C₁-C₆₀ alkyl group or a substituted or unsubstituted C₆-C₃₀ aryl group.

In an embodiment, at least one of R₁(s) in the number of a1 and R₃(s) in the number of a3 in Formula 1 may each independently be a C₁-C₂₀ alkyl group or a C₈-C₃₀ aryl group, each unsubstituted or substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₁₀ alkyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof.

In one or more embodiments, at least one of R₁(s) in the number of a1 and R₃(s) in the number of a3 in Formula 1 may each independently be deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an isopropyl group, an n-butyl group, a sec-butyl group, an isobutyl group, a tert-butyl group, an n-pentyl group, a tert-pentyl group, neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each unsubstituted or substituted with at least one of a methyl group, an ethyl group, an n-propyl group, an isopropyl group, an n-butyl group, a sec-butyl group, an isobutyl group, a tert-butyl group, an n-pentyl group, a tert-pentyl group, neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, but embodiments of the present disclosure are not limited thereto.

In one or more embodiments, at least one of R₁(s) in the number of a1 and R₃(s) in the number of a3 in Formula 1 may each independently be hydrogen, deuterium, —F, a cyano group, a nitro group, —SF₅, —CH₃, —CD₃, —CD₂H, —CDH₂, —CF₃, —CF₂H, —CFH₂, a group represented by one of Formulae 9-1 to 9-66, a group represented by one of Formulae 9-1 to 9-66 in which at least one hydrogen is substituted with deuterium, a group represented by one of Formulae 10-1 to 10-249, a group represented by one of Formulae 10-1 to 10-249 in which at least one hydrogen is substituted with deuterium, —N(Q₁)(Q₂), or —Si(Q₃)(Q₄)(Q₅)(Q₁ to Q₅ are the same as described in the present specification):

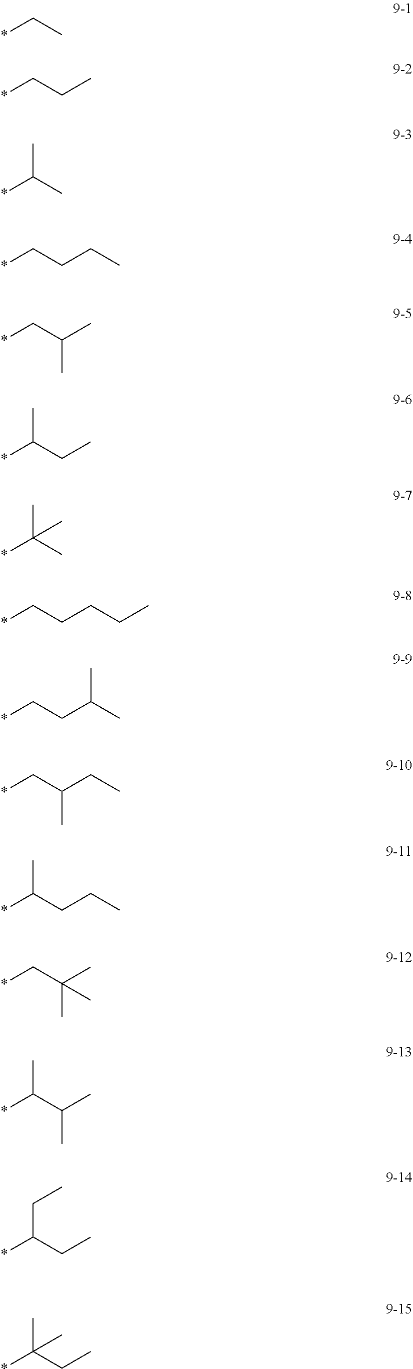

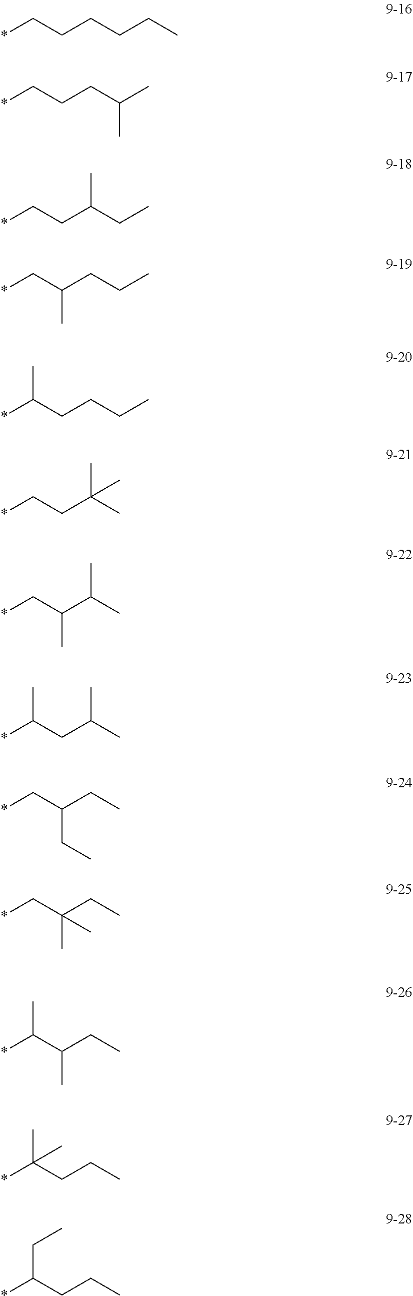

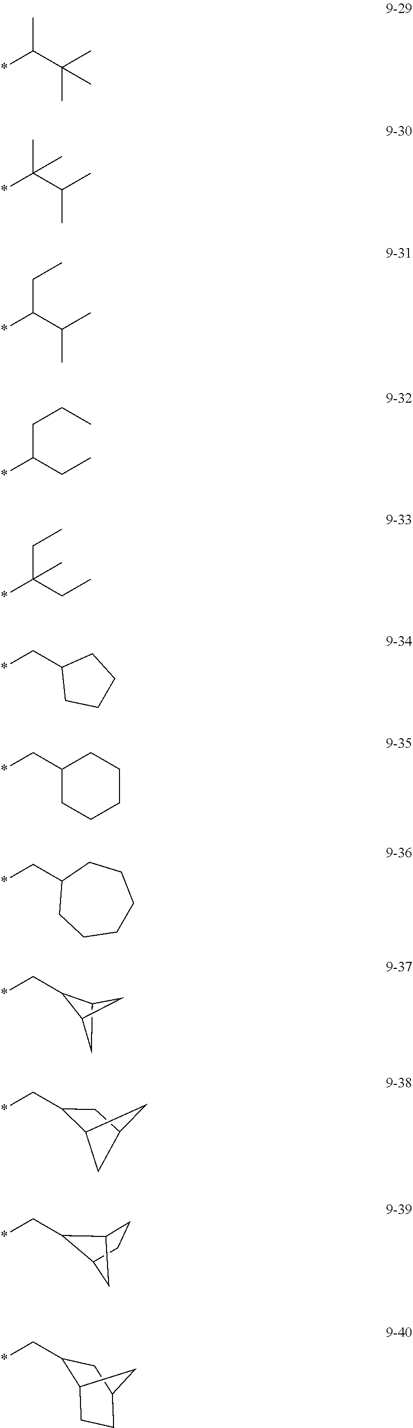

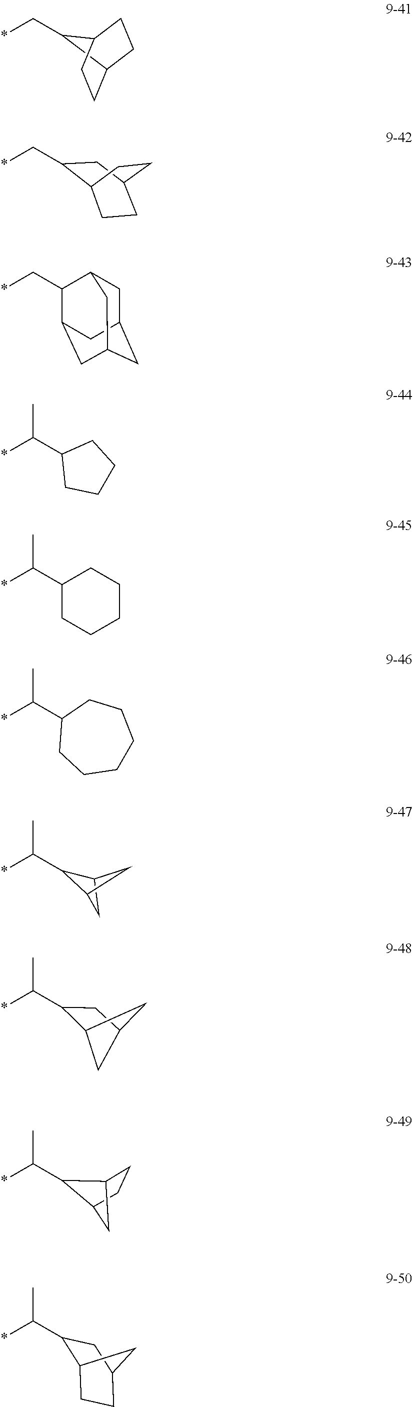

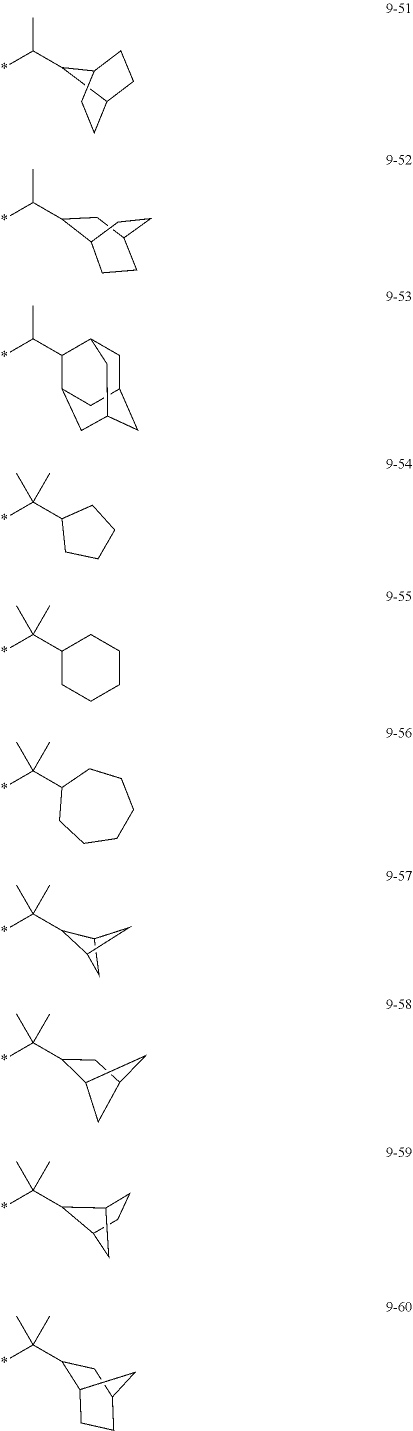

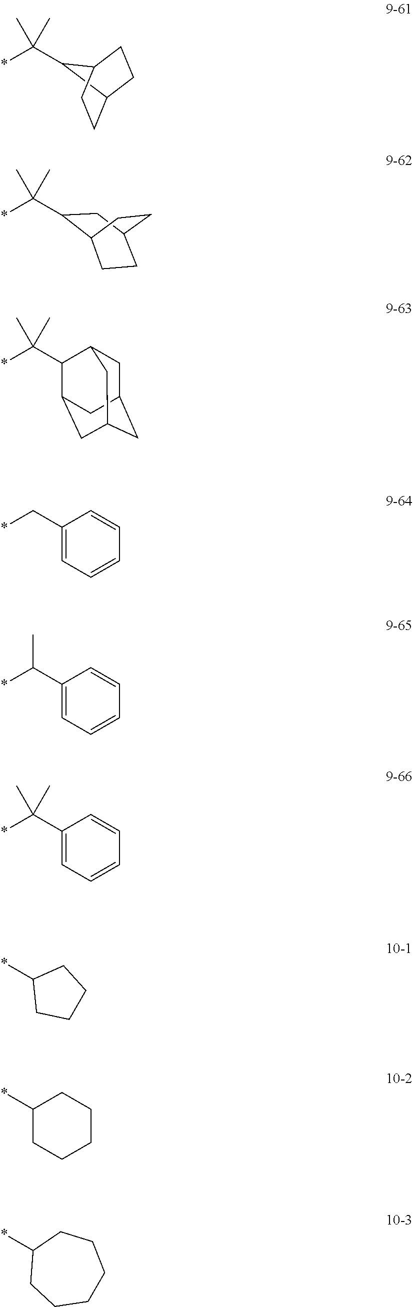

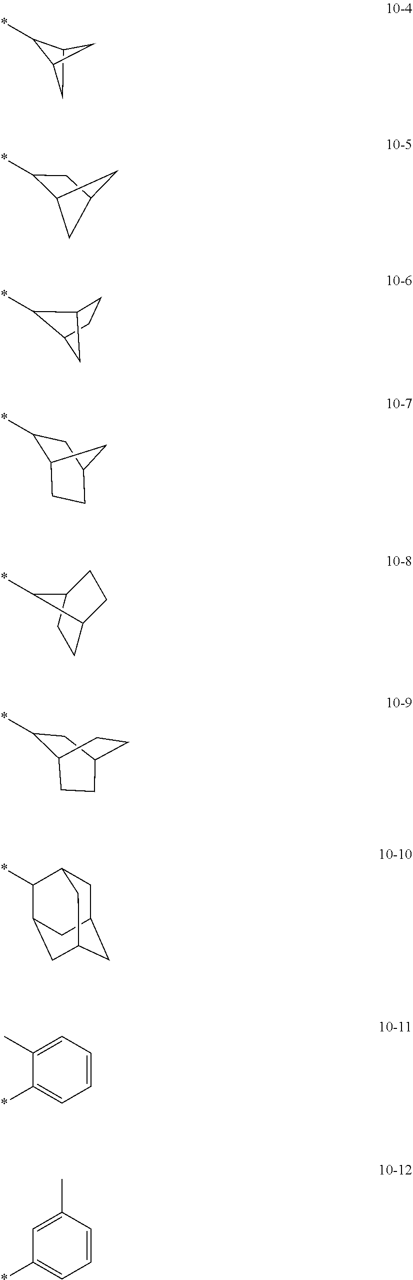

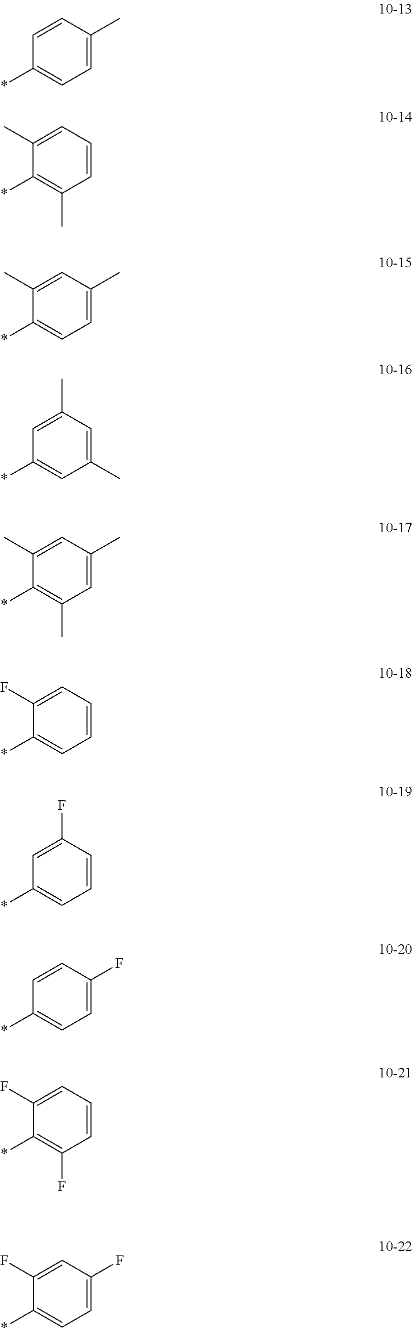

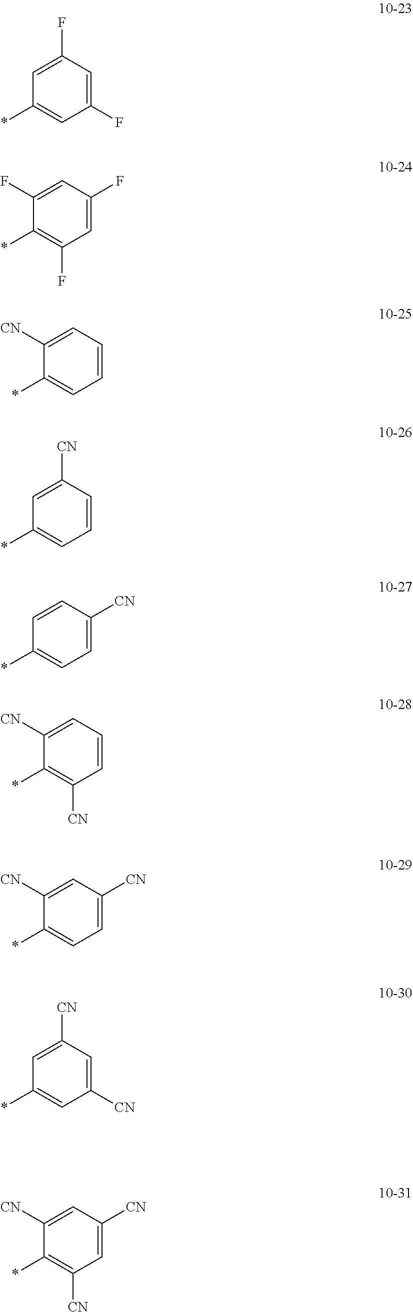

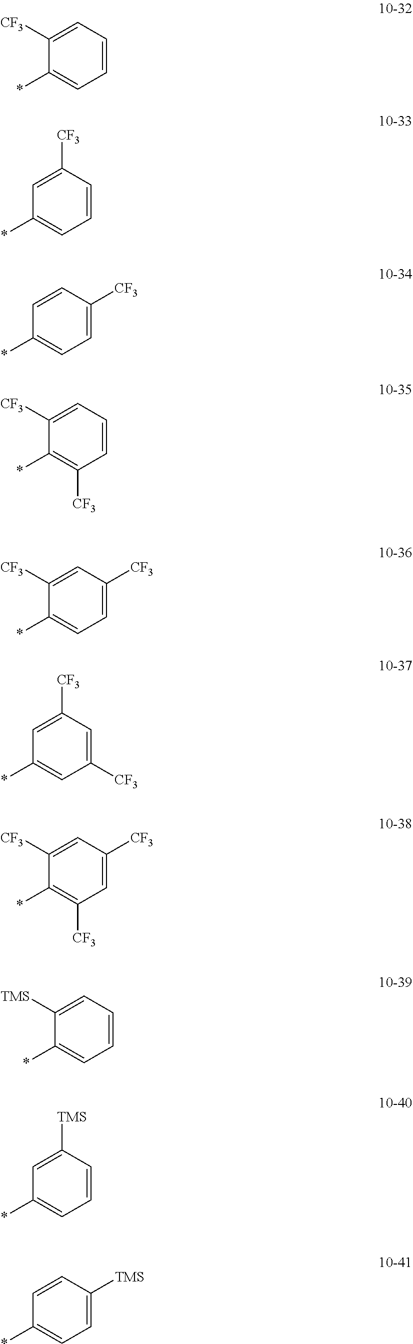

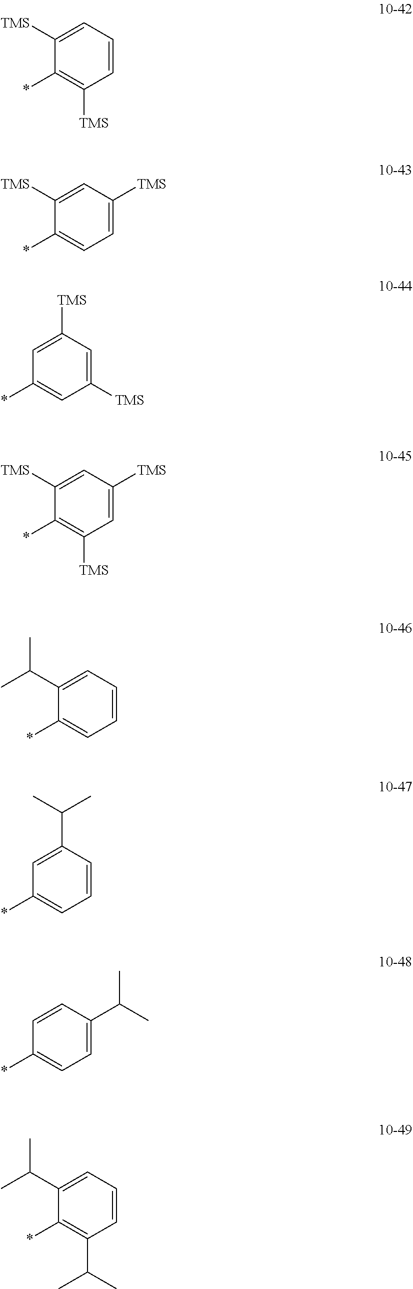

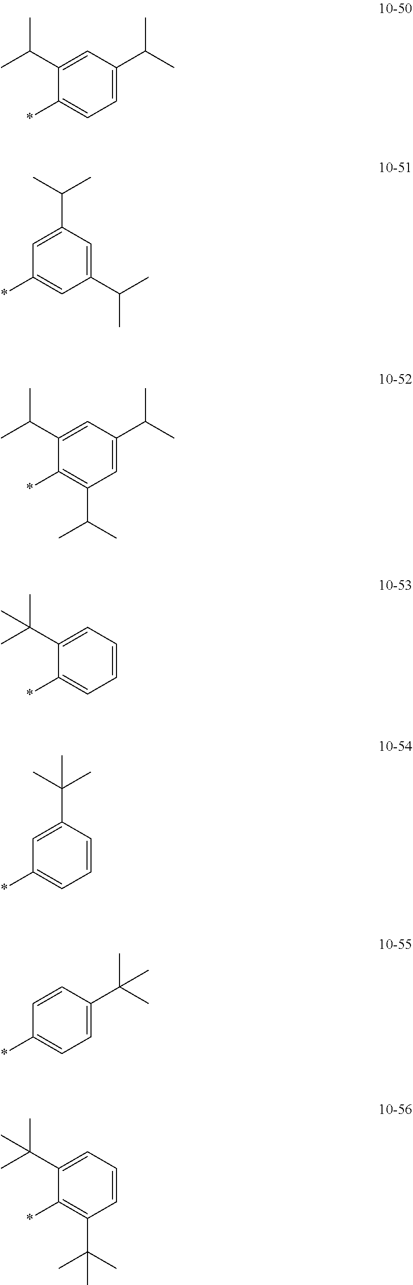

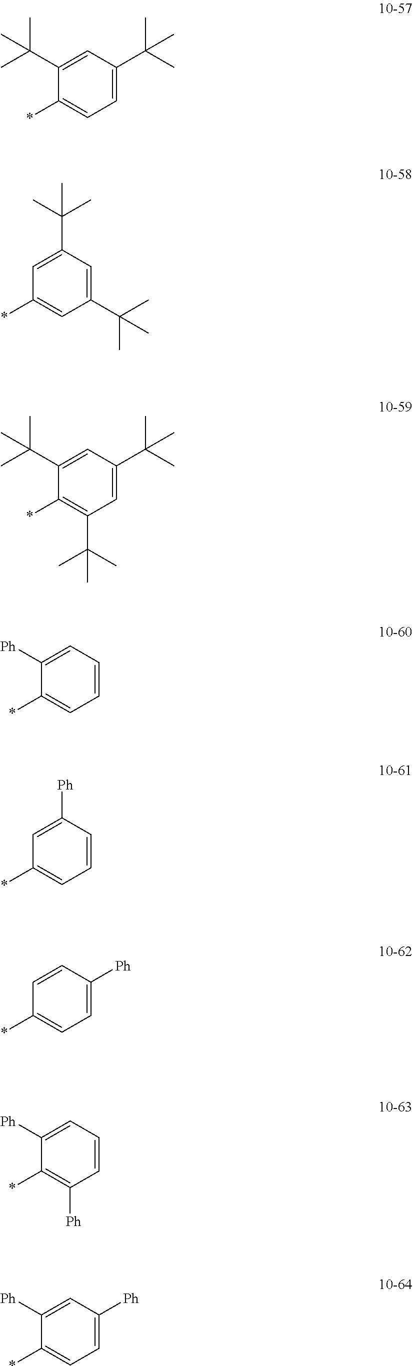

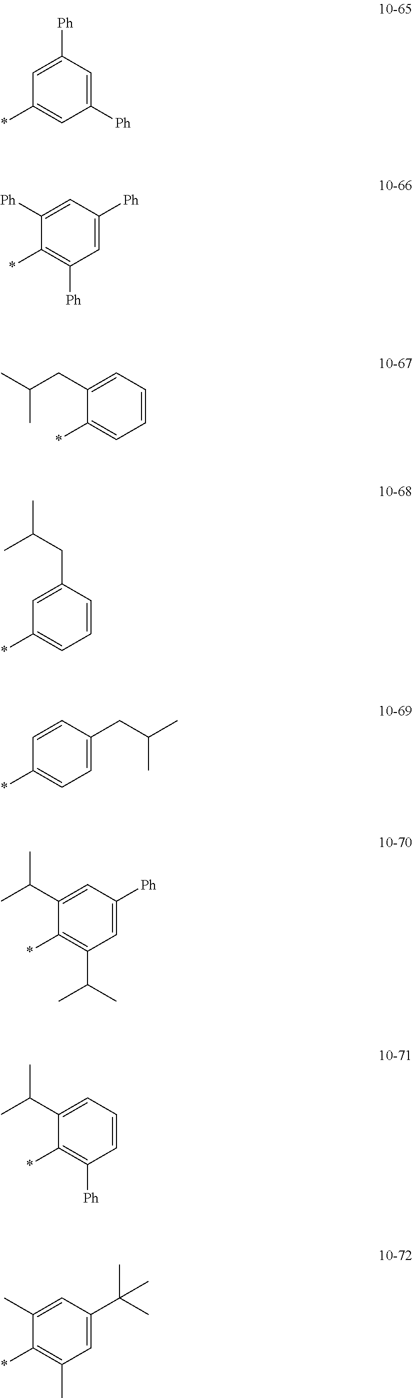

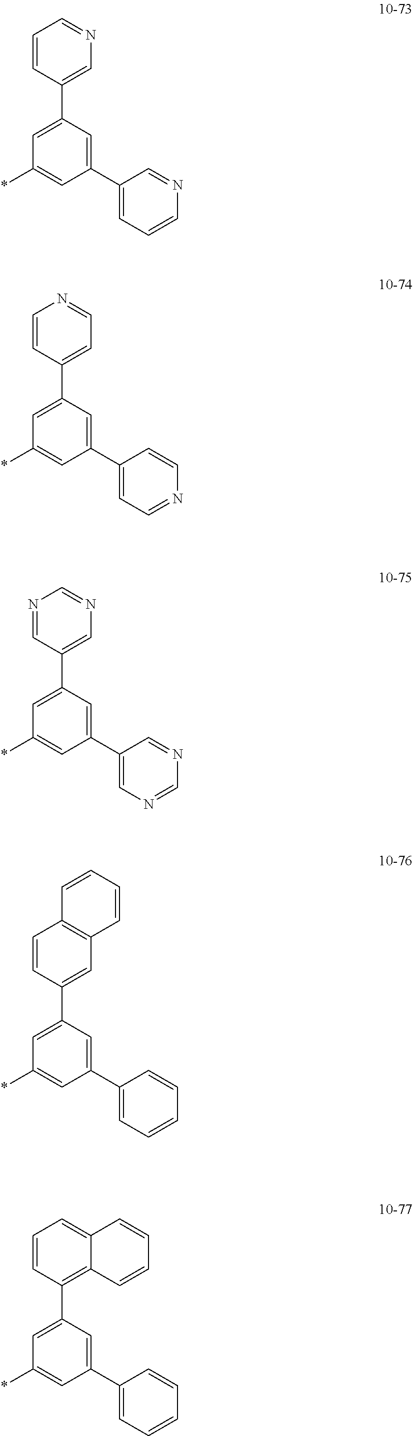

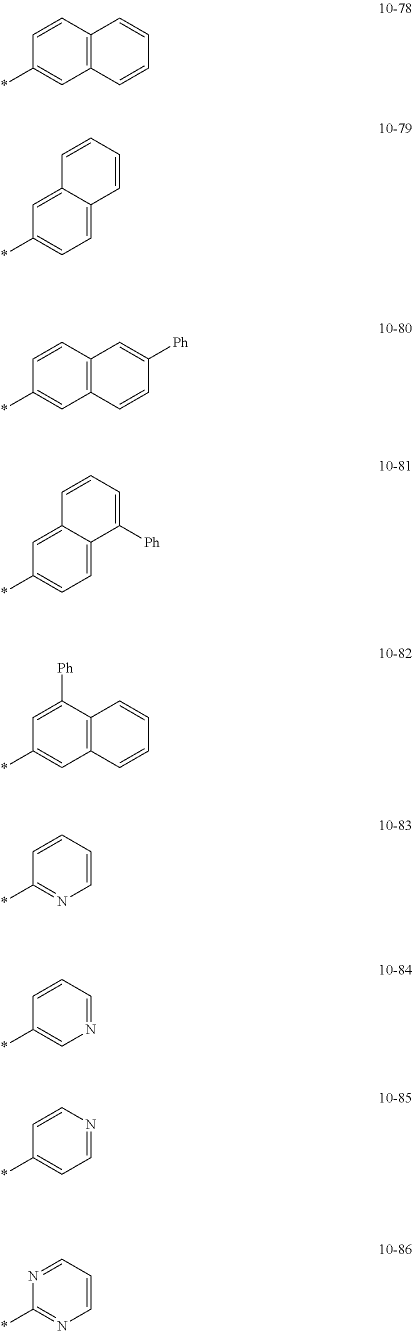

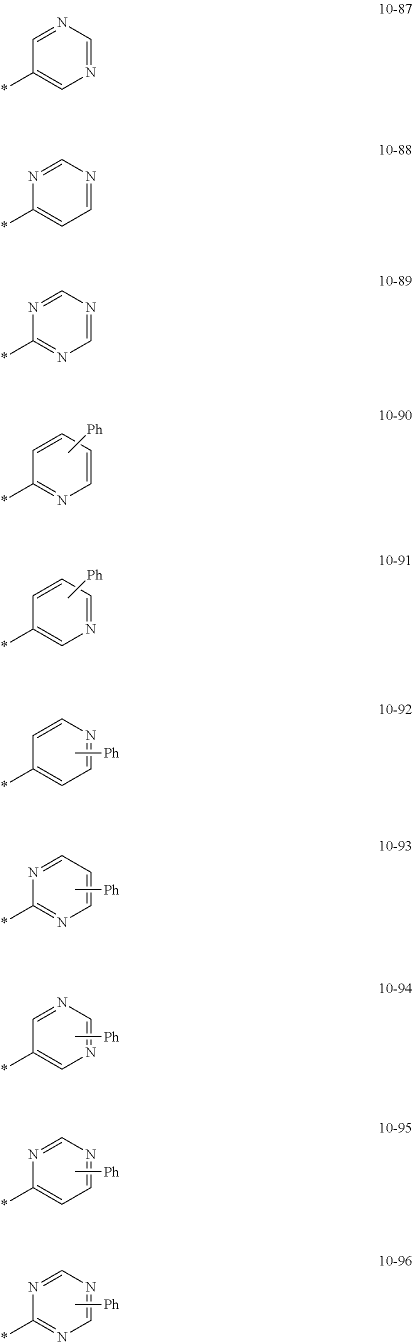

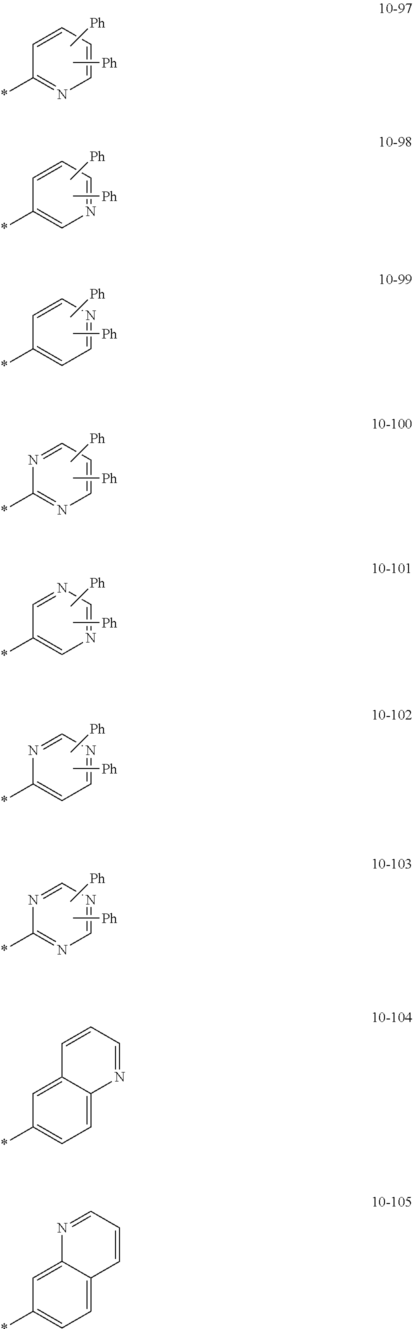

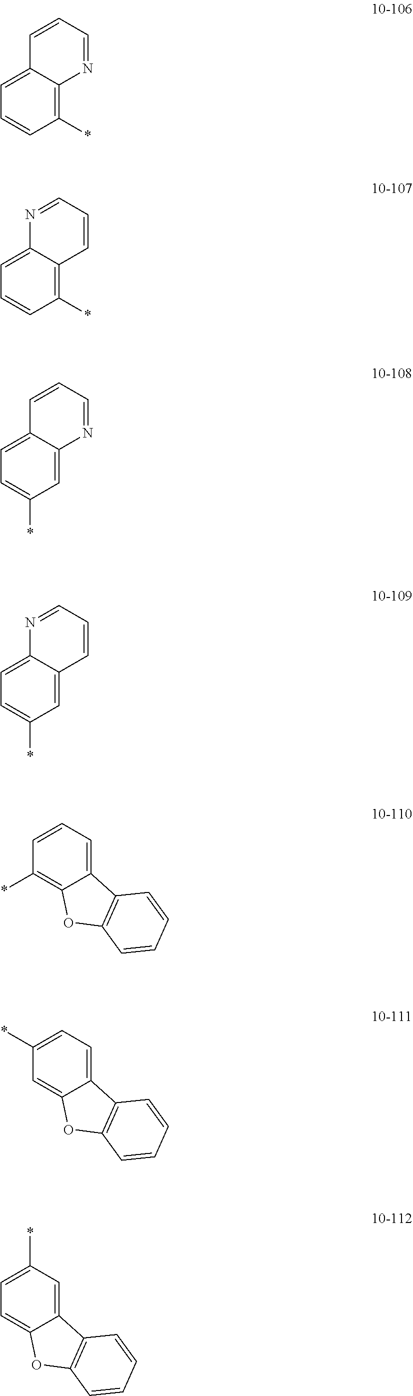

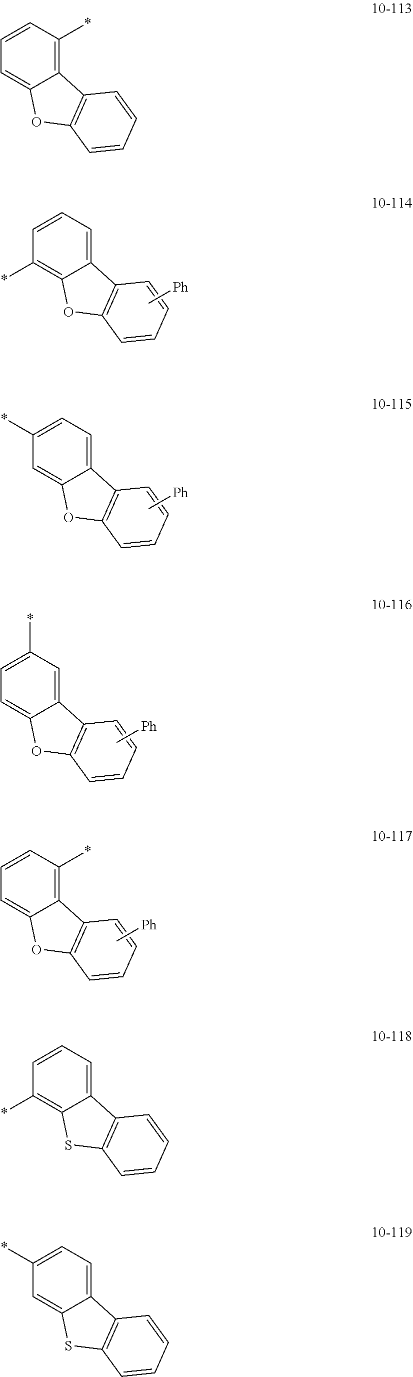

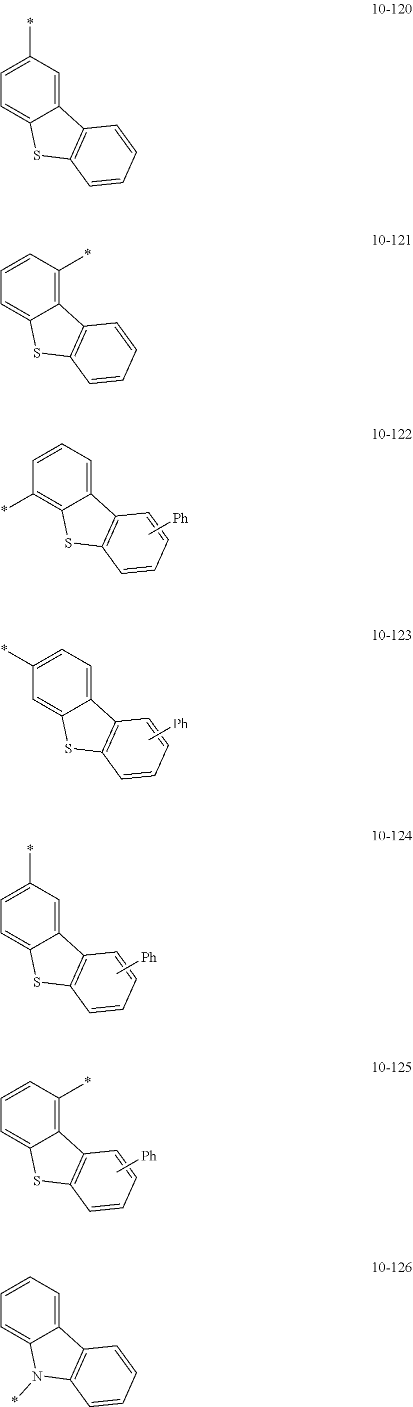

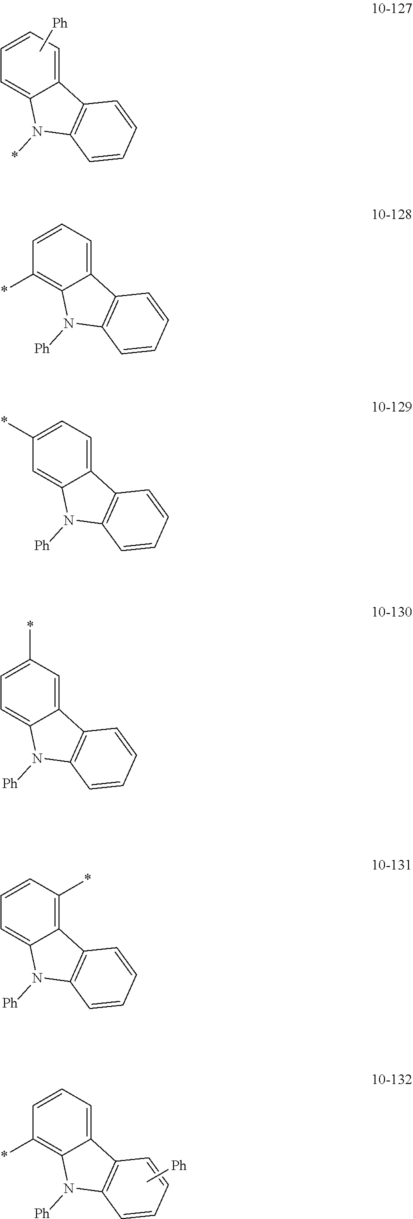

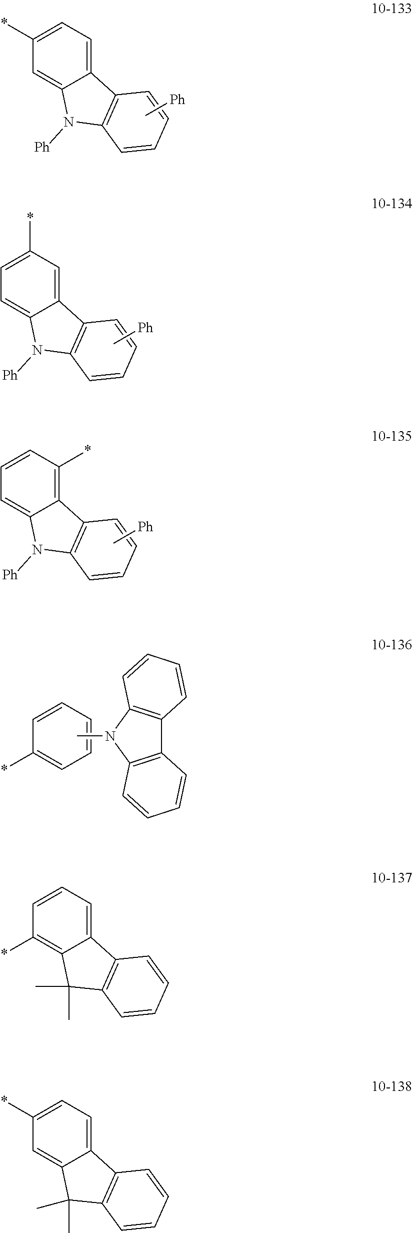

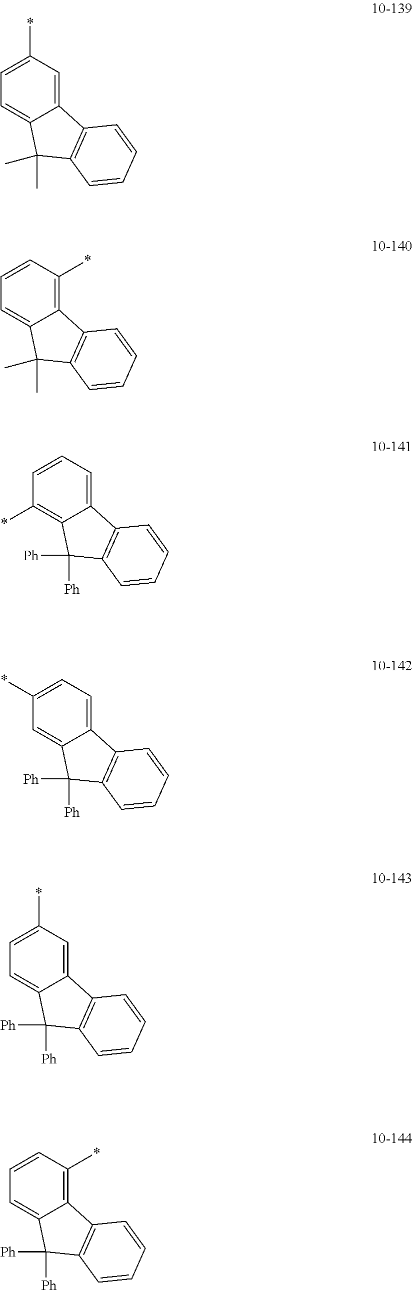

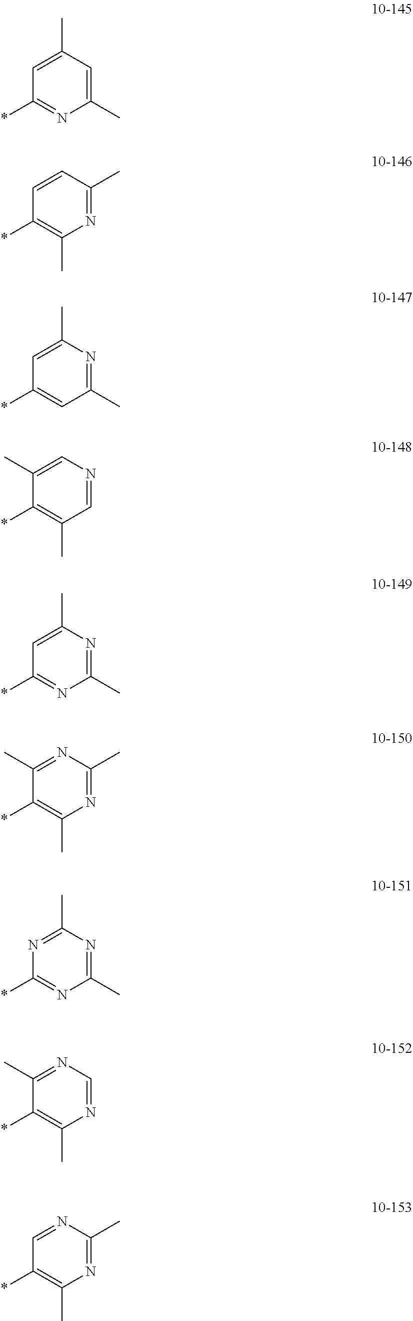

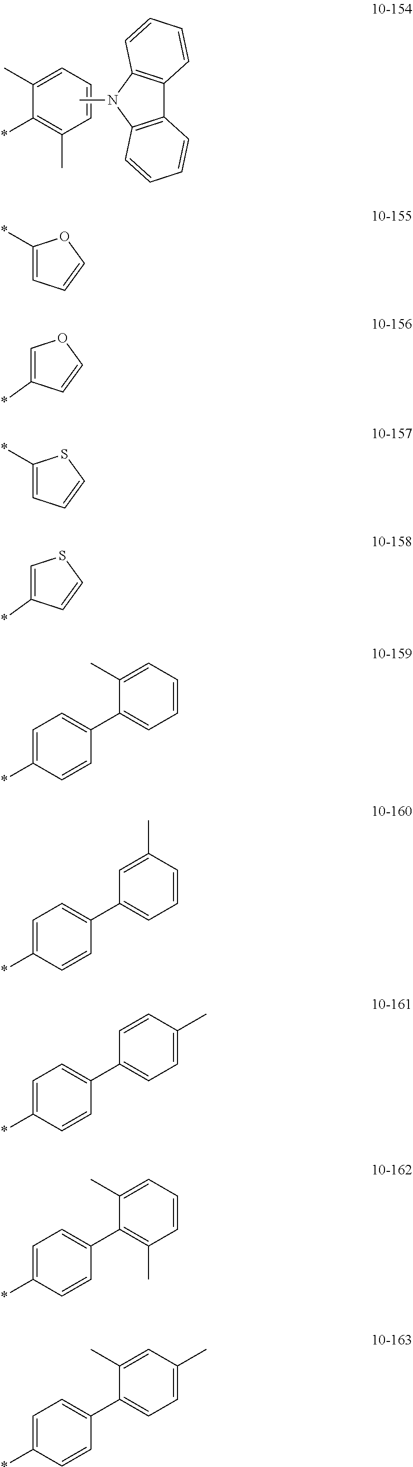

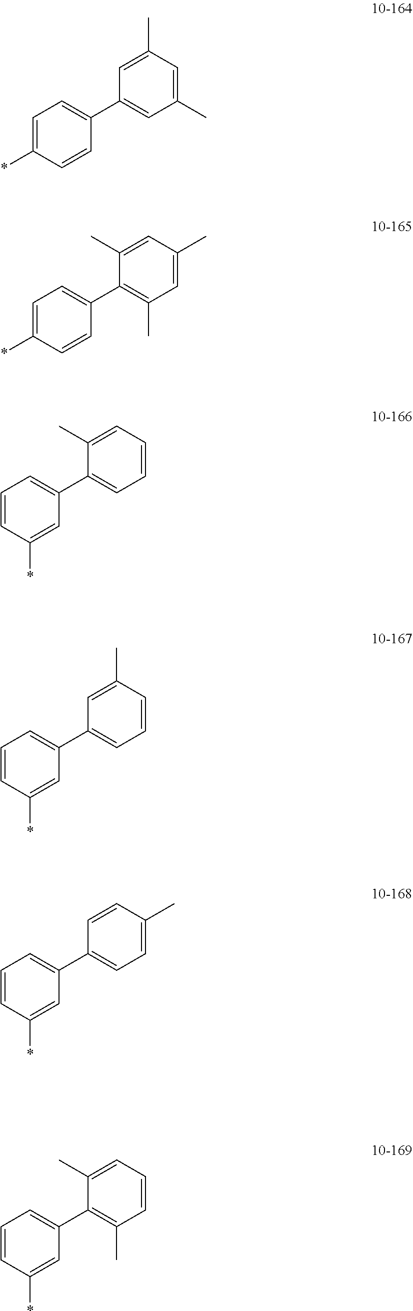

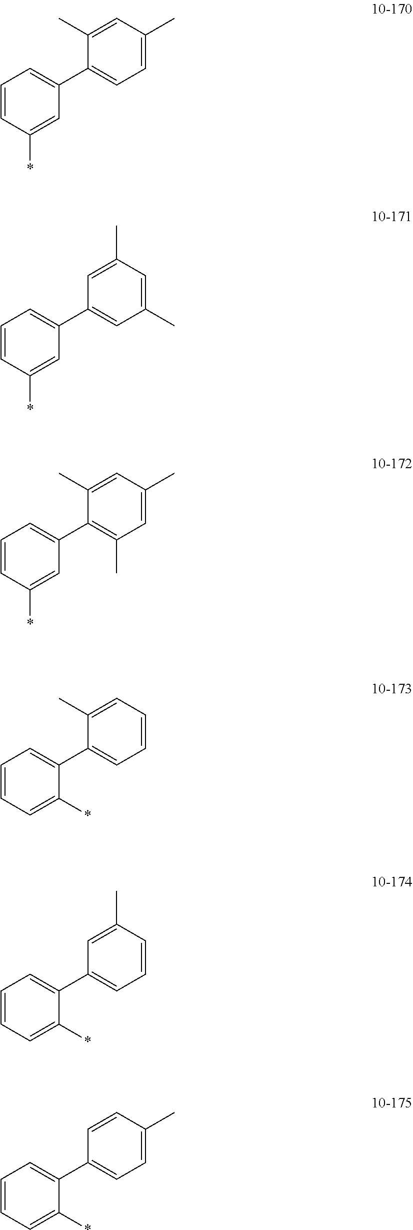

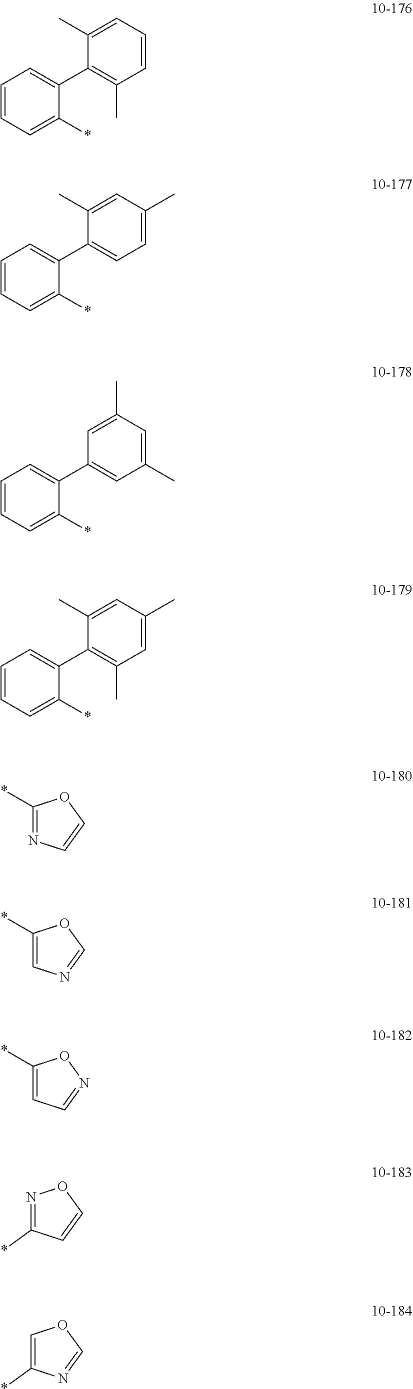

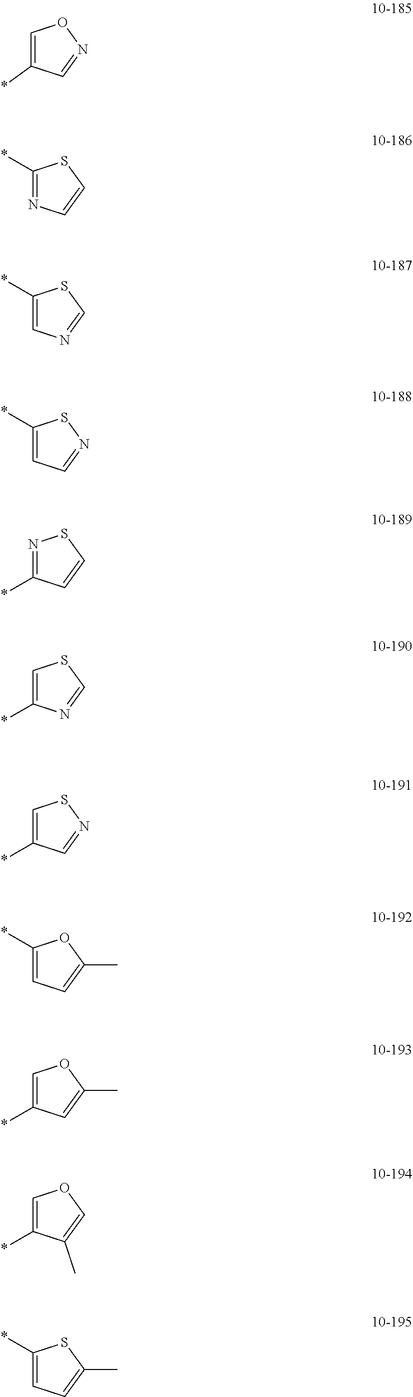

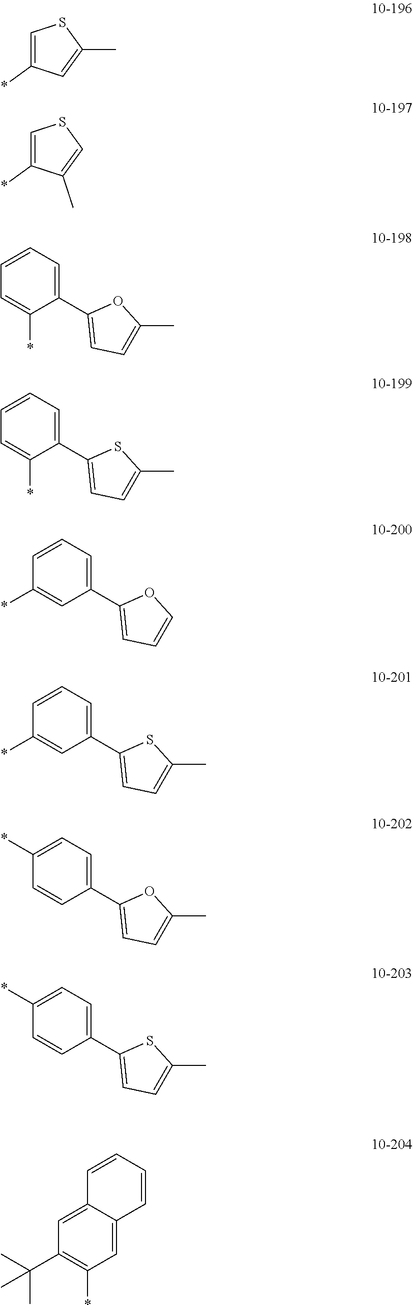

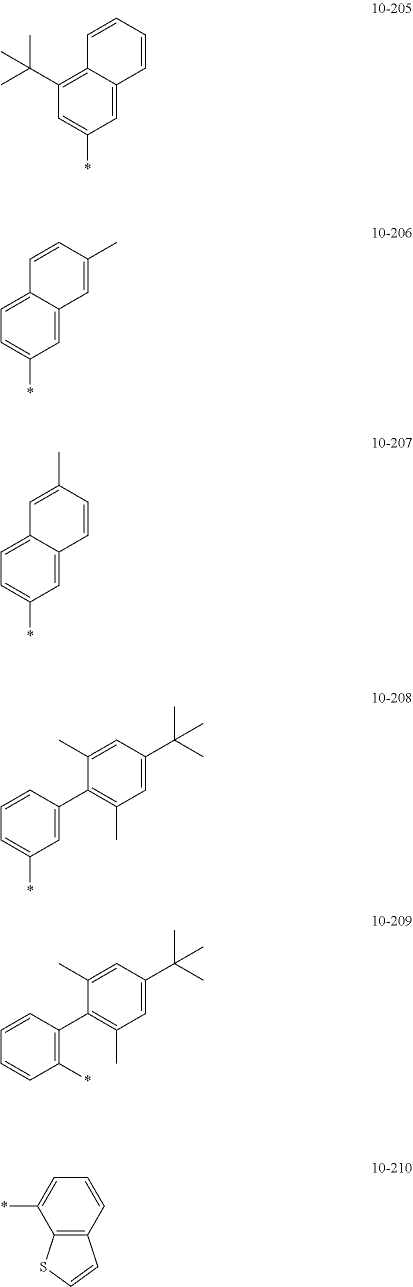

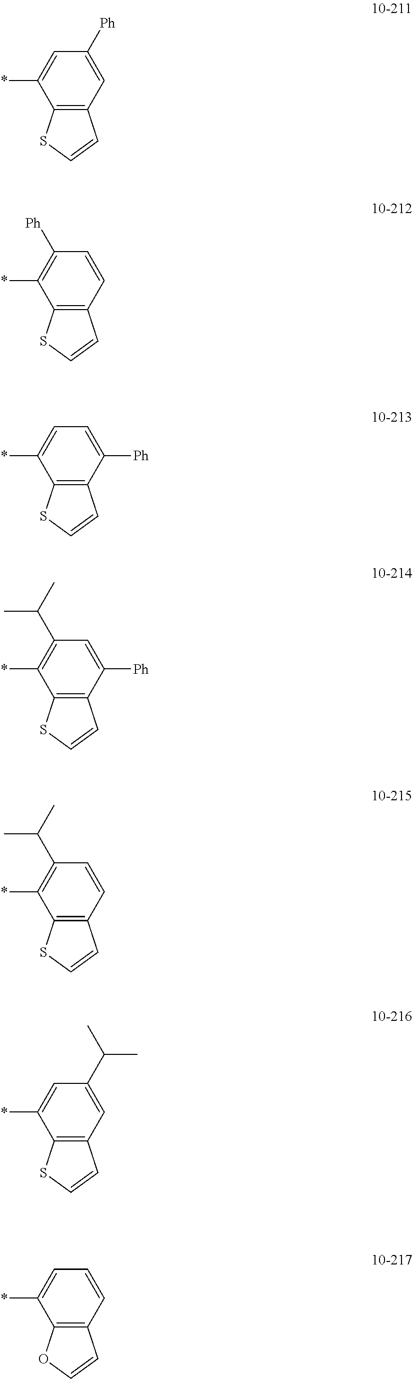

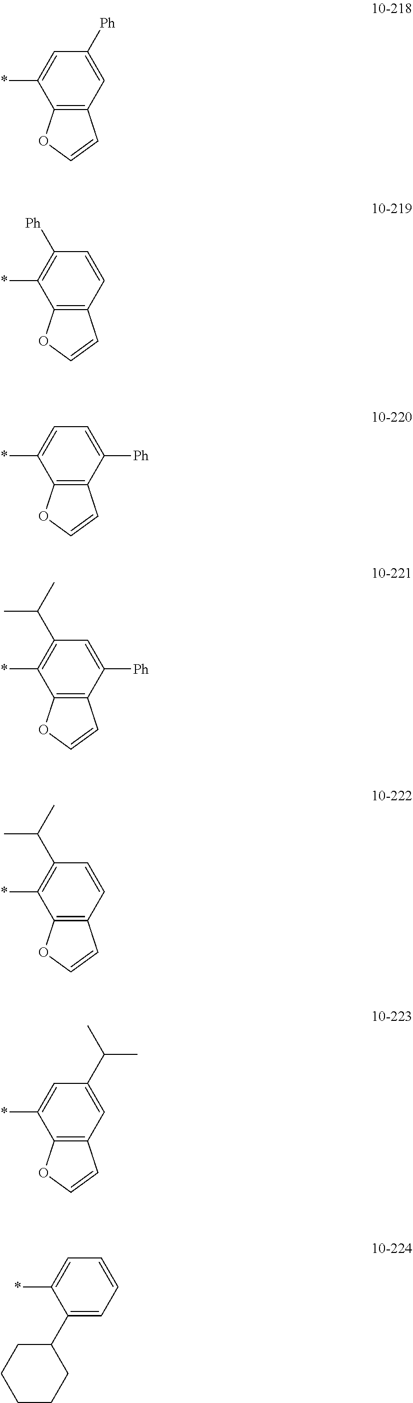

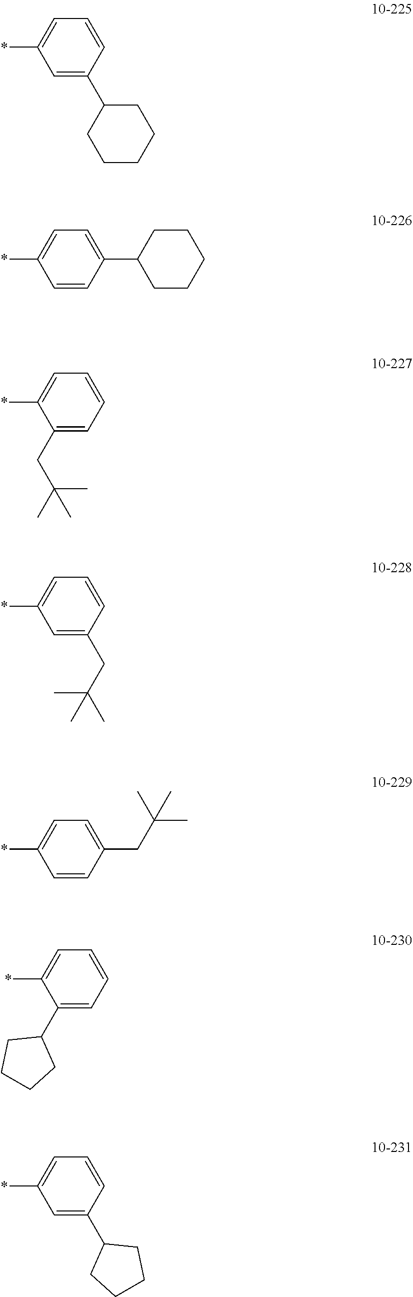

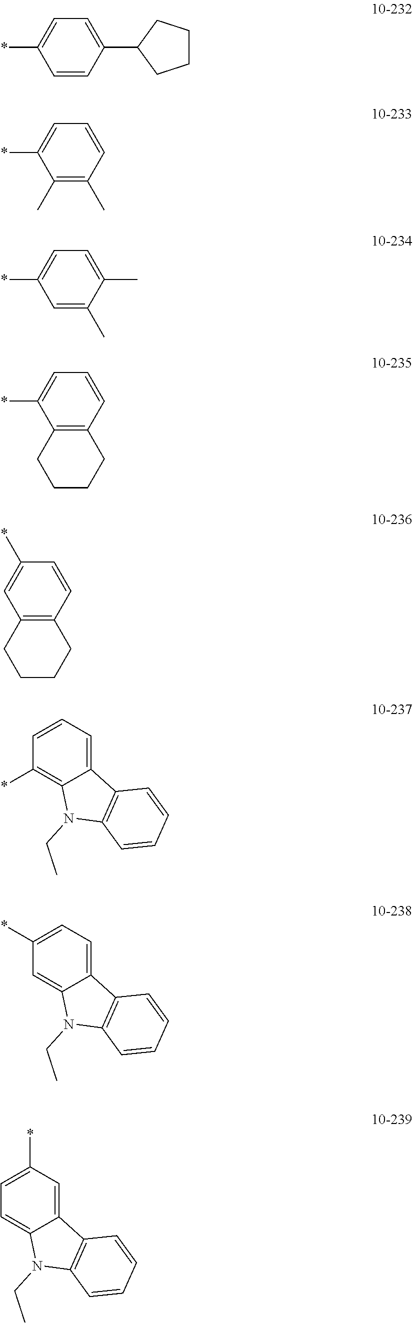

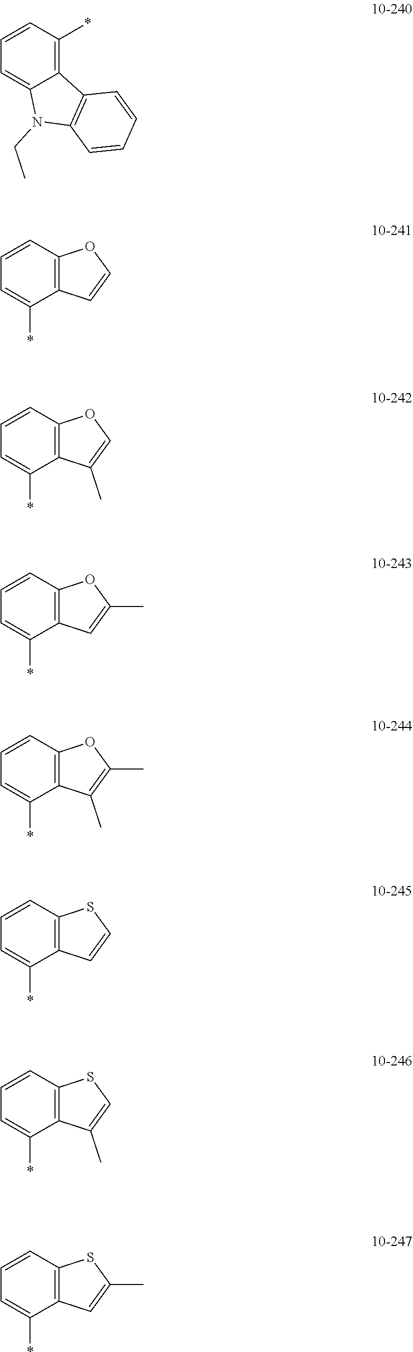

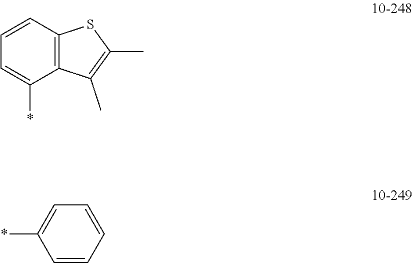

wherein, in Formulae 9-1 to 9-66 and 10-1 to 10-249, * indicates a binding site to a neighboring atom, Ph may be a phenyl group, and TMS may be a trimethylsilyl group.

The “group represented by one of Formulae 9-1 to 9-66 in which at least one hydrogen is substituted with deuterium” may be a group represented by one of Formulae 9-501 to 9-552:

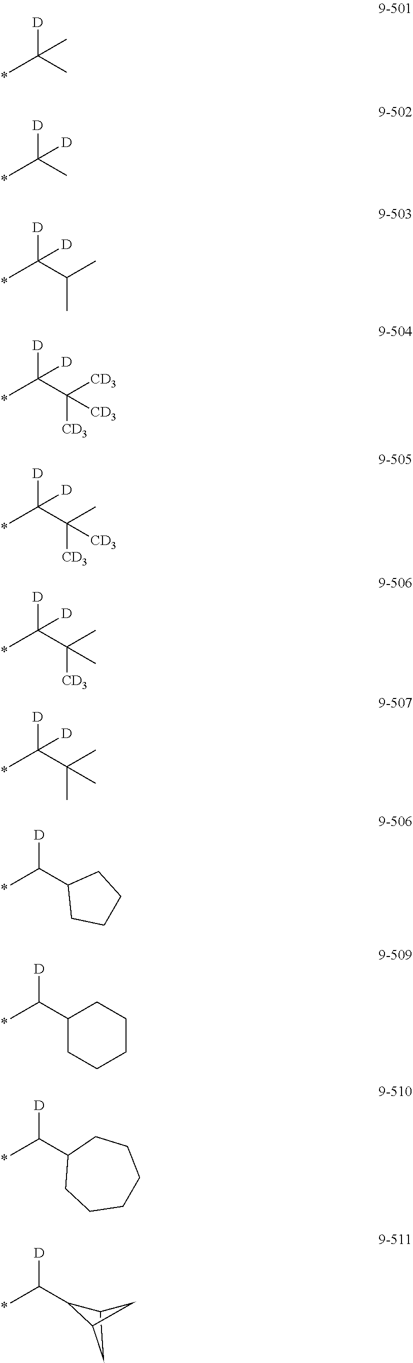

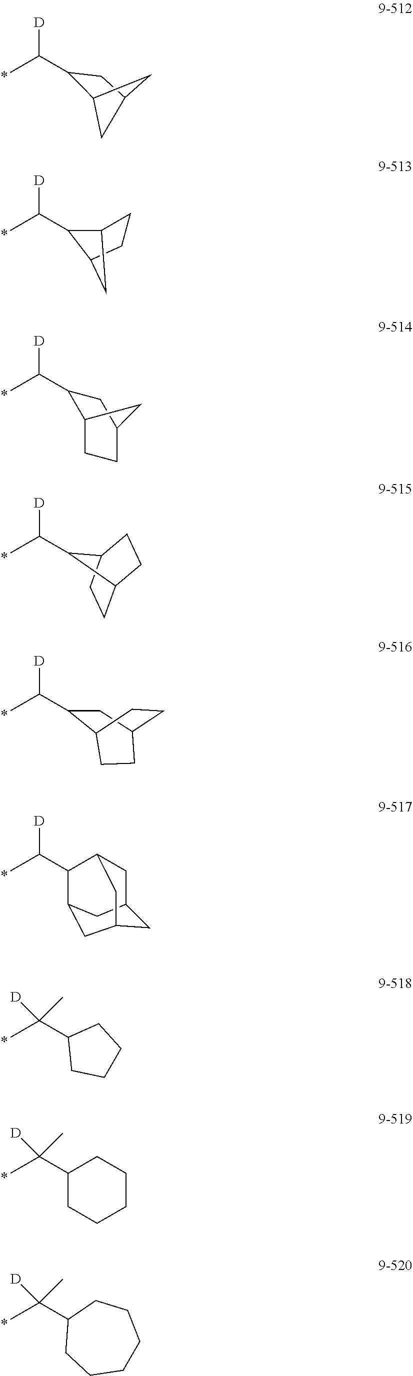

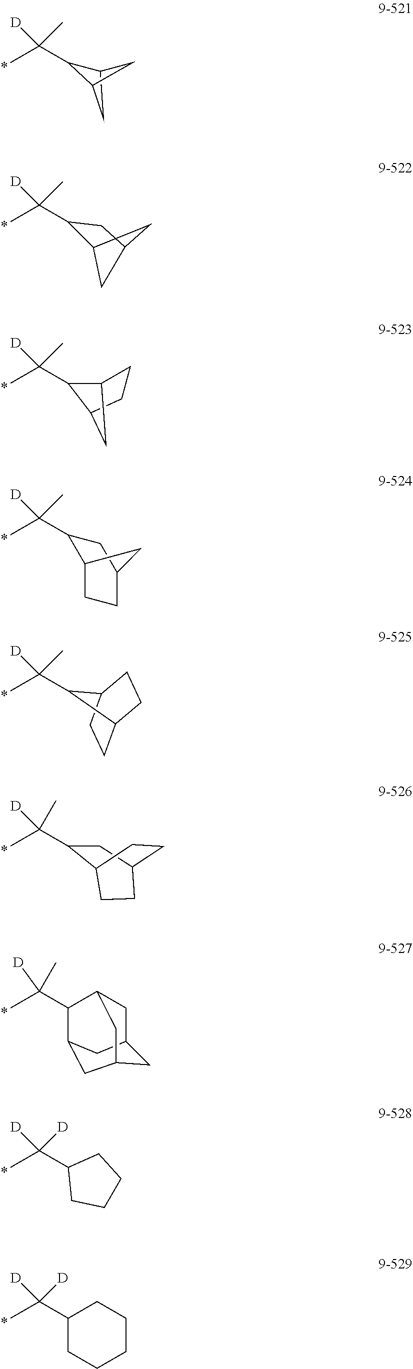

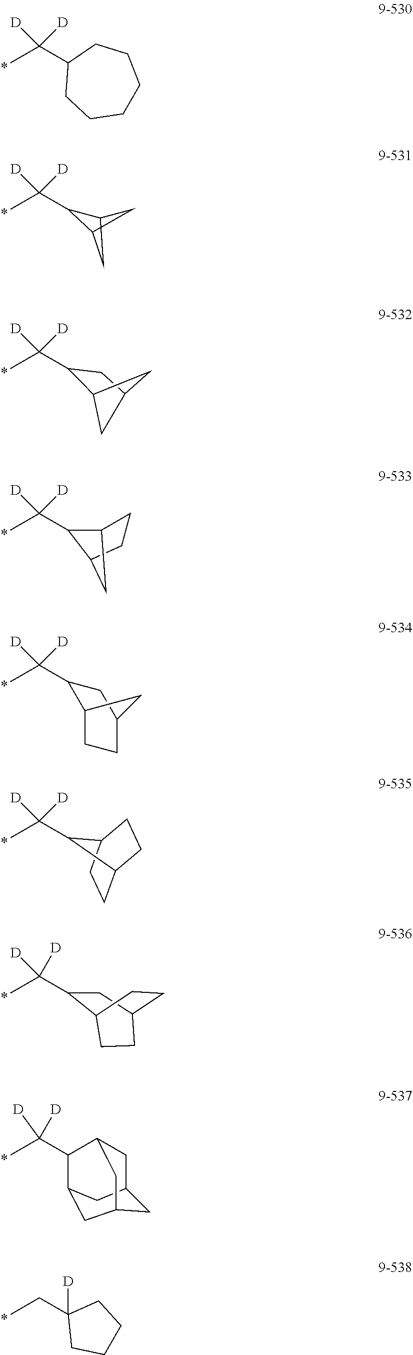

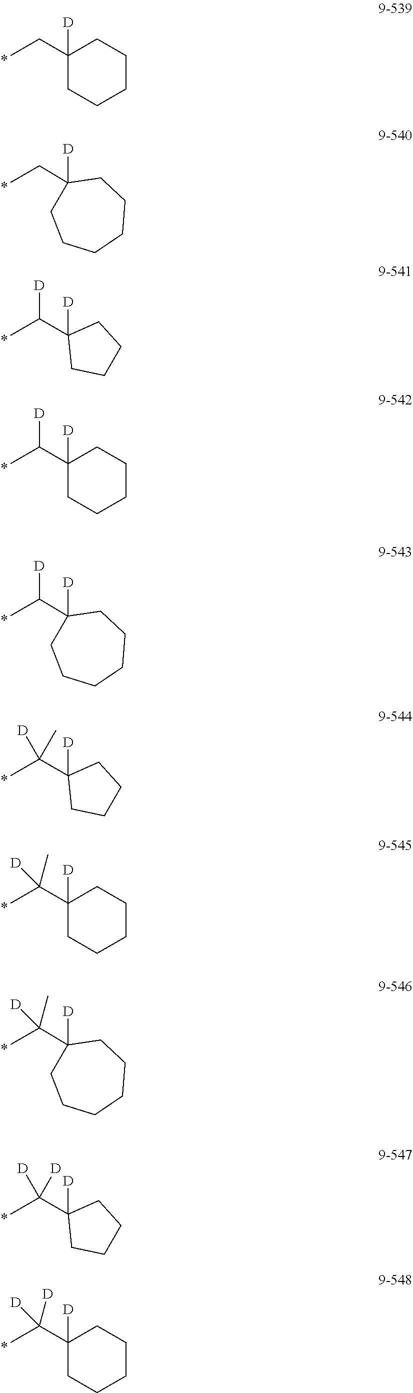

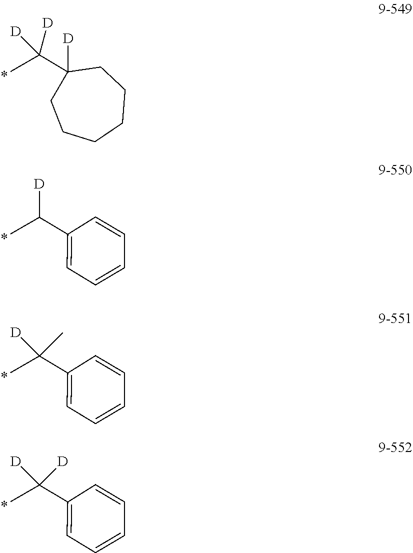

The “group represented by one of Formulae 10-1 to 10-249 in which at least one hydrogen is substituted with deuterium” may be a group represented by one of Formulae 10-501 to 10-510:

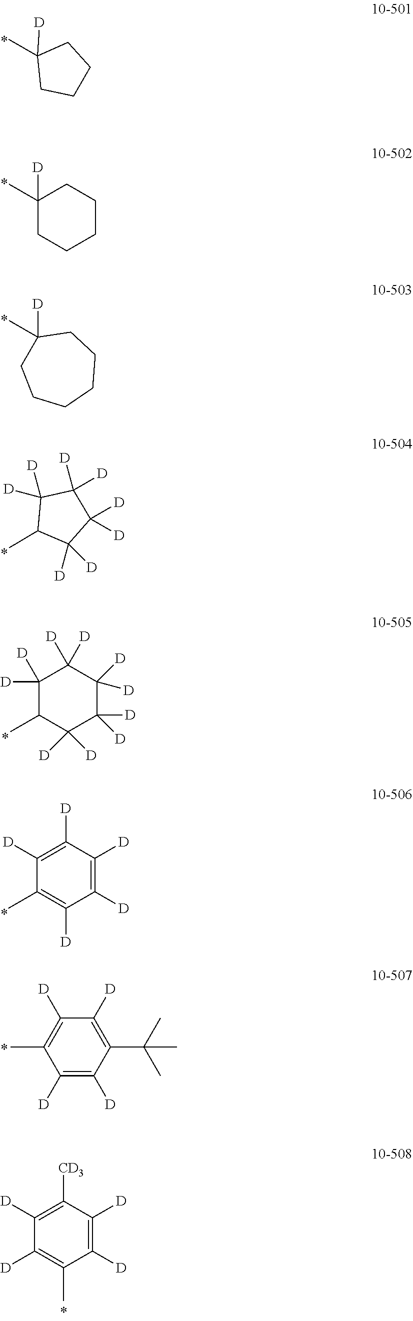

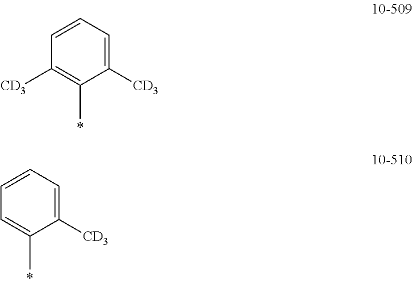

a2 and a4 in Formula 1 may each be 0.

In an embodiment, in Formula 1, a1 and a3 may each be 1, a2 and a4 may each be 0, and R₁ and R₃ may each independently be Formulae 10-11 to 10-249.

Regarding Formula 1, two or more of a plurality of R₁(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, an R₁ and a N of ring CY₁ are optionally linked to each other to form a C₁-C₃₀ heterocyclic group that is unsubstituted or substituted with at least one R₁₀ₐ, two or more of a plurality of R₂(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, and two or more of a plurality of R₄(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ. In this regard, R₁₀ₐ is the same as described in connection with R₁.

At least one of a plurality of R₁, R₂, and R₃ and at least one of a plurality of R₄(s) in Formula 1 may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ. In this regard, R₁₀ₐ is the same as described in connection with R₁.

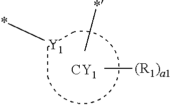

A group represented by in Formula 1 may be represented by one of Formulae CY₁-1 to CY₁-48:

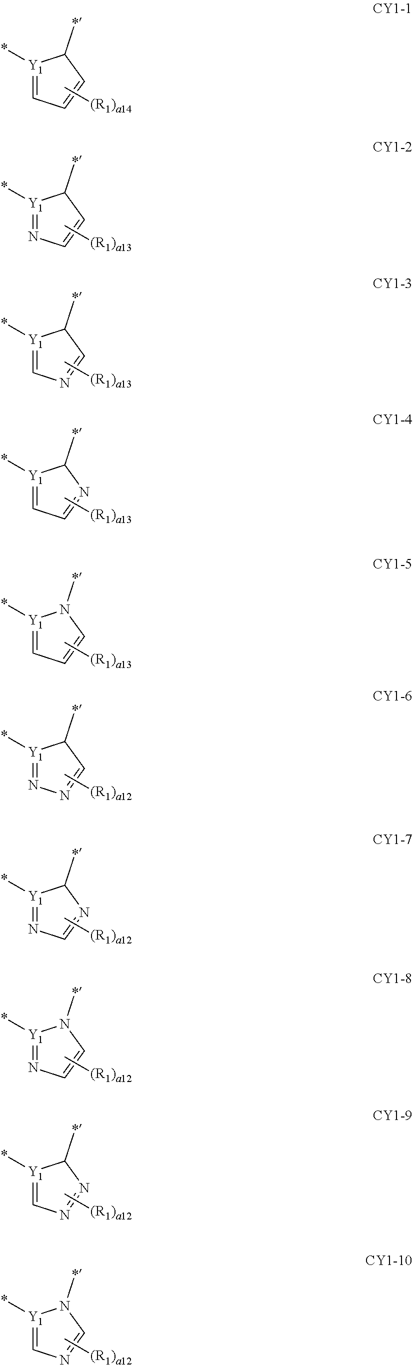

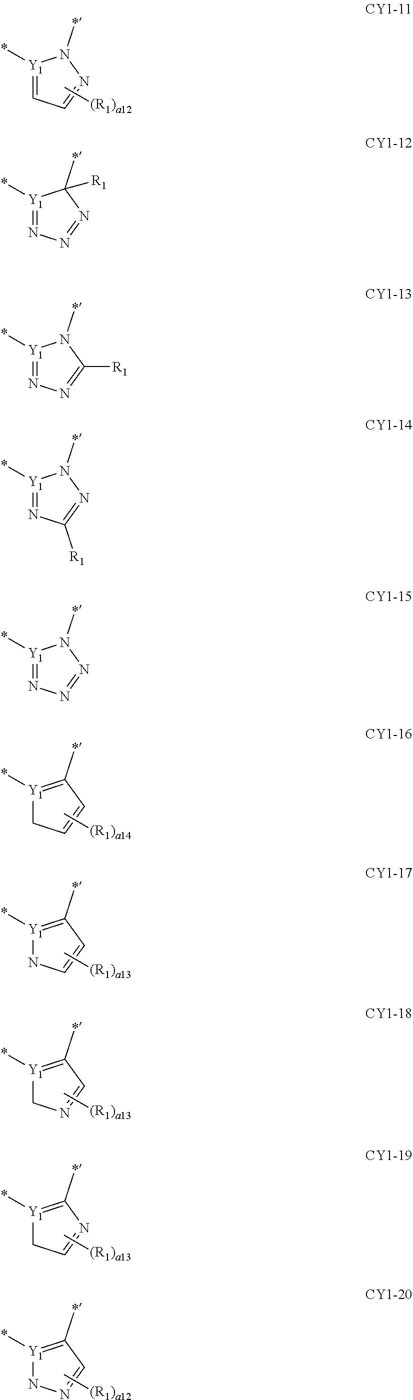

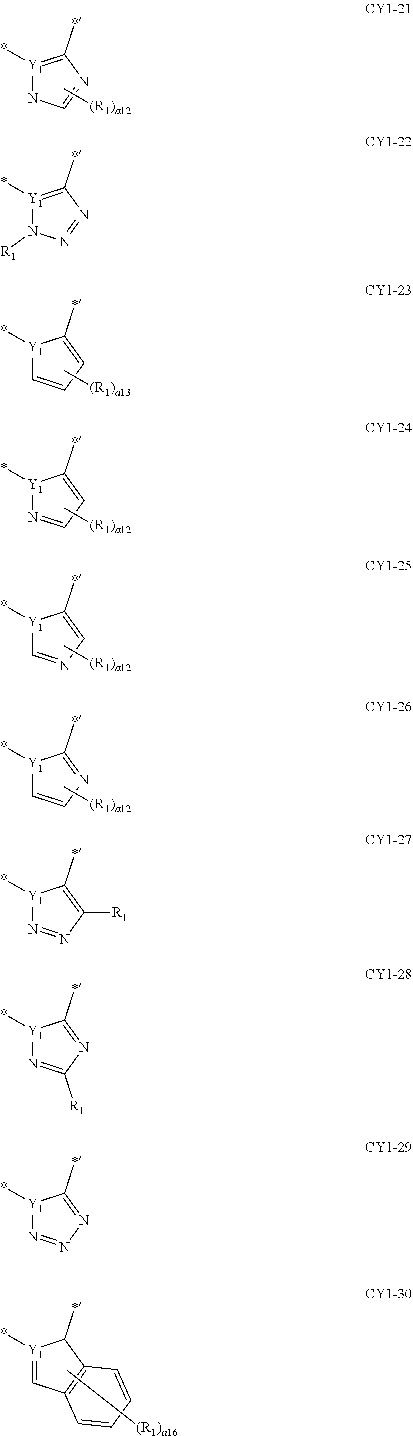

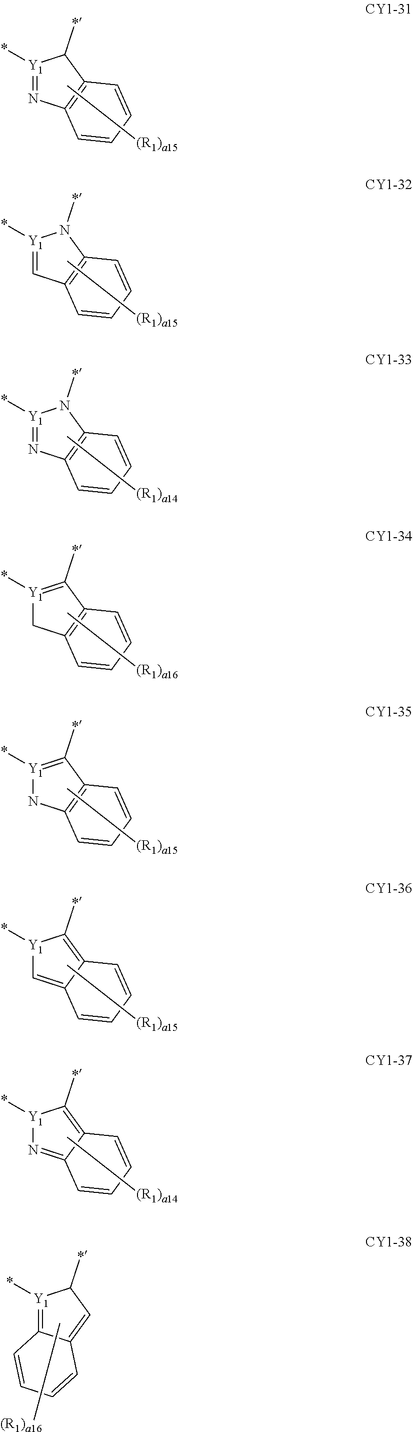

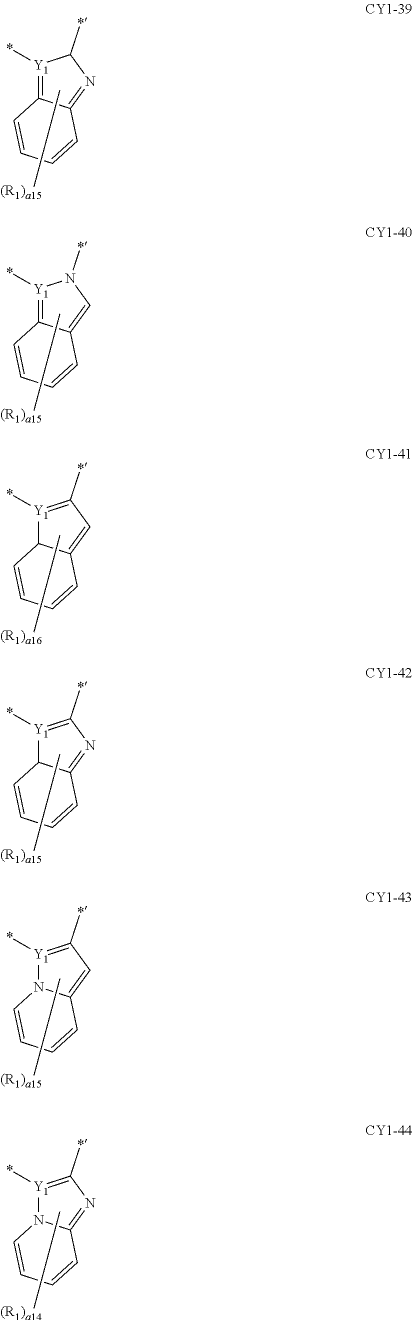

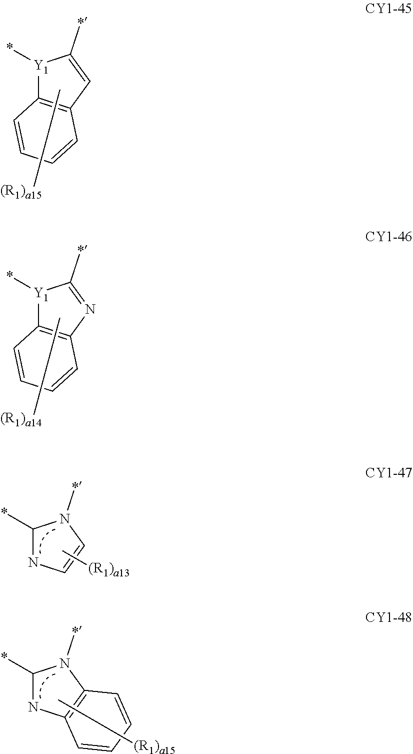

wherein, in Formulae CY1-1 to CY1-48,

Y₁ and R₁ are the same as described above,

a12 may be an integer from 0 to 2,

a13 may be an integer from 0 to 3,

a14 may be an integer from 0 to 4,

a15 may be an integer from 0 to 5,

a16 may be an integer from 0 to 6,

* indicates a binding site to M in Formula 1, and

*′ indicates a binding site to T₁ in Formula 1.

In an embodiment, Formula 1 may be represented by one of Formulae 2-1 to 2-5:

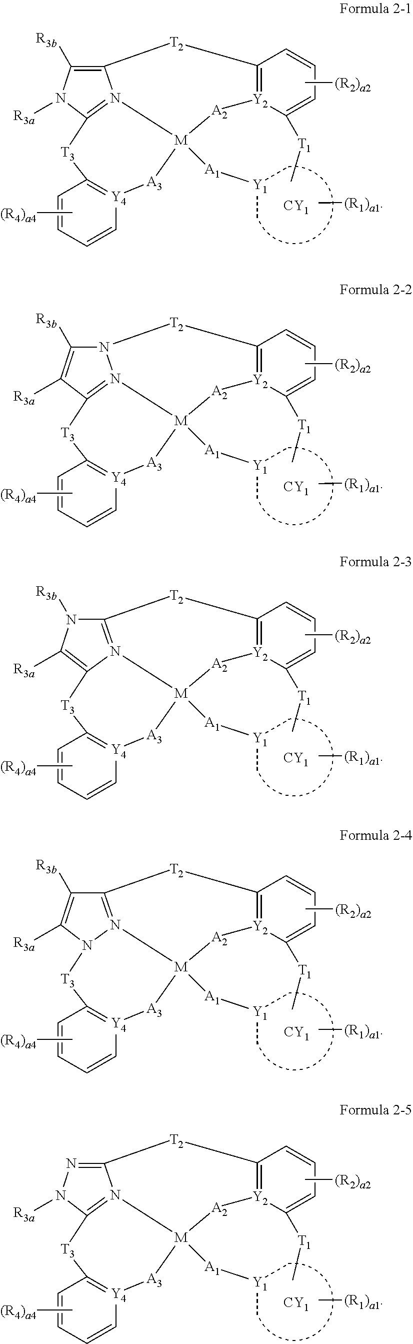

wherein, in Formulae 2-1 to 2-5,

CY₁, Y₁, Y₂, Y₄, A₁, A₂, A₃, T₁, T₂, T₃, R₁, R₂, R₄, a1, a2, and a4 are the same as described above, and

R₃ₐ and R_{3b} are the same as described in connection with R₃.

In an embodiment, in Formulae 2-1 to 2-5,

A₃ may be O,

A₁ and A₂ may each be a chemical bond, and

CY₁ may be

a cyclopentane group, a cyclopentadiene group, a furan group, a benzofuran group, a thiophene group, a benzothiophene group, a pyrrole group, a benzopyrrole group, a silole group, a benzosilole group, an oxazole group, a benzoxazole group, an isoxazole group, a benzoisoxazole group, an oxadiazole group, a benzoxadiazole group, an isoxadiazole group, a benzoisoxadiazole group, an oxatriazole group, a benzoxatriazole group, an isoxatriazole group, a benzoisoxatriazole group, a thiazole group, a benzothiazole group, an isothiazole group, a benzoisothiazole group, a thiadiazole group, a benzothiadiazole group, isothiadiazole group, a benzoisothiadiazole group, a thiatriazole group, a benzothiatriazole group, an isothiatriazole group, a benzoisothiatriazole group, a pyrazole group, a benzopyrazole group, an imidazole group, a benzimidazole group, a 5-membered cyclic carbene group, a 5-membered benzocyclic carbene group, a triazole group, a benzotriazole group, a tetrazole group, a benzotetrazole group, an azasilole group, a benzoazasilole group, a diazasilole group, a benzodiazasilole group, a triazasilole group, or a benzotriazasilole group, but embodiments of the present disclosure are not limited thereto.

In an embodiment, Formula 1 may be represented by one of Formulae 3-1 to 3-10:

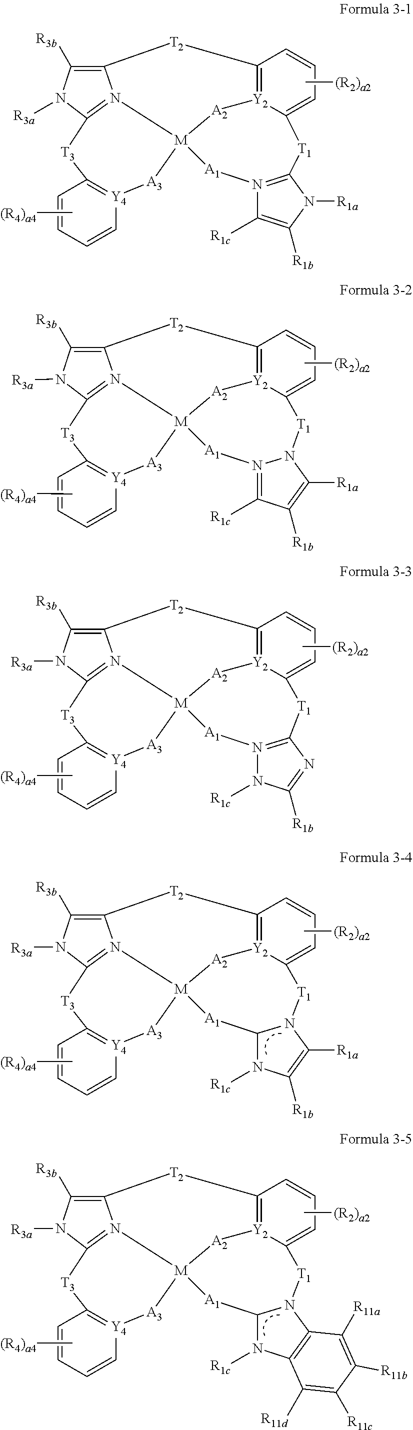

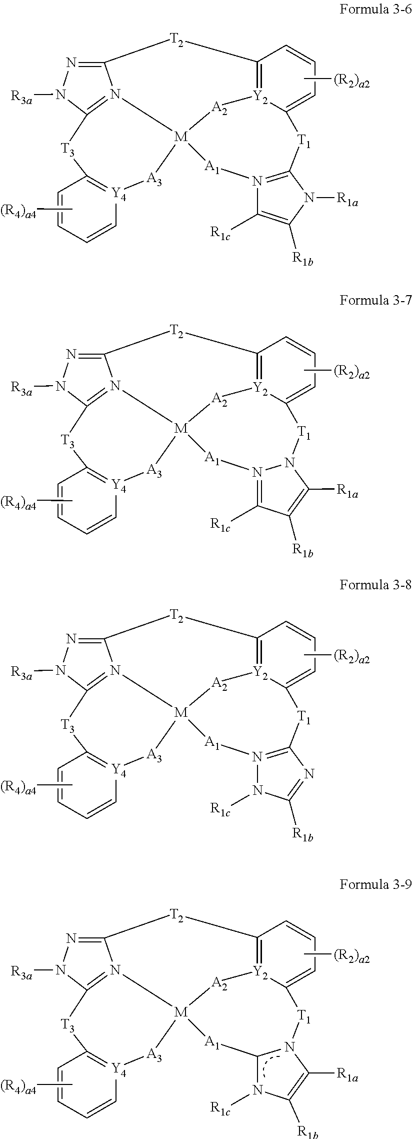

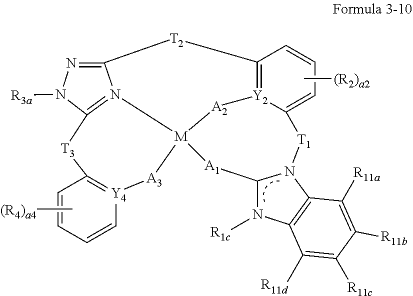

wherein, in Formulae 3-1 to 3-10,

Y₂, Y₄, A₁, A₂, A₃, T₁, T₂, T₃, R₂, R₄, a2, and a4 are the same as described above, and

R₃ₐ and R_{3b} are the same as described in connection with R₃.

R₁ₐ, R_{1b}, R_{1c}, R₁₁ₐ, R_{11b}, R_{11c}, and R_{11d} are the same as described in connection with R₁.

The organometallic compound may be one of Compounds 1 to 114:

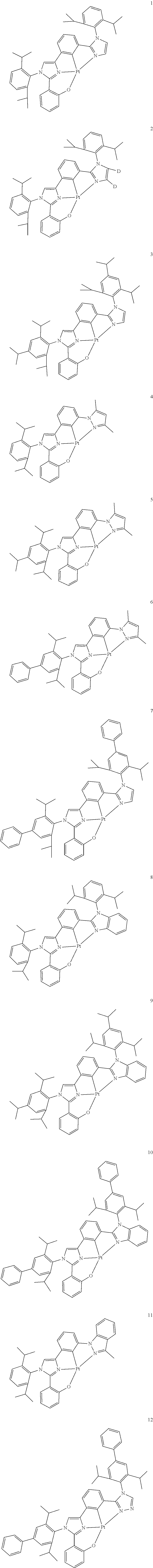

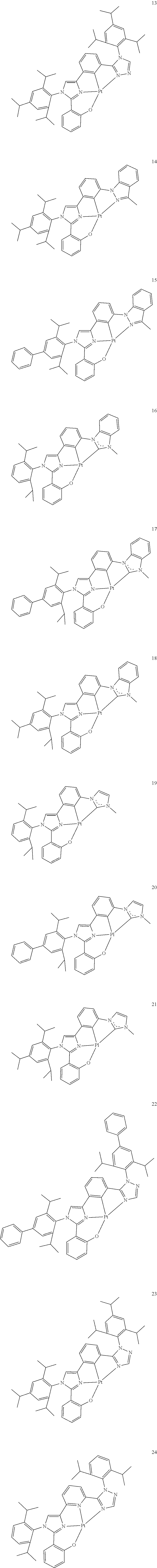

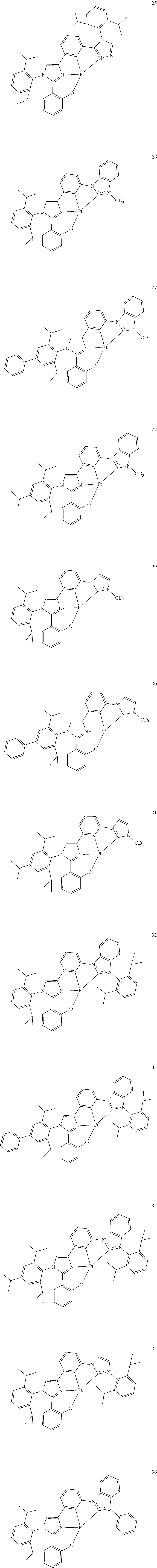

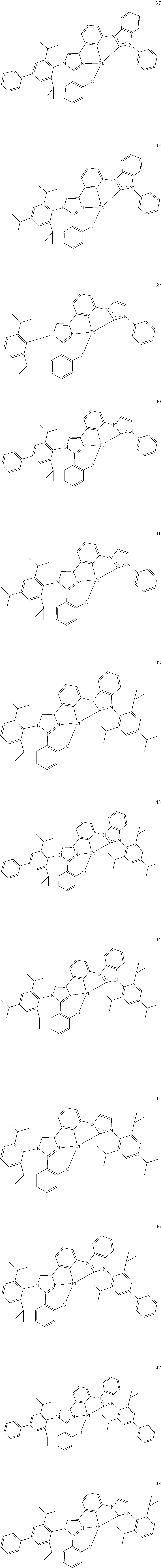

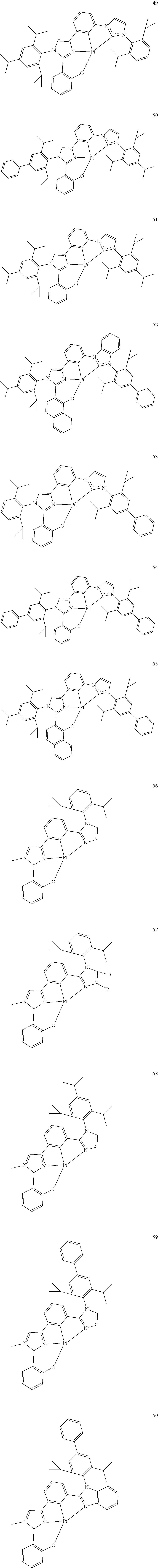

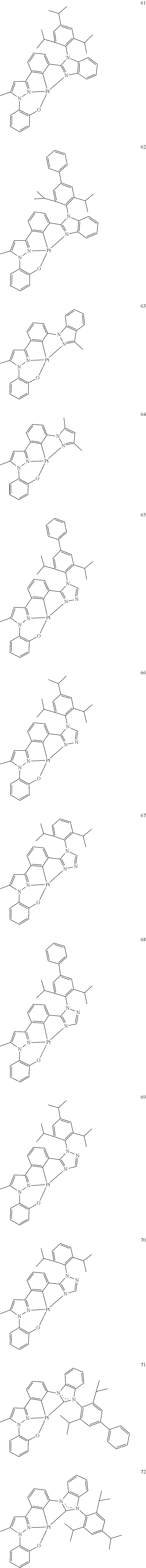

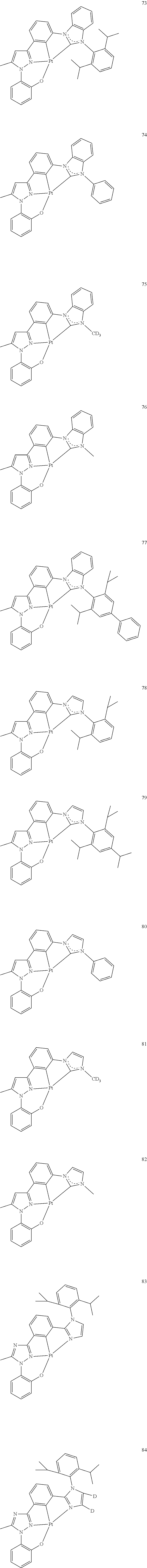

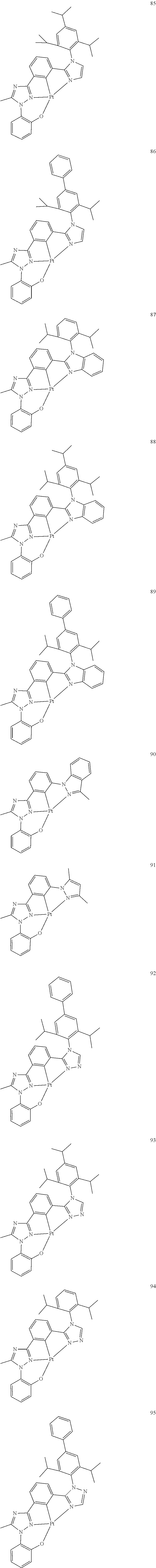

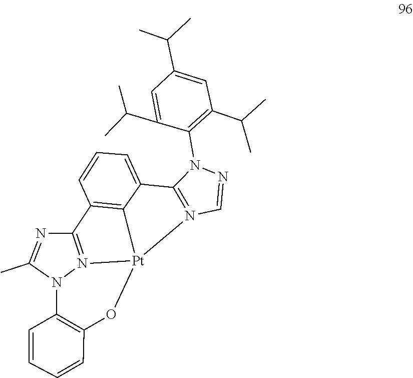

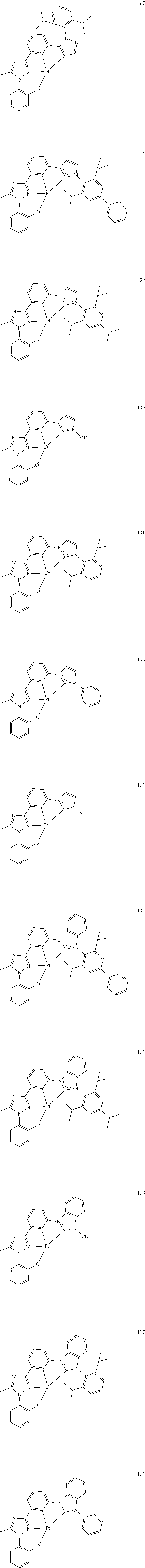

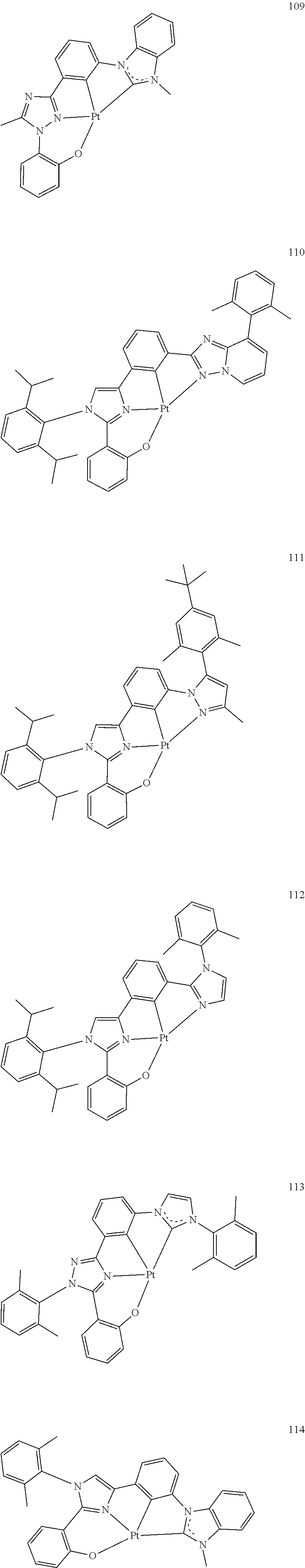

The organometallic compound may include a tetradentate ligand in which two central metals are linked via two covalent bonds and two coordination bonds. Due to the inclusion of the tetradentate ligand in the organometallic compound, high thermal stability may be obtained compared to a compound having a tridentate ligand which is combined with a monodentate ligand having a weak binding force due to a single bond.

Also, since the organometallic compound includes the ring CY₂ in the tetradentate ligand which is a 5-membered heterocyclic group including N atom as Y₃, compared to a case in which Y₃ is C, that is, the case of carbene or indene, quenching caused by the transfer of energy to the metal-centered ligand-field states may be suppressed and thus efficiency may be increased.

Also, since, in the organometallic compound, CY₁ is a 5-membered heterocyclic group in which Y₃ is N and CY₂ is a 5-membered heterocyclic group, in the tetradentate ligand, the organometallic compound may have high triplet energy and thus may emit blue light.

Regarding Formula 1 representing the organometallic compound, at least one of R₁(s) in the number of a1 and R₃(s) in the number of a3 may each independently be a substituted or unsubstituted C₁-C₆₀ alkyl group or a substituted or unsubstituted C₆-C₃₀ aryl group. As a result, since the organometallic compound represented by Formula 1 may have high optical orientation, the emission of blue light and high luminescence efficiency can be obtained at least one the same time.

For example, the highest occupied molecular orbital (HOMO), lowest unoccupied molecular orbital (LUMO), and T₁ energy levels of some of the compounds are structure-optimized at the (B3LYP, 6-31G(d,p)) level by using the DFT method of the Gaussian program and evaluated. Results thereof are shown in Table 1 below.

TABLE 1

| Compound | HOMO | LUMO | T₁ |
|---|---|---|---|
| No. | (eV) | (eV) | (eV) |
| 110 | −4.72 | −1.51 | 2.74 |
| 111 | −4.57 | −0.86 | 2.71 |
| 112 | −4.46 | −1.01 | 2.63 |
| 113 | −4.71 | −0.93 | 3.12 |
| 114 | −4.66 | −1.04 | 2.83 |

From Table 1, it can be confirmed that the organometallic compound represented by Formula 1 has electrical characteristics suitable for use as a dopant for an electronic device, for example, an organic light-emitting device.

For example, the organometallic compound represented by Formula 1 may emit blue light.

In an embodiment, the organometallic compound represented by Formula 1 may emit blue light with a maximum emission range of about 450 nm to about 470 nm.

In addition, in one or more embodiments, the triplet (T₁) energy level of the organometallic compound represented by Formula 1 may be in the range of about 2.6 eV or more, or in the range of about 2.6 eV to about 3.5 eV. The T₁ energy level is the result of evaluation (structure optimization at the level of B3LYP, 6-31G(d,p)) using the DFT method of the Gaussian program.

In one or more embodiments, the full width at half maximum (FWMH) of the main peak having the maximum intensity in the photoluminescence (PL) spectrum of the organometallic compound represented by Formula 1 may be in the range of about 50 nm or less or from about 10 nm to about 50 nm.

Synthesis methods of the organometallic compound represented by Formula 1 may be recognizable by one of ordinary skill in the art by referring to Synthesis Examples provided below.

The organometallic compound represented by Formula 1 is suitable for use in an organic layer of an organic light-emitting device, for example, for use as a dopant in an emission layer of the organic layer. Thus, another aspect provides an organic light-emitting device that includes: a first electrode; a second electrode; and an organic layer that is located between the first electrode and the second electrode and includes an organic layer including an emission layer and at least one of the organometallic compound represented by Formula 1.

The organic light-emitting device may have, due to the inclusion of an organic layer including the organometallic compound represented by Formula 1, a low driving voltage, high efficiency, high power, high quantum efficiency, a long lifespan, a low roll-off ratio, and excellent color purity.

The organometallic compound of Formula 1 may be used between a pair of electrodes of an organic light-emitting device. For example, the organometallic compound represented by Formula 1 may be included in the emission layer. In this regard, the organometallic compound may act as a dopant, and the emission layer may further include a host (that is, an amount of the organometallic compound represented by Formula 1 is smaller than an amount of the host).

The expression “(an organic layer) includes at least one of organometallic compounds” used herein may include a case in which “(an organic layer) includes identical organometallic compounds represented by Formula 1” and a case in which “(an organic layer) includes two or more different organometallic compounds represented by Formula 1.”

For example, the organic layer may include, as the organometallic compound, only Compound 1. In this embodiment, Compound 1 may be included in the emission layer of the organic light-emitting device. In one or more embodiments, the organic layer may include, as the organometallic compound, Compound 1 and Compound 2. In this regard, Compound 1 and Compound 2 may exist in an identical layer (for example, Compound 1 and Compound 2 all may exist in an emission layer).

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

In one embodiment, in the organic light-emitting device, the first electrode is an anode, and the second electrode is a cathode, and the organic layer further includes a hole transport region between the first electrode and the emission layer and an electron transport region between the emission layer and the second electrode, and the hole transport region includes a hole injection layer, a hole transport layer, an electron blocking layer, or any combination thereof, and the electron transport region includes a hole blocking layer, an electron transport layer, an electron injection layer, or any combination thereof.

The term “organic layer” used herein refers to a single layer and/or a plurality of layers between the first electrode and the second electrode of the organic light-emitting device. The “organic layer” may include, in addition to an organic compound, an organometallic complex including metal.

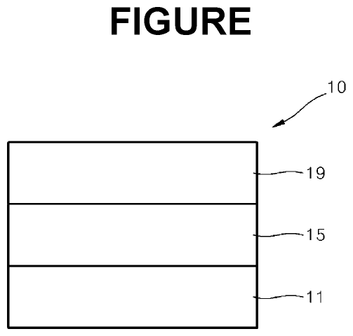

FIG. 1s a schematic cross-sectional view of an organic light-emitting device 10 according to an embodiment. Hereinafter, the structure of an organic light-emitting device according to an embodiment of the present disclosure and a method of manufacturing an organic light-emitting device according to an embodiment of the present disclosure will be described in connection with FIGURE. The organic light-emitting device 10 includes a first electrode 11, an organic layer 15, and a second electrode 19, which are sequentially stacked.

A substrate may be additionally located under the first electrode 11 or above the second electrode 19. For use as the substrate, any substrate that is used in organic light-emitting devices available in the art may be used, and the substrate may be a glass substrate or a transparent plastic substrate, each having excellent mechanical strength, thermal stability, transparency, surface smoothness, ease of handling, and water resistance.

In one or more embodiments, the first electrode 11 may be formed by depositing or sputtering a material for forming the first electrode 11 on the substrate. The first electrode 11 may be an anode. The material for forming the first electrode 11 may be materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO, but the structure of the first electrode 11 is not limited thereto.

The organic layer 15 is located on the first electrode 11.

The organic layer 15 may include a hole transport region, an emission layer, and an electron transport region.

The hole transport region may be between the first electrode 11 and the emission layer.

The hole transport region may include a hole injection layer, a hole transport layer, an electron blocking layer, a buffer layer, or any combination thereof.

The hole transport region may include only either a hole injection layer or a hole transport layer. In one or more embodiments, the hole transport region may have the hole injection layer/hole transport layer structure, the hole injection layer/hole transport layer/electron blocking layer structure, or the first hole injection layer/second hole injection layer/electron blocking layer structure, wherein, in each structure, constituting layers are sequentially stacked from the first electrode 11.

When the hole transport region includes a hole injection layer (HIL), the hole injection layer may be formed on the first electrode 11 by using one or more suitable methods, for example, vacuum deposition, spin coating, casting, and/or Langmuir-Blodgett (LB) deposition.

When a hole injection layer is formed by vacuum deposition, the deposition conditions may vary according to a material that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Å/sec to about 100 Å/sec. However, the deposition conditions are not limited thereto.

When the hole injection layer is formed using spin coating, coating conditions may vary according to the material used to form the hole injection layer, and the structure and thermal properties of the hole injection layer. For example, a coating speed may be from about 2,000 rpm to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include at least one m-MTDATA, TDATA, 2-TNATA, NPB, R-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonicacid (PANI/CSA), polyaniline/poly(4-styrenesulfonate) (PANI/PSS), a compound represented by Formula 201 below, and a compound represented by Formula 202 below:

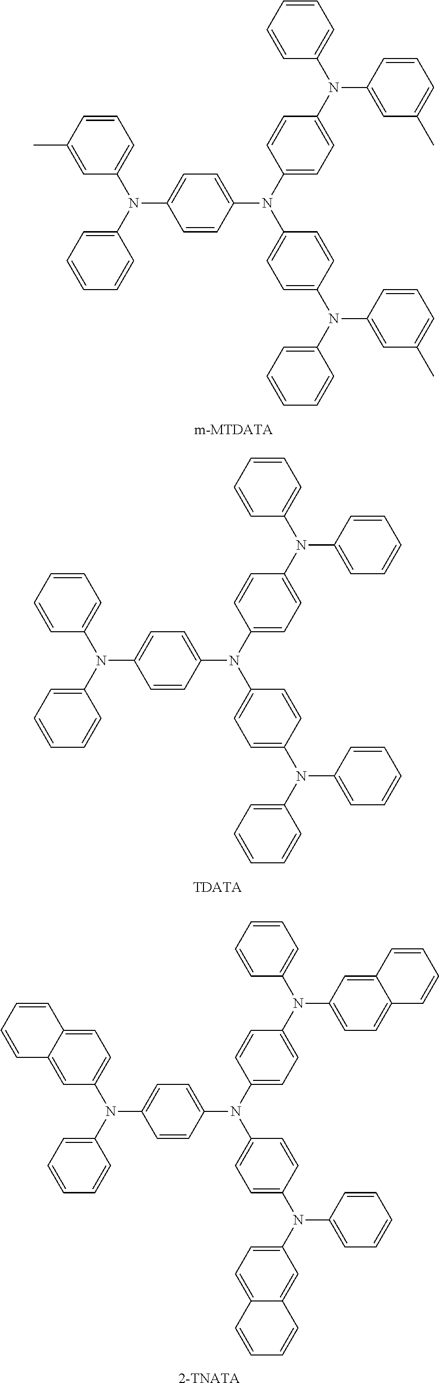

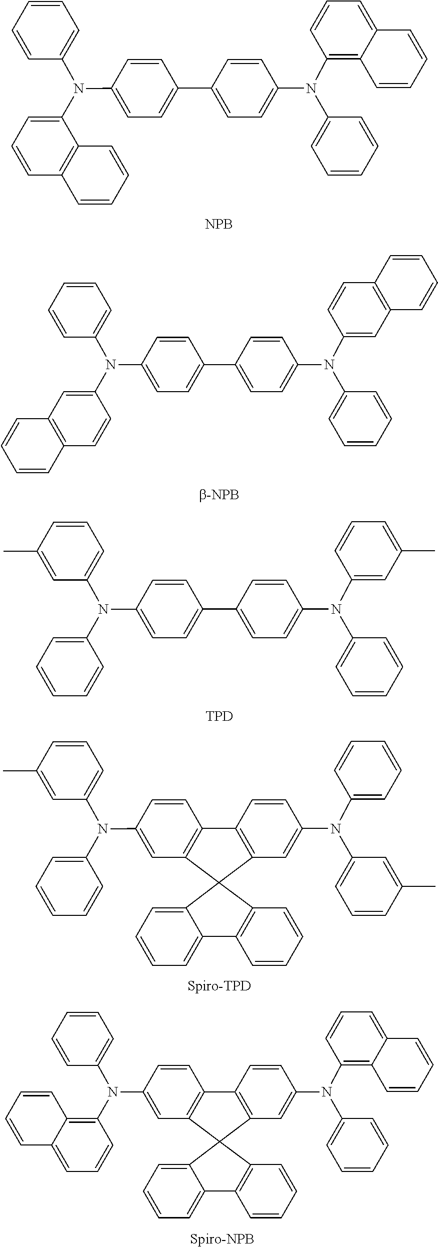

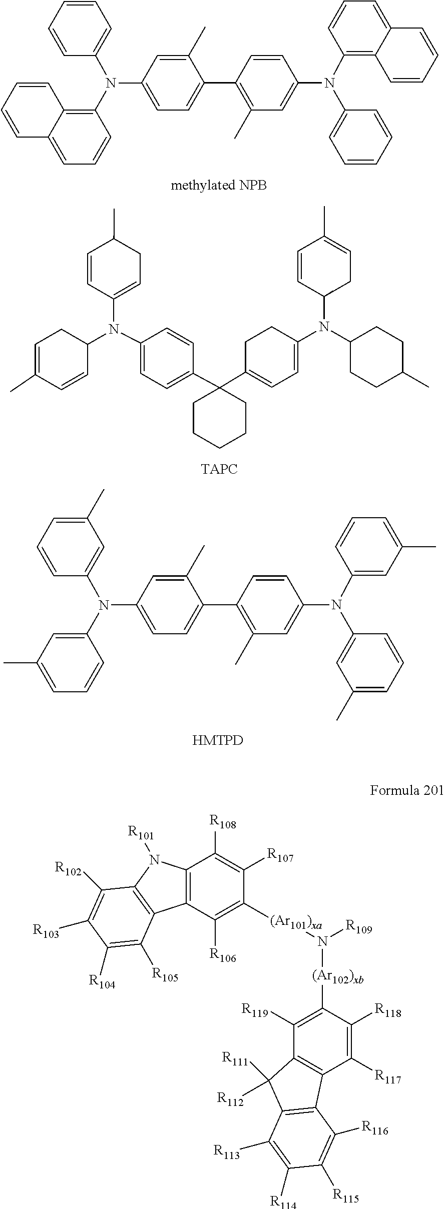

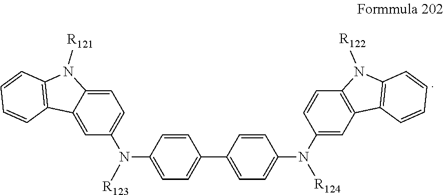

Ar₁₀₁ to Ar₁₀₂ in Formula 201 may each independently be:

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group; or

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each substituted with at least one deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or any combination thereof.

xa and xb in Formula 201 may each independently be an integer from 0 to 5, or 0, 1, or 2. For example, xa may be 1 and xb may be 0, but xa and xb are not limited thereto.

R₁₀₁ to R₁₀₈, R₁₁₁ to R₁₁₉ and R₁₂₁ to R₁₂₄ in Formulae 201 and 202 may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, and so on), or a C₁-C₁₀ alkoxy group (for example, a methoxy group, an ethoxy group, a propoxy group, a butoxy group, a pentoxy group, and so on);

a C₁-C₁₀ alkyl group or a C₁-C₁₀ alkoxy group, each substituted with at least one deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or any combination thereof;

a phenyl group, a naphthyl group, an anthracenyl group, a fluorenyl group, or a pyrenyl group; or

a phenyl group, a naphthyl group, an anthracenyl group, a fluorenyl group, or a pyrenyl group, each substituted with at least one deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, or any combination thereof,

but embodiments of the present disclosure are not limited thereto.

R₁₀₉ in Formula 201 may be:

a phenyl group, a naphthyl group, an anthracenyl group, or a pyridinyl group; or

a phenyl group, a naphthyl group, an anthracenyl group, or a pyridinyl group, each substituted with at least one a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a pyridinyl group, or any combination thereof.

According to an embodiment, the compound represented by Formula 201 may be represented by Formula 201A below, but embodiments of the present disclosure are not limited thereto:

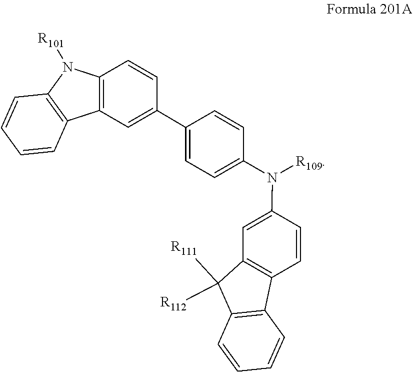

R₁₀₁, R₁₁₁, R₁₁₂, and R₁₀₉ in Formula 201A may be understood by referring to the description provided herein.

For example, the compound represented by Formula 201, and the compound represented by Formula 202 may include compounds HT1 to HT20 illustrated below, but are not limited thereto:

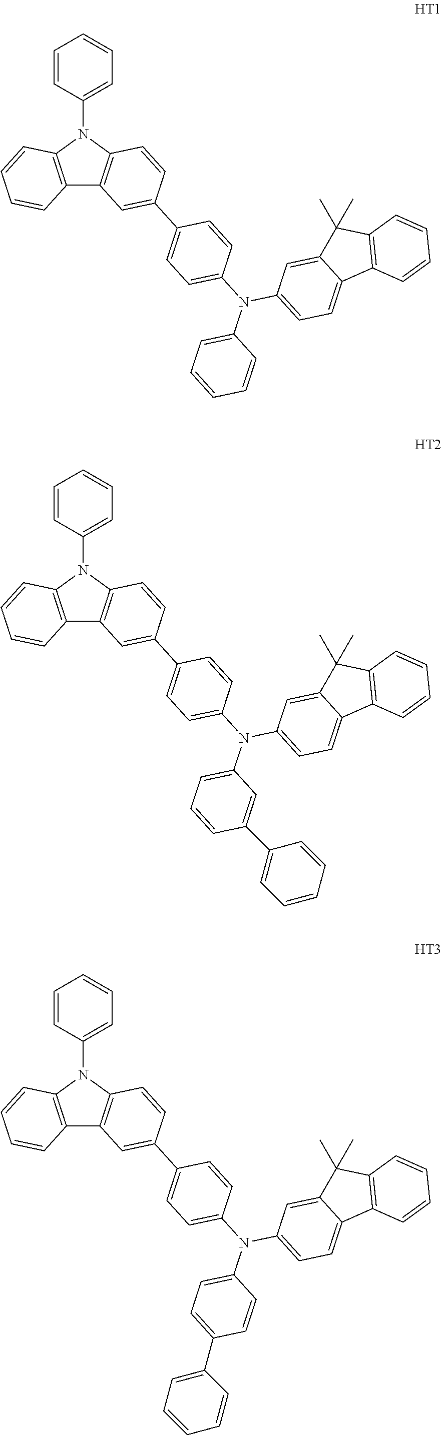 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

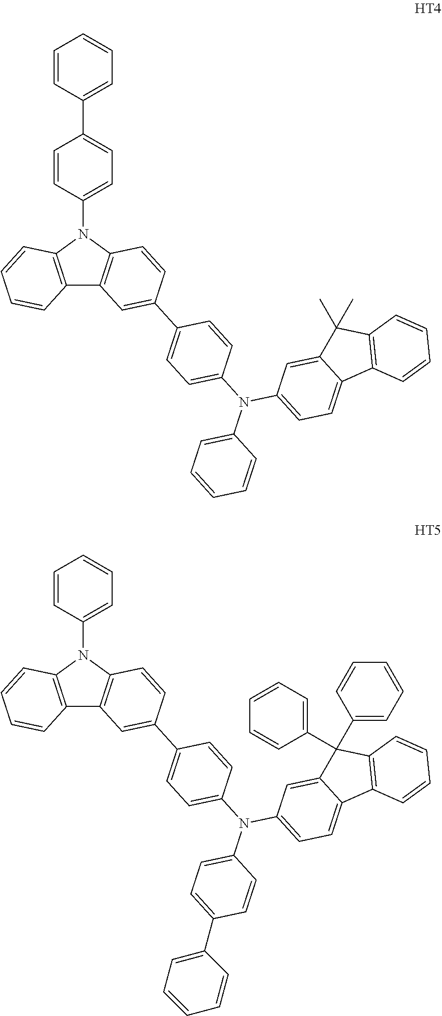 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

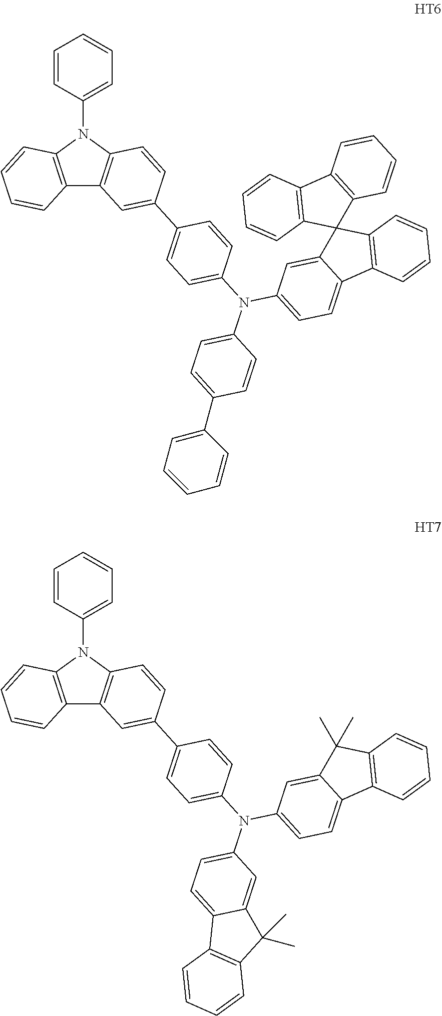 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

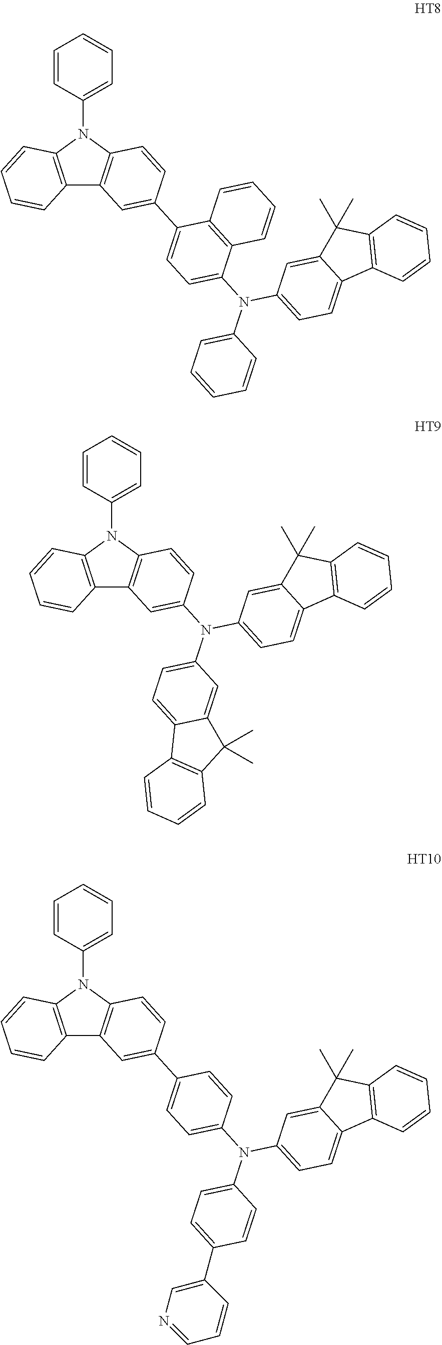 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

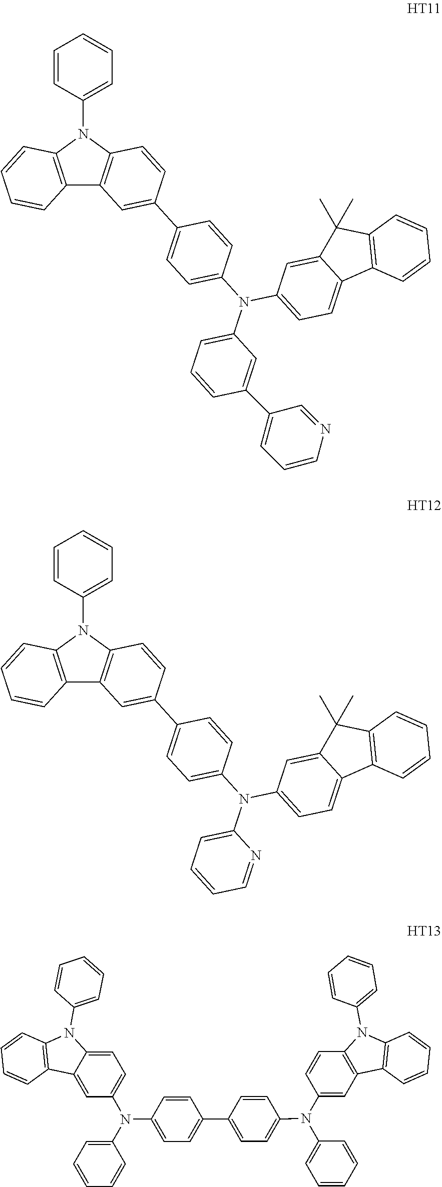 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

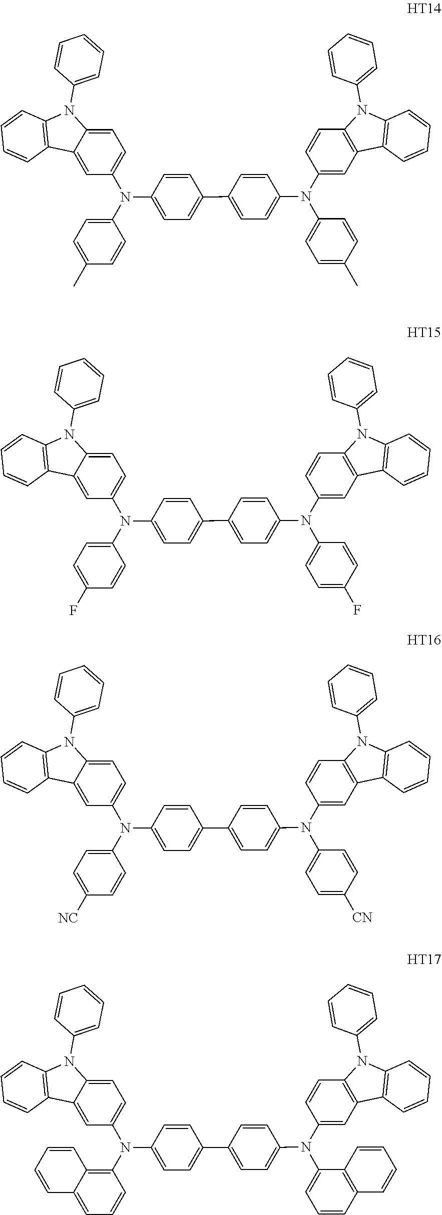 [SMILES: Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1]

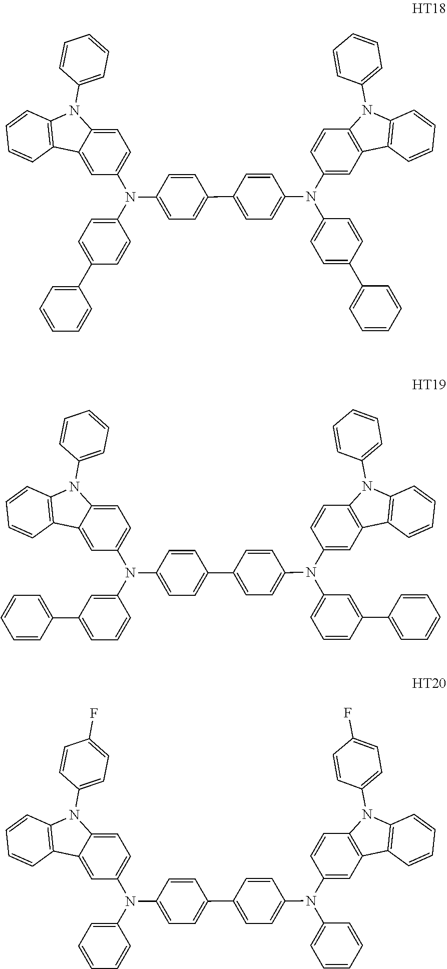 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, for example, about 100 Å to about 1,000 Å. When the hole transport region includes at least one of a hole injection layer and a hole transport layer, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be one a quinone derivative, a metal oxide, and a cyano group-containing compound, but embodiments of the present disclosure are not limited thereto. Examples of the p-dopant are: a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a cyano group-containing compound, such as Compound HT-D1 below, but are not limited thereto.

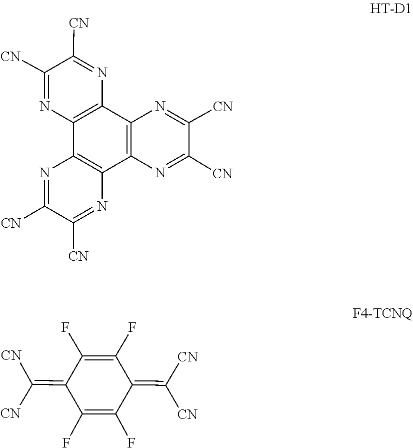

The hole transport region may include a buffer layer.

Also, the buffer layer may compensate for an optical resonance distance according to a wavelength of light emitted from the emission layer, and thus, efficiency of a formed organic light-emitting device may be improved.

Then, an emission layer (EML) may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a material that is used to form the hole transport layer.

Meanwhile, when the hole transport region includes an electron blocking layer, a material for the electron blocking layer may be materials for the hole transport region described above and materials for a host to be explained later. However, the material for the electron blocking layer is not limited thereto. For example, when the hole transport region includes an electron blocking layer, a material for the electron blocking layer may be mCP, which will be explained later.

The emission layer may include a host and a dopant, and the dopant may include the organometallic compound represented by Formula 1.

The host may include at least one of TPBi, TBADN, ADN (also referred to as “DNA”), CBP, CDBP, TCP, mCP, Compound H50, Compound H51, and Compound

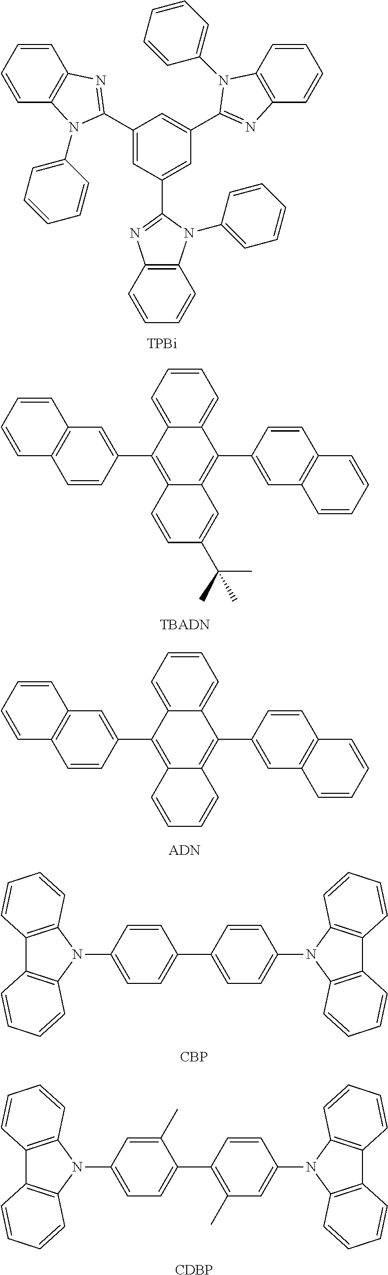

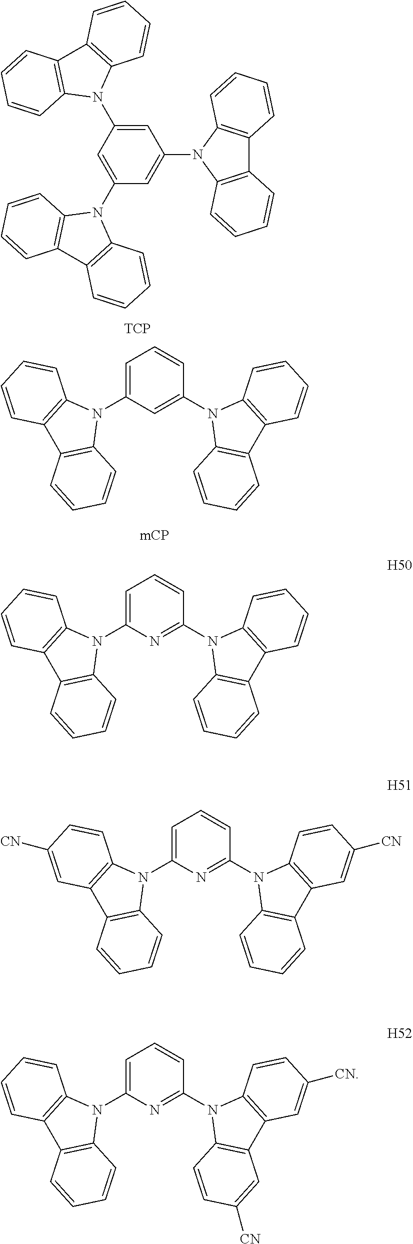

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

When the emission layer includes a host and a dopant, an amount of the dopant may be in a range of about 0.01 parts by weight to about 15 parts by weight based on 100 parts by weight of the host, but embodiments of the present disclosure are not limited thereto.

A thickness of the emission layer may be in a range of about 100 Å to about 1,000 Å, for example, about 200 Å to about 600 Å. When the thickness of the emission layer is within this range, excellent light-emission characteristics may be obtained without a substantial increase in driving voltage.

Then, an electron transport region may be located on the emission layer.

The electron transport region may include a hole blocking layer, an electron transport layer, an electron injection layer, or any combination thereof.

For example, the electron transport region may have a hole blocking layer/electron transport layer/electron injection layer structure or an electron transport layer/electron injection layer structure, and the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, at least one of BCP, Bphen, and BAlq but embodiments of the present disclosure are not limited thereto.

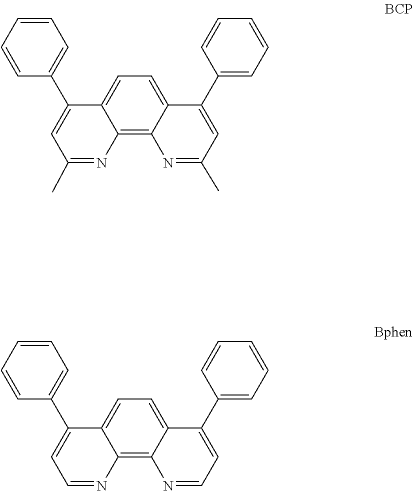 [SMILES: Cc1cc(-c2ccccc2)c2ccc3c(-c4ccccc4)cc(C)nc3c2n1 ; c1ccc(-c2ccnc3c2ccc2c(-c4ccccc4)ccnc23)cc1]

A thickness of the hole blocking layer may be in a range of about 20 Å to about 1,000 Å, for example, about 30 Å to about 300 Å. When the thickness of the hole blocking layer is within these ranges, the hole blocking layer may have excellent hole blocking characteristics without a substantial increase in driving voltage.

The electron transport layer may further include at least one of BCP, Bphen, Alq₃, BAlq, TAZ, NTAZ, or any combination thereof.

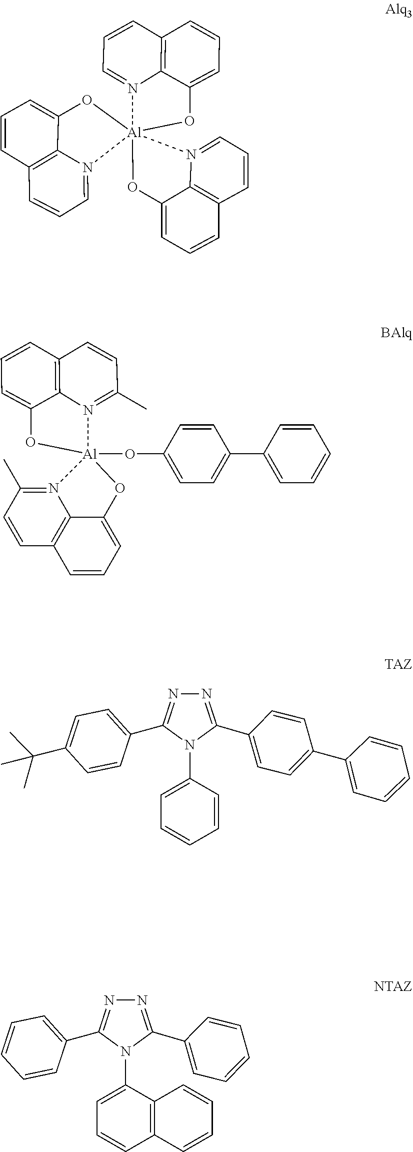

In one or more embodiments, the electron transport layer may include at least one of ET1 to ET25, but are not limited thereto:

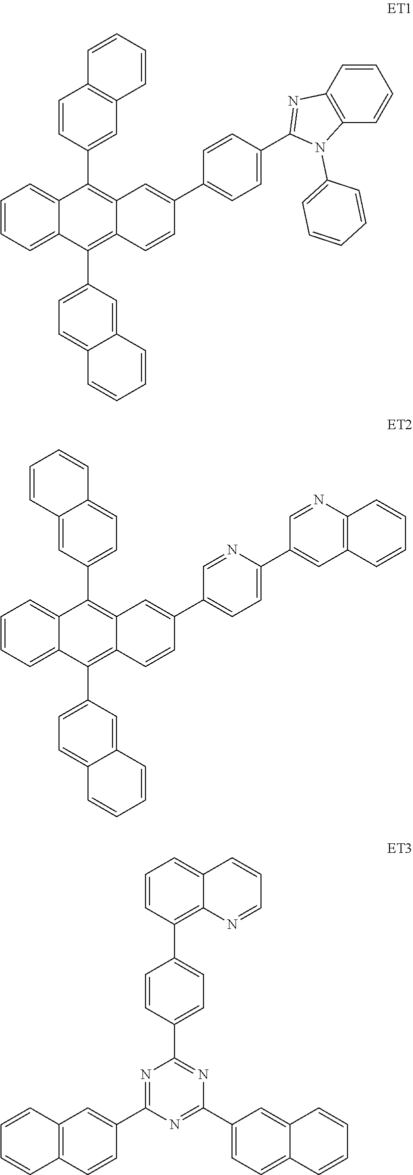 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

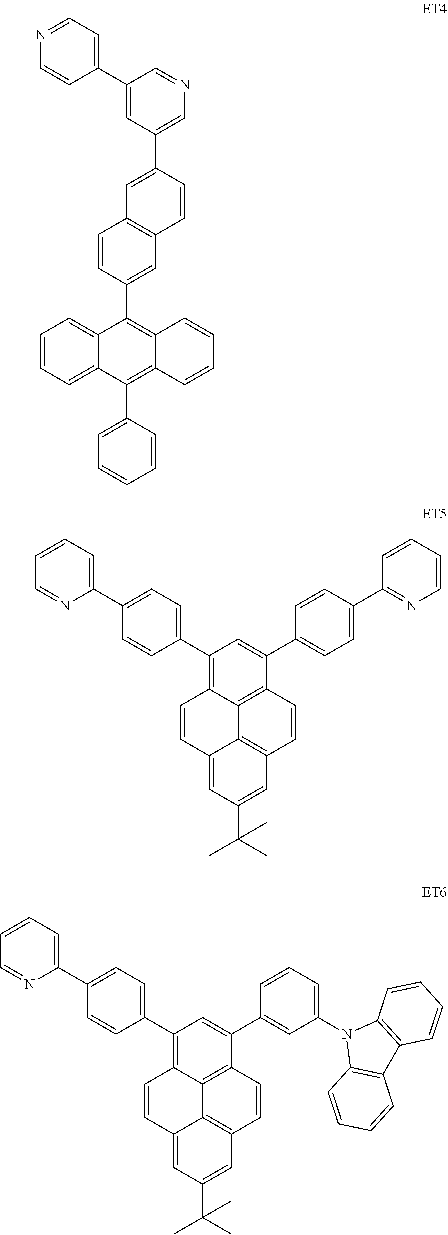 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

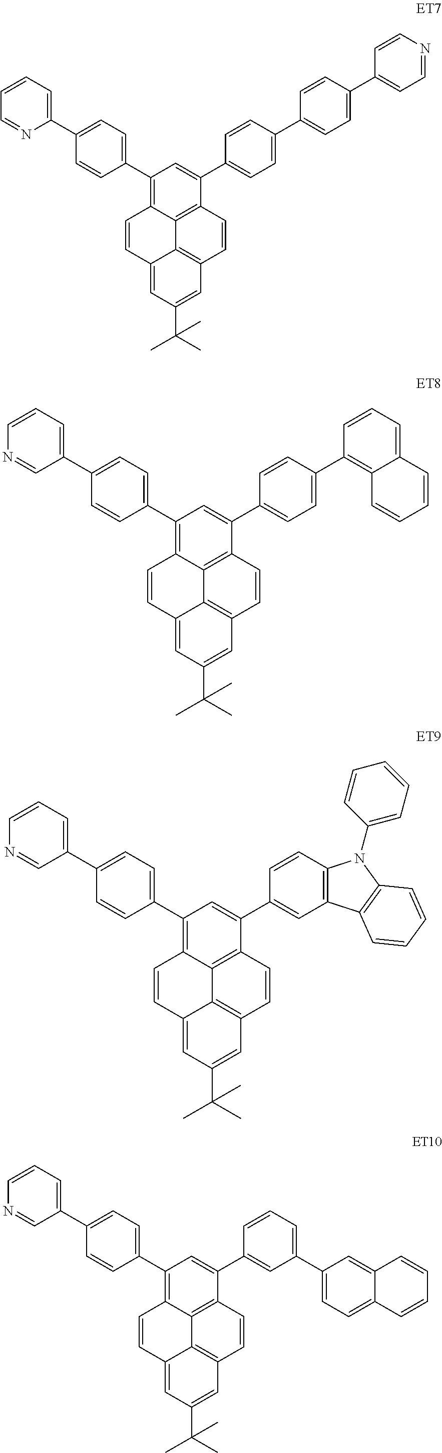 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34 ; CC(C)(C)c1cc2ccc3c(-c4ccc(-c5cccnc5)cc4)cc(-c4cccc(-c5ccc6ccccc6c5)c4)c4ccc(c1)c2c34]

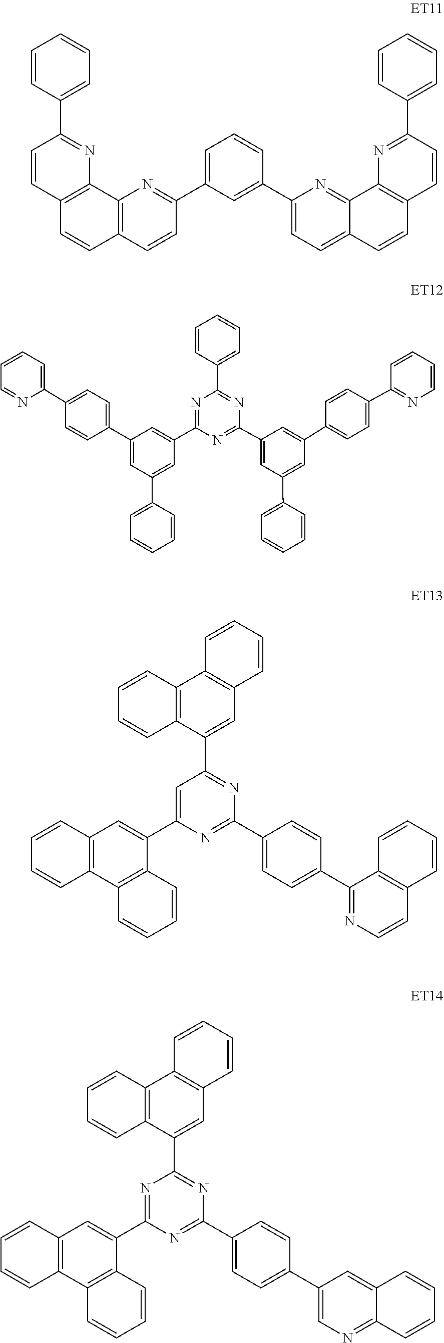 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

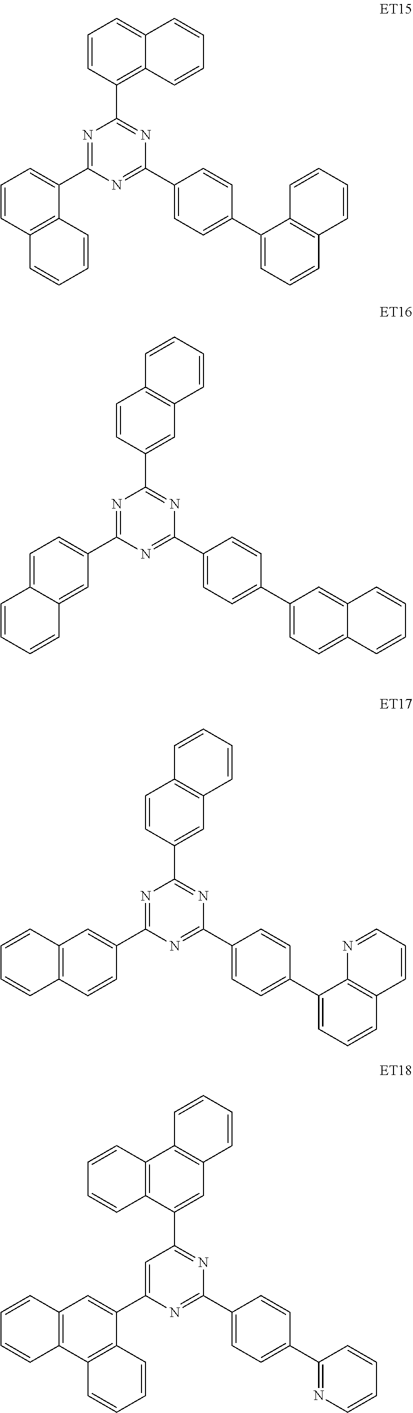 [SMILES: c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)cc(-c4cc5ccccc5c5ccccc45)n3)cc2)nc1]

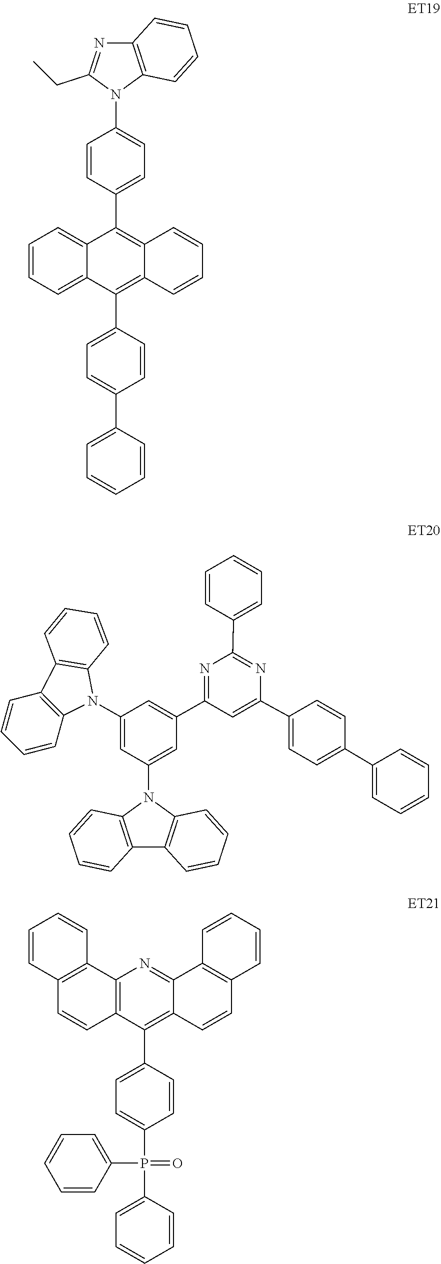 [SMILES: CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; O=P(c1ccccc1)(c1ccccc1)c1ccc(-c2c3ccc4ccccc4c3nc3c2ccc2ccccc23)cc1]

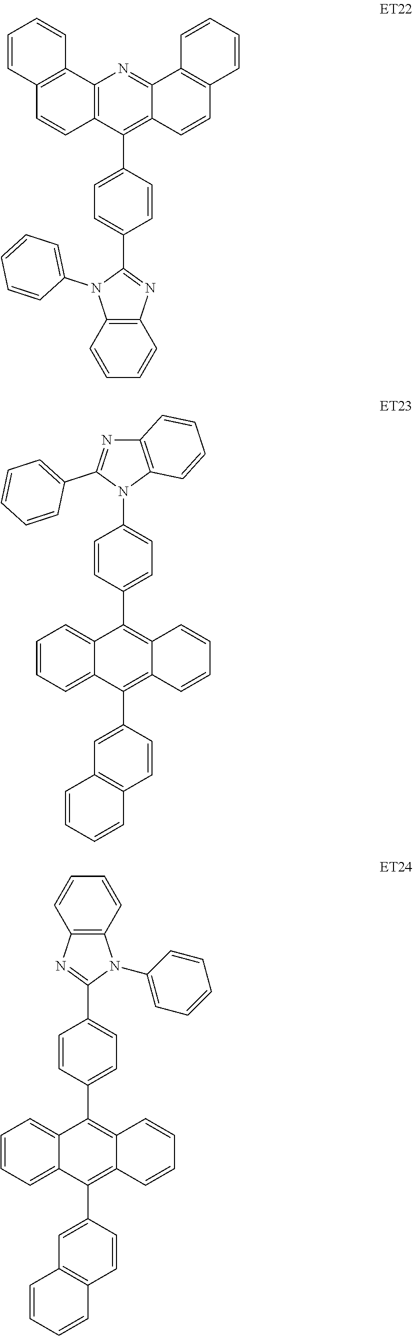

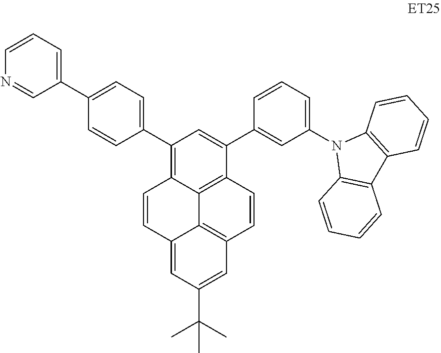 [SMILES: CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. When the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a Li complex. The Li complex may include, for example, Compound ET-D1 (lithium quinolate, LiQ) or ET-D2:

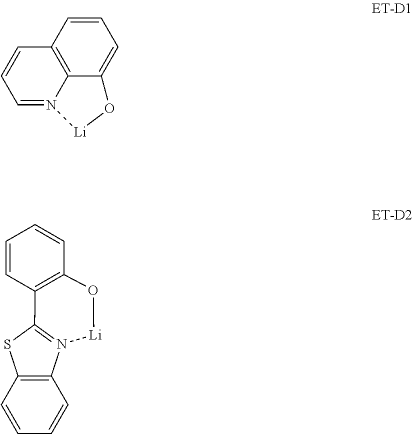

The electron transport region may include an electron injection layer (EIL) that promotes the flow of electrons from the second electrode 19 thereinto.

The electron injection layer may include at least one of LiF, NaCl, CsF, Li₂O, BaO, or any combination thereof.

A thickness of the electron injection layer may be in a range of about 1 Å to about 100 Å, and, for example, about 3 Å to about 90 Å. When the thickness of the electron injection layer is within the range described above, the electron injection layer may have satisfactory electron injection characteristics without a substantial increase in driving voltage.

The second electrode 19 is located on the organic layer 15. The second electrode 19 may be a cathode. A material for forming the second electrode 19 may be metal, an alloy, an electrically conductive compound, or a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as the material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIGURE, but embodiments of the present disclosure are not limited thereto.

Another aspect provides a diagnostic composition including at least one organometallic compound represented by Formula 1.

The organometallic compound represented by Formula 1 provides high luminescent efficiency. Accordingly, a diagnostic composition including the organometallic compound may have high diagnostic efficiency.

The diagnostic composition may be used in various applications including a diagnosis kit, a diagnosis reagent, a biosensor, and a biomarker.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an isoamyl group, and a hexyl group. The term “C₁-C₆₀ alkylene group” as used herein refers to a divalent group having the same structure as the C₁-C₆₀ alkyl group.

The term “C₁-C₆₀ alkoxy group” used herein refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having three to ten carbon, and examples thereof are a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl (bicyclo[1.1.1]pentyl) group, a bicyclo[2.1.1]hexyl(bicyclo[2.1.1]hexyl) group, a bicyclo[2.2.1]heptyl(bicyclo[2.2.1]heptyl) group, and a bicyclo[2.2.2]octyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom of N, O, P, Si, S, B, Ge, Te, or any combination thereof as a ring-forming atom and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom of N, O, P, Si, S, B, Se, Ge, Te, or any combination thereof as a ring-forming atom, 1 to 10 carbon atoms, and at least one carbon-carbon double bond in its ring. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group” as used herein refers to a monovalent group having a carbocyclic aromatic system that has at least one heteroatom of N, O, P, Si, S, B, Se, Ge, Te, or any combination thereof as a ring-forming atom, and 1 to 60 carbon atoms. The term “C₁-C₆ heteroarylene group” as used herein refers to a divalent group having a carbocyclic aromatic system that has at least one heteroatom N, O, P, and S as a ring-forming atom, and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₆-C₆₀ heteroaryl group and the C₆-C₆₀ heteroarylene group each include two or more rings, the rings may be fused to each other.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates -SA₁₀₃ (wherein A₁₀₃ is the C₆-C₆₀ aryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom of N, O, P, Si, S, B, Se, Ge, Te, or any combination thereof, other than carbon atoms, as a ring-forming atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group.

The term “C₁-C₃₀ heterocyclic group” as used herein refers to a saturated or unsaturated cyclic group having, as a ring-forming atom, at least one heteroatom of N, O, Si, P, S, B, Se, Ge, Te, or any combination thereof other than 1 to 30 carbon atoms. The C₁-C₃₀ heterocyclic group may be a monocyclic group or a polycyclic group.

At least one substituent of the substituted C₅-C₃₀ carbocyclic group, the substituted C₂-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be:

deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;

a C₁-C₆₀ alkyl group, a C₂-C₆₀ alkenyl group, a C₂-C₆₀ alkynyl group, or a C₁-C₆₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), —P(═O)(Q₁₈)(Q₁₉), or any combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), —P(═O)(Q₂₈)(Q₂₉), or any combination thereof; or

—N(Q₃₁)(Q₃₂), —Si(Q₃₃)(Q₃₄)(Q₃₅), —B(Q₃₆)(Q₃₇), or —P(═O)(Q₃₈)(Q₃₉),

wherein Q₁ to Q₉, Q₁₁ to Q₁₉, Q₂₁ to Q₂₉ and Q₃₁ to Q₃₉ used herein may each independently be selected from: hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group and a C₆-C₆₀ aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group.

Hereinafter, a compound and an organic light-emitting device according to embodiments are described in detail with reference to Synthesis Example and Examples. However, the organic light-emitting device is not limited thereto. The wording “B was used instead of A” used in describing Synthesis Examples means that an amount of A used was identical to an amount of B used, in terms of a molar equivalent.

### EXAMPLES

### Synthesis Example 1 (Compound 110)

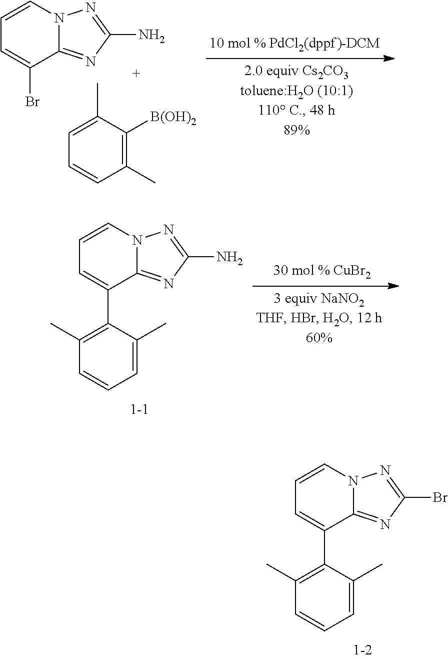

### Synthesis of Compound 1-1 (8-(2,6-dimethylphenyl)-[1,2,4]triazolo[1,5-a]pyridin-2-amine)

In a glove box, 8-bromo-[1,2,4]triazolo[1,5-a]pyridin-2-amine (100 mg, 0.472 mmol), (2,6-dimethylphenyl)boronic acid (84.9 mg, 0.566 mmol), Pd(pph₃)₄ (54.5 mg, 0.0471 mmol), and Cs₂CO₃ (307 mg, 0.944 mmol) were added to a sealed tube, which was then sealed by using a rubber septa. Then, the sealed tube was taken out of the glove box. After the sealed tube containing the reactants was flushed with nitrogen gas for 5 minutes, 2.4 mL of toluene and 0.24 mL of degassed H₂O were added thereto. The reaction mixture was stirred at 110° C. for 48 hours. After the reaction, the solution was cooled to room temperature, 4 mL of H₂O was added thereto, and an extraction process was performed thereon three times by using CH₂Cl₂ (3×2 mL) to obtain an organic layer, to which MgSO₄ was then added to remove water therefrom. Then, the resultant was filtered and concentrated. The concentrated reaction product was separated by silica gel column chromatography (CH₂Cl₂:EtOAc=10:1) to obtain a white solid compound represented by Formula 1-1: 8-(2,6-dimethylphenyl)-[1,2,4]triazolo[1,5-a]pyridin-2-amine (100 mg, 0.4198 mmol, 89%). ¹H NMR (400 MHz, CDCl₃): δ 8.34 (d, J=6.4 Hz, 1H), 7.26-7.22 (m, 1H), 7.20 (d, J=7.3 Hz, 1H), 7.15 (d, J=7.3 Hz, 2H), 6.92 (t, J=7.1 Hz, 1H), 4.53 (s, 2H), 2.05 (s, 6H); ¹³C NMR (100 MHz, CDCl₃): δ 165.4, 150.1, 136.6, 135.0, 129.4, 128.3, 127.6, 127.0, 126.2, 111.6, 20.3.

### Synthesis of Compound 1-2 (2-bromo-8-(2,6-dimethylphenyl)-[1,2,4]triazolo[1,5-a]pyridine)

In a glove box, 8-(2,6-dimethylphenyl)-[1,2,4]triazolo[1,5-a]pyridin-2-amine (1-1, 101 mg, 0.423 mmol), CuBr₂ (18.2 mg, 0.127 mmol), and NaNO₂ (87.6 mg, 1.27 mmol) were added to a 8 mL vial (product of Kimax), and then sealed by using a phenolic open top cap with gray PTFE/silicone. Then, the vial was taken out of the glove box. The vial containing the reactants was flushed with nitrogen gas for 5 minutes, and then, 1 mL of THF, 1 mL of degassed H₂O and 1 mL of HBr were added to the reaction vessel. After the reaction mixture was stirred for 12 hours at room temperature, 5 mL of 10% NaOH was added to the reaction solution to terminate the reaction, followed by extraction three times with 3 mL of EtOAc. MgSO₄ was added to an organic layer solution to remove water therefrom, followed by filtration and concentration. The concentrated reaction product was separated by silica gel column chromatography (hexanes:EtOAc=3:1) to obtain a white solid compound represented by Formula 1-2: 2-bromo-8-(2,6-dimethylphenyl)-[1,2,4]triazolo[1,5-a]pyridine (76.4 mg, 0.254 mmol, 60%). ¹H NMR (400 MHz, CDCl₃): δ 8.57 (dd, J=6.9, 1.4 Hz, 1H), 7.38 (dd, J=7.3, 1.4 Hz, 1H), 7.25-7.23 (m, 1H), 7.17-7.13 (m, 3H), 2.03 (s, 6H); ¹³C NMR (100 MHz, CDCl₃): δ 150.8, 145.0, 136.4, 133.8, 130.8, 129.4, 128.7, 127.8, 126.9, 114.2, 20.4.

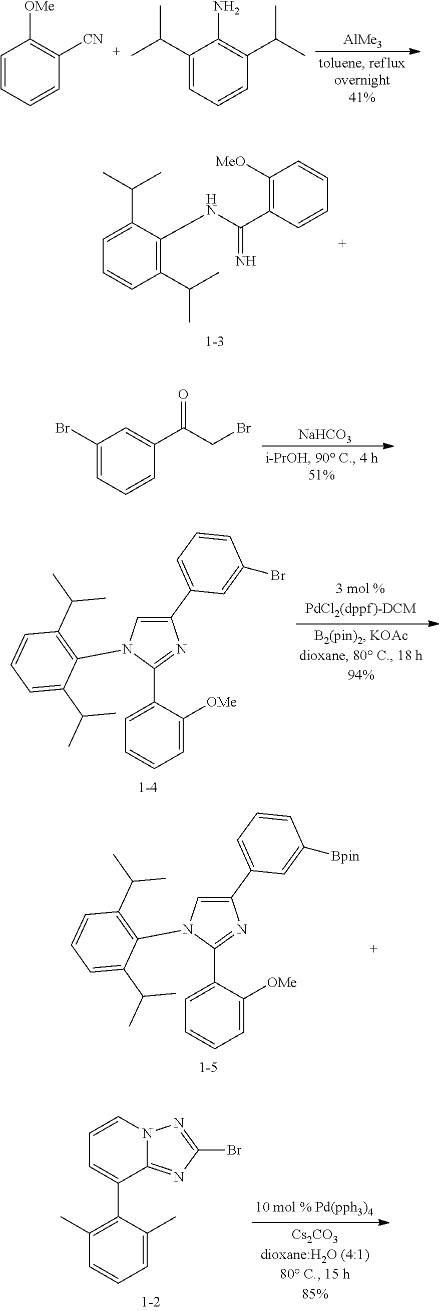

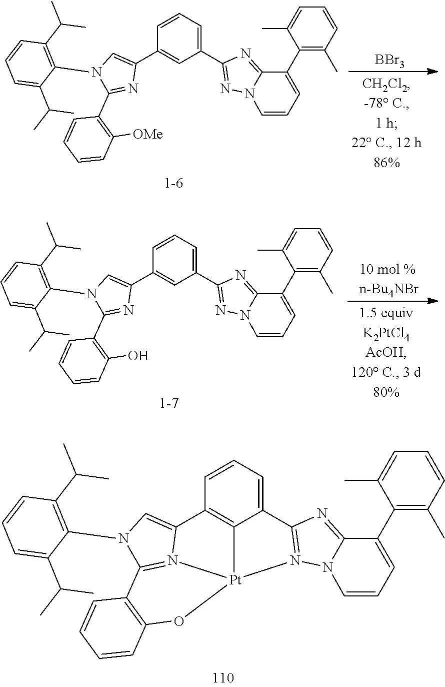

### Synthesis of Compound 1-3 (N-(2,6-diisopropylphenyl)-2-methoxybenzimidamide)

Diisopropylaniline (3.12 mL, 16.5 mmol) and a magnetic bar were added to a 250 mL round-bottom flask, and 87 mL of toluene was added under nitrogen atmosphere. After cooling the reaction solution to the temperature of 0° C. using an ice water bath, AlMe₃ (2.0 M in toluene, 11.3 mL, 22.5 mmol) was added thereto. After the reaction mixture was stirred at room temperature for 2 hours, a solution of 2-methoxybenzonitrile (2.00 g, 15.0 mmol) dissolved in 25.8 mL of toluene was added to the mixture and stirred at 100° C. for 10 hours. After lowering the reaction temperature to room temperature, silica gel slurry (CH₂Cl₂:MeOH=2:1) was poured into the reaction solution and stirred for 15 minutes. After the stirring, filtration was performed using silica gel slurry while a solution of CH₂Cl₂ and MeOH at the volumetric ratio of 2:1 was allowed to pass therethrough. MgSO₄ was added to the filtrate to remove water therefrom, and then filtered again and concentrated. Hexane was added to the concentrated reaction product to perform a recrystallization process to obtain a white solid compound represented by Formula 1-3: N-(2,6-diisopropylphenyl)-2-methoxybenzimidamide (3.87 g, 12.5 mmol, 41%). ¹H NMR (400 MHz, CDCl₃): δ 8.28 (dt, J=7.2, 1.8 Hz, 1H), 7.49-7.44 (m, 1H), 7.23 (dd, J=7.5, 2.1 Hz, 2H), 7.16-7.11 (m, 2H), 7.03 (d, J=8.7 Hz, 1H), 5.29 (br s, 2H), 3.94 (d, J=1.4 Hz, 3H), 3.22-3.15 (m, 2H), 1.29-1.25 (m, 12H); ¹³C NMR (100 MHz, CDCl₃): δ 157.2, 152.7, 144.0, 139.4, 131.1, 131.0, 124.0, 123.2, 121.2, 111.5, 55.7, 28.0, 23.6, 23.6.

### Synthesis of Compound 1-4 (4-(3-bromophenyl)-1-(2,6-diisopropylphenyl)-2-(2-methoxyphenyl)-1H-imidazole)

N-(2,6-diisopropylphenyl)-2-methoxybenzimidamide (1-3, 912 mg, 2.94 mmol) and NaHCO₃ (740 mg, 8.81 mmol) were added to a 25 mL round-bottom flask, and then, 4.2 mL of i-PrOH was added thereto under nitrogen atmosphere. After the reaction mixture was stirred at 50° C. for 30 minutes, 3-bromophenacyl bromide (408 mg, 1.47 mmol) was added thereto, and the mixture was stirred at 90° C. for 1 hour. 3-bromophenacyl bromide (408 mg×3, 1.47 mmol×3) was added three times every hour. After lowering the temperature of the reaction solution to room temperature, a saturated NaHCO₃ aqueous solution (10 mL) was added thereto terminate the reaction, followed by extraction with CH₂Cl₂ (3×5 mL). MgSO₄ was added to a collected organic layer solution to remove water therefrom, followed by filtration and concentration of the filtrate. The concentrated reaction product was separated by silica gel column chromatography (hexanes:EtOAc=5:1) to obtain a yellow solid compound represented by Formula 1-4: 4-(3-bromophenyl)-1-(2,6-diisopropylphenyl)-2-(2-methoxyphenyl)-1H-imidazole (739 mg, 1.51 mmol, 52%). 1H NMR (400 MHz, CDCl₃): δ 8.10 (d, J=1.8 Hz, 1H), 7.82 (d, J=7.8 Hz, 1H), 7.38 (d, J=7.8 Hz, 1H), 7.32 (t, 1H), 7.29 (s, 1H), 7.30-7.23 (m, 1H), 7.25-7.23 (m, 1H), 7.14 (d, J=7.8 Hz, 2H), 7.09 (dd, J=7.8, 0.9 Hz, 1H), 6.85 (d, J=8.2 Hz, 1H), 6.78 (td, J=7.5, 0.9 Hz, 1H), 3.73 (s, 3H), 2.71 (quint, J=6.7 Hz, 2H), 1.13 (d, J=6.9 Hz, 6H), 1.03 (d, J=6.9 Hz, 6H); ¹³C NMR (100 MHz, CDCl₃): δ 158.0, 146.1, 136.4, 133.1, 131.7, 130.6, 130.0, 129.5, 129.4, 127.9, 123.6, 123.5, 122.8, 119.7, 119.1, 118.8, 111.1, 55.6, 28.0, 26.2, 22.5.

### Synthesis of Compound 1-5 (1-(2,6-diisopropylphenyl)-2-(2-methoxyphenyl)-4-(3-(4,4,5,5-tetramethyl-1,3,2-dioxaborolan-2-yl)phenyl)-1H-imidazole)

In a glove box, 4-(3-bromophenyl)-1-(2,6-diisopropylphenyl)-2-(2-methoxyphenyl)-1H-imidazole (1-4, 101 mg, 0.423 mmol), CuBr₂ (18.2 mg, 0.127 mmol), and PdCl₂(dppf)DCM (5.00 mg, 0.0122 mmol) were added to a 8 mL vial (product of Kimax) and then, sealed by using a phenolic open top cap with gray PTFE/silicone. Then, the vial was taken out of the glove box. The vial containing the reactants was flushed with nitrogen gas for 5 minutes, and then, 0.68 mL of dioxane was added to dioxane under nitrogen atmosphere. After the reaction mixture was stirred at 80° C. for 18 hours, the reaction temperature was lowered to room temperature, and 2 mL of saturated NaHCO₃ aqueous solution was added to the reaction solution, followed by extraction three times with 2 mL of CH₂Cl₂. MgSO₄ was added to a collected organic layer solution to remove water therefrom, followed by filtration and concentration of the filtrate. The concentrated reaction product was separated by silica gel column chromatography (hexanes:EtOAc=8:1) to obtain a white solid compound represented by Formula 1-5: 1-(2,6-diisopropylphenyl)-2-(2-methoxyphenyl)-4-(3-(4,4,5,5-tetramethyl-1,3,2-dioxaborolan-2-yl)phenyl)-1H-imidazole (154 mg, 0.288 mmol, 94%). ¹H NMR (400 MHz, CDCl₃): δ 8.28 (s, 1H), 8.09 (d, J=7.8 Hz, 1H), 7.71 (d, J=7.3 Hz, 1H), 7.42 (t, J=7.5 Hz, 1H), 7.34 (s, 1H), 7.31 (t, J=7.8 Hz, 1H), 7.26-7.21 (m, 1H), 7.13 (d, J=7.8 Hz, 3H), 6.84 (d, J=8.2 Hz, 1H), 6.77 (t, J=7.5 Hz, 1H), 3.71 (s, 3H), 2.74 (quint, J=6.7 Hz, 2H), 1.35 (s, 12H), 1.13 (d, J=6.4 Hz, 6H), 1.03 (d, J=6.9 Hz, 6H); ¹³C NMR (100 MHz, CDCl₃): δ 146.2, 141.0, 133.7, 133.2, 132.0, 131.4, 131.4, 130.4, 129.3, 127.9, 127.6, 123.6, 119.7, 119.6, 118.5, 111.1, 83.7, 55.6, 28.1, 28.0, 26.2, 24.9, 24.8, 24.5, 22.6.

### Synthesis of Compound 1-6 (2-(3-(1-(2,6-diisopropylphenyl)-2-(2-methoxyphenyl)-1H-imidazol-4-yl)phenyl)-8-(2,6-dimethylphenyl)-[1,2,4]triazolo[1,5-a]pyridine)

In a glove box, 2-(2-methoxyphenyl)-1-methyl-4-(3-(4,4,5,5-tetramethyl-1,3,2-dioxaborolan-2-yl)phenyl)-1H-imidazole (1-5, 243 mg, 0.453 mmol), 2-bromo-8-(2,6-dimethylphenyl)-[1,2,4]triazolo[1,5-a]pyridine (1-2, 150 mg, 0.498 mmol), PdCl₂(dppf)DCM (74.0 mg, 0.0906 mmol), and CS₂CO₃ (295 mg, 0.906 mmol) were added to 25 mL KIMAX vial, and then, sealed by using a phenolic open top cap with gray PTFE/silicone. Then, the vial was taken out of the glove box. The vial containing the reactants was flushed with nitrogen gas for 5 minutes, and then 3 mL of dioxane and 0.75 mL of degassed H₂O were added thereto. After the reaction mixture was stirred at 80° C. for 15 hours, the reaction temperature was lowered to room temperature, and 5 mL of saturated NH₄Cl aqueous solution was added to the reaction solution, followed by extraction three times with 3 mL of CH₂Cl₂. MgSO₄ was added to a collected organic layer solution to remove water therefrom, followed by filtration and concentration of he filtrate. The concentrated reaction product was separated by silica gel column chromatography (hexanes:EtOAc=3:1) to obtain a white solid compound represented by Formula 1-6: 2-(3-(1-(2,6-diisopropylphenyl)-2-(2-methoxyphenyl)-1H-imidazol-4-yl)phenyl)-8-(2,6-dimethylphenyl)-[1,2,4]triazolo[1,5-a]pyridine (238 mg, 0.385 mmol, 85%). ¹H NMR (400 MHz, CDCl₃): δ 8.65-8.63 (m, 2H), 8.14 (td, J=6.2, 1.8 Hz, 2H), 7.50 (td, J=7.8 Hz, 1H), 7.43 (s, 1H), 7.33-7.29 (m, 2H), 7.26-7.22 (m, 2H), 7.19-7.17 (m, 2H), 7.14 (d, J=7.8 Hz, 3H), 7.07 (d, J=6.9 Hz, 1H), 6.85 (d, J=8.7 Hz, 1H), 6.78 (t, J=7.5 Hz, 1H), 3.71 (s, 3H), 2.75 (quint, J=6.7 Hz, 2H), 2.10 (s, 6H), 1.14 (d, J=6.9 Hz, 6H), 1.03 (d, J=6.9 Hz, 6H); ¹³C NMR (100 MHz, CDCl₃): δ 164.6, 158.1, 150.8, 146.2, 145.8, 140.8, 136.8, 134.7, 133.4, 132.0, 131.9, 131.1, 130.4, 129.7, 129.7, 129.3, 128.8, 128.2, 127.6, 127.2, 127.0, 126.1, 124.0, 123.6, 119.7, 119.6, 118.9, 113.2, 111.2, 55.7, 28.0, 26.2, 22.6, 20.6.

### Synthesis of Compound 1-7 (2-(1-(2,6-diisopropylphenyl)-4-(3-(8-(2,6-dimethylphenyl)-[1,2,4]triazolo[1,5-a]pyridin-2-yl)phenyl)-1H-imidazol-2-yl)phenol)

2-(3-(1-(2,6-Diisopropylphenyl)-2-(2-methoxyphenyl)-1H-imidazol-4-yl)phenyl)-8-(2,6-dimethylphenyl)-[1,2,4]triazolo[1,5-a]pyridine (1-6, 100 mg, 0.158 mmol), and 2.3 mL of CH₂Cl₂ were added to a sealed tube. After lowering the reaction temperature to −78° C., BBr₃ (68.6 μL, 0.713 mmol) was added thereto. After the reaction mixture was stirred for 12 hours at room temperature, 5 mL of saturated NaHCO₃ aqueous solution and 1 mL of MeOH were added to terminate the reaction. The resultant solution was washed three times with 3 mL of CH₂Cl₂, and then, MgSO₄ was added to an organic layer to remove water therefrom, and then, the mixture was filtered and concentrated. The concentrated reaction product was separated by silica gel column chromatography (hexanes:EtOAc=8:1) to obtain an ivory solid compound represented by Formula 1-7: 2-(1-(2,6-diisopropylphenyl)-4-(3-(8-(2,6-dimethylphenyl)-[1,2,4]triazolo[1,5-a]pyridin-2-yl)phenyl)-1H-imidazol-2-yl)phenol (84.1 mg, 0.138 mmol, 86%). ¹H NMR (400 MHz, CDCl₃): δ 8.67 (d, J=6.9 Hz, 1H), 8.57 (s, 1H), 8.20 (d, J=7.8 Hz, 1H), 8.05 (d, J=7.8 Hz, 1H), 7.55 (td, J=7.7, 1.6 Hz, 2H), 7.36 (s, 1H), 7.34 (s, 2H), 7.33-7.30 (m, 2H), 7.20 (s, 1H), 7.18 (s, 1H), 7.14 (dd, J=6.9, 1.4 Hz, 1H), 7.11 (t, J=6.9 Hz, 1H), 7.08-7.05 (m, 1H), 6.57 (dd, J=7.8, 1.4 Hz, 1H), 6.46 (td, J=7.7, 1.1 Hz, 1H), 2.57 (quint, J=6.9 Hz, 2H), 2.10 (s, 6H), 1.16 (d, J=6.9 Hz, 6H), 0.96 (d, J=6.9 Hz, 6H); ¹³C NMR (100 MHz, CDCl₃): δ 164.2, 158.4, 150.8, 146.0, 145.9, 138.2, 136.8, 135.0, 134.3, 132.8, 131.4, 130.4, 130.2, 129.9, 129.8, 129.1, 128.3, 127.6, 127.2, 126.8, 126.5, 124.7, 123.8, 118.6, 117.9, 117.7, 113.4, 113.0, 28.3, 24.7, 23.0, 20.6.

### Synthesis of Compound 110

In a glove box, 2-(1-(2,6-diisopropylphenyl)-4-(3-(8-(2,6-dimethylphenyl)-[1,2,4]triazolo[1,5-a]pyridin-2-yl)phenyl)-1H-imidazol-2-yl)phenol (1-7, 100 mg, 0.162 mmol), K₂PtCl₄ (101 mg, 0.243 mmol), and tetrabutylammonium bromide (5.22 mg, 0.0162 mmol) were added to a sealed tube, and then, sealed by using a rubber septa, and then, the sealed tube was taken out of the glove box. After nitrogen gas was blown through the sealed tube containing the reactants for 5 minutes, 5.4 mL of degassed AcOH was added thereto. After the reaction mixture was stirred at 120° C. for 3 days, the reaction temperature was lowered to room temperature, and 10 mL of a saturated Na₂CO₃ aqueous solution was added to terminate the reaction. The resultant solution was washed three times with 5 mL of CH₂Cl₂, and then, MgSO₄ was added to an organic layer to remove water therefrom, and then, the mixture was filtered and concentrated. The concentrated reaction product was separated by silica gel column chromatography (hexanes:EtOAc=10:1) to obtain Compound 110 (105 mg, 0.130 mol, 80%), which was a yellow solid. ¹H NMR (400 MHz, CDCl₃): δ 9.15 (dd, J=6.4, 1.4 Hz, 1H), 7.76 (d, J=7.3 Hz, 1H), 7.61 (t, J=7.7 Hz, 1H), 7.51-7.47 (m, 2H), 7.45-7.43 (m, 2H), 7.41-7.39 (m, 2H), 7.36-7.32 (m, 1H), 7.25-7.23 (m, 4H), 7.08 (s, 1H), 6.93 (dd, J=8.2, 1.8 Hz, 1H), 6.28 (ddd, J=8.2, 6.9, 1.4 Hz, 1H), 2.65 (quint, J=6.9 Hz, 2H), 2.13 (s, 6H), 1.18 (d, J=6.9 Hz, 6H), 1.02 (d, J=6.9 Hz, 6H); ¹³C NMR (100 MHz, CDCl₃): δ 175.1, 165.2, 154.9, 149.2, 146.1, 139.1, 136.7, 136.3, 135.0, 133.8, 131.4, 131.2, 130.6, 130.4, 130.2, 128.8, 127.8, 125.9, 125.8, 124.8, 123.0, 122.9, 121.6, 117.1, 115.4, 113.7, 112.8, 29.6, 28.4, 24.6, 23.1, 20.5.

### Synthesis Example 2 (Compound 111)

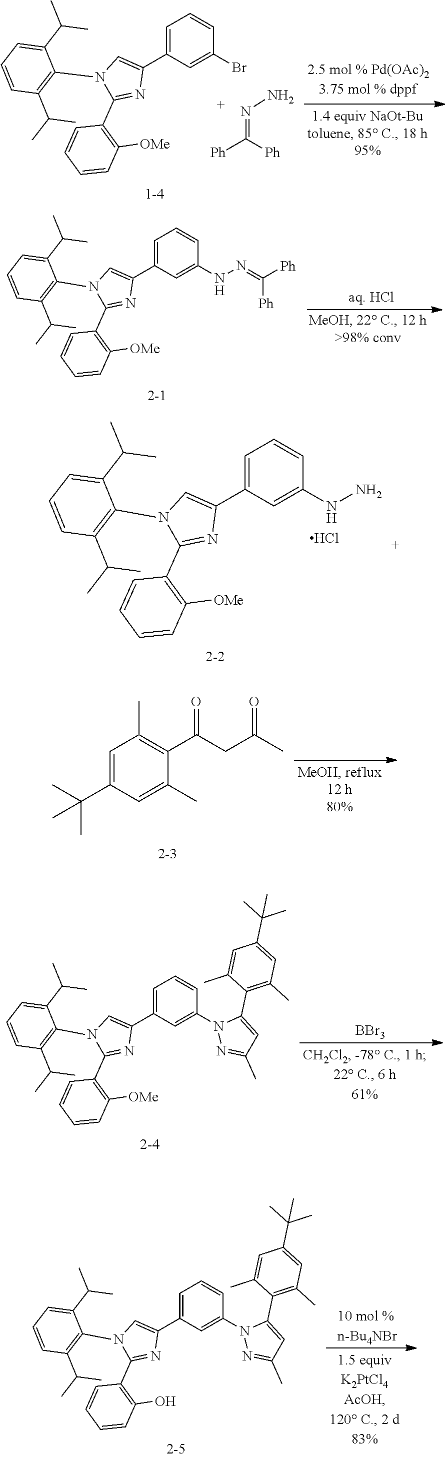

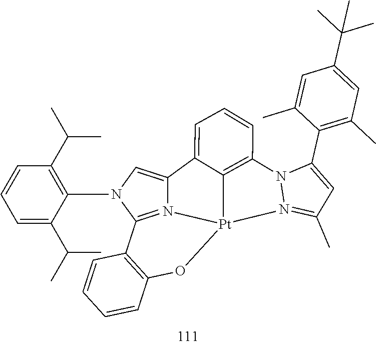

### Synthesis of Compound 2-1 (1-(2,6-diisopropylphenyl)-4-(3-(2-(diphenylmethylene)hydrazinyl)phenyl)-2-(2-methoxyphenyl)-1H-imidazole)

In a glove box, 4-(3-bromophenyl)-1-(2,6-diisopropylphenyl)-2-(2-methoxyphenyl)-1H-imidazole (1-4, 100 mg, 0.204 mmol), (diphenylmethylene)hydrazine (52.1 mg, 0.266 mmol), Pd(OAc)₂ (1.20 mg, 5.11×10⁻³ mmol), 1,1′-ferrocenediyl-bis(diphenylphosphine) (dppf, 4.20 mg, 7.66×10⁻³ mmol), NaOt-Bu (27.5 mg, 0.286 mmol), and a magnetic bar were added to a 8 mL KIMAX vial, and then, sealed by using a phenolic open top cap with gray PTFE/silicone. Then, the vial was taken out of the glove box. Nitrogen gas was blown into the vial containing the reactants for 5 minutes, and then, 1.3 mL of toluene was added thereto under nitrogen atmosphere. The reaction mixture was stirred for 18 hours at 85° C., and then slowly cooled to at room temperature. Then, the solvent was removed therefrom by distillation under reduced pressure. The remaining reaction product after reduced-pressure distillation was purified by silica gel column chromatography (hexanes:EtOAc=1:1+1% Et₃N) to obtain a yellow solid compound represented by Formula 2-1: 1-(2,6-diisopropylphenyl)-4-(3-(2-(diphenylmethylene)hydrazinyl)phenyl)-2-(2-methoxyphenyl)-1H-imidazole (128 mg, 0.212 mmol, 95%). ¹H NMR (400 MHz, CDCl₃): δ 7.66-7.57 (m, 5H), 7.55-7.51 (m, 1H), 7.46 (t, J=1.6, 1H), 7.40-7.27 (m, 10H), 7.23 (td, J=8.0, 1.9, 1H), 7.15 (s, 1H), 7.13 (s, 1H), 7.10 (dd, J=7.8, 1.8, 1H), 6.84 (d, J=8.2, 1H), 6.77 (t, J=7.5, 1H), 3.70 (s, 3H), 2.75 (quint, J=6.9, 2H), 1.14 (d, J=6.9, 6H), 1.04 (d, J=6.9, 6H); ¹³C NMR (100 MHz, CDCl₃): δ 158.1, 146.2, 145.6, 144.9, 143.9, 140.9, 138.4, 134.9, 133.3, 132.8, 131.8, 130.4, 129.7, 129.5, 129.3, 129.2, 129.0, 1281, 127.8, 126.3, 123.6, 119.6, 119.5, 118.4, 116.6, 111.0, 110.9, 109.9, 55.5, 27.9, 26.2, 22.5.

### Synthesis of Compound 2-4 (5-(4-(tert-butyl)-2,6-dimethylphenyl)-1-(3-(1-(2,6-diisopropylphenyl)-2-(2-methoxyphenyl)-1H-imidazol-4-yl)phenyl)-3-methyl-1H-pyrazole)

1-(2,6-Diisopropylphenyl)-4-(3-(2-(diphenylmethylene)hydrazinyl)phenyl)-2-(2-methoxyphenyl)-1H-imidazole (2-1, 300 mg, 0.496 mmol) was a 25 mL round-bottom flask which had been dried, and then, under nitrogen atmosphere, aq.HCl/EtOH (10/1, 7.8 mL) was added thereto. The reaction mixture was stirred at room temperature for 24 hours. Thereafter, the reaction mixture was extracted with CH₂Cl₂ (10 mL×3), MgSO₄ was added to the obtained organic layer solution to remove water therefrom. Then, the filtrate obtained by filtration was concentrated. The concentrated reaction product was dissolved in 1 mL of CH₂Cl₂, and then, subjected to trituration using Et₂O to obtain a solid, which was then filtered to obtain a white solid compound represented by Formula 2-2: 1-(3-(1-(2,6-diisopropylphenyl)-2-(2-methoxyphenyl)-1H-imidazol-4-yl)phenyl)hydrazin-1-ium chloride (236 mg, 0.486 mmol, 98%).

The synthesized compound represented by Formula 2-2 (351 mg, 0.736 mmol) was added to a 25 mL round-bottom flask, and then, under nitrogen atmosphere, 9 mL of MeOH was added thereto. (Z)-1-(4-(tert-butyl)-2,6-dimethylphenyl)butane-1,3-dione (2-3, 362 mg, 1.47 mmol) dissolved in 1 mL of MeOH at room temperature and 1 mL of aq.HCl were added to a reaction flask, and then, after a reflux condenser was installed, the reaction temperature was raised to 75° C. and then, at the temperature, stirred for 12 hours. After the reaction temperature was gradually lowered to room temperature, a 40 mL of saturated NaHCO₃ aqueous solution was added to the reaction mixture to terminate the reaction and the reaction mixture was extracted using CH₂Cl₂ (10×3 mL), and then, MgSO₄ was added to the combined organic layers to remove water therefrom. Then, the filtrate obtained by filtration was concentrated. The concentrated reaction product was purified by silica gel column chromatography (hexanes:EtOAc=3:1) to obtain a light yellow solid compound represented by Formula 2-4: 5-(4-(tert-butyl)-2,6-dimethylphenyl)-1-(3-(1-(2,6-diisopropylphenyl)-2-(2-methoxyphenyl)-1H-imidazol-4-yl)phenyl)-3-methyl-1H-pyrazole (383 mg, 0.588 mmol, 80%). ¹H NMR (400 MHz, CDCl₃): δ 7.88 (d, J=7.3 Hz, 1H), 7.51 (s, 1H), 7.31-7.25 (m, 3H), 7.21 (td, J=7.8, 1.4 Hz, 1H), 7.11 (d, J=7.8 Hz, 2H), 7.06 (s, J=7.5, 1.6 Hz, 1H), 7.01 (s, 2H), 6.82 (d, J=8.7 Hz, 1H), 6.78 (s, 1H), 6.74 (t, J=7.5 Hz, 1H), 6.09 (s, 1H), 3.68 (s, 3H), 2.66 (quint, J=6.9 Hz, 2H), 2.41 (s, 3H), 2.05 (s, 6H), 1.13 (s, 9H), 1.11 (d, J=6.9 Hz, 6H), 0.99 (d, J=6.9 Hz, 6H); ¹³C NMR (100 MHz, CDCl₃): δ 158.0, 151.5, 148.9, 145.8, 145.6, 141.3, 140.5, 140.4, 137.1, 134.8, 133.2, 131.7, 130.3, 129.2, 129.0, 128.5, 124.4, 123.5, 123.1, 120.2, 120.0, 119.4, 118.5, 118.1, 111.1, 108.3, 55.5, 34.1, 31.0, 27.9, 26.0, 22.5, 20.6, 13.7.

### Synthesis of Compound 2-5 (2-(4-(3-(5-(4-(tert-butyl)-2,6-dimethylphenyl)-3-methyl-1H-pyrazol-1-yl)phenyl)-1-(2,6-diisopropylphenyl)-1H-imidazol-2-yl)phenol)

5-(4-(tert-Butyl)-2,6-dimethylphenyl)-1-(3-(1-(2,6-diisopropylphenyl)-2-(2-methoxyphenyl)-1H-imidazol-4-yl)phenyl)-3-methyl-1H-pyrazole (2-4, 100 mg, 0.154 mmol) and 2.3 mL of CH₂Cl₂ were, under nitrogen atmosphere, added to a 10 mL round-bottom flask, and then, the reaction temperature was lowered to −78° C., and then, BBr₃ (68.6 μL, 0.713 mmol) was gradually added thereto. The reaction mixture was stirred at −78° C. for 1 hour, and then, further stirred for 6 hours at room temperature. 3 mL of saturated aqueous NaHCO₃ solution was added to the reaction solution at −78° C. to terminate the reaction. Then, the reaction temperature was slowly raised to room temperature, and then, the resultant mixture was further stirred for 30 minutes to terminate the reaction completely. The reaction mixture was extracted using CH₂Cl₂ (2×3 mL) and MgSO₄ was added to the combined organic layers to remove water therefrom, and then, the filtrate obtained by filtration was concentrated. The concentrated reaction product was purified by silica gel column chromatography (hexanes:EtOAc=3:1+1% Et₃N) to obtain a white solid compound represented by Formula 2-5: 2-(4-(3-(5-(4-(tert-butyl)-2,6-dimethylphenyl)-3-methyl-1H-pyrazol-1-yl)phenyl)-1-(2,6-diisopropylphenyl)-1H-imidazol-2-yl)phenol (60.0 mg, 0.0942 mmol, 61%). ¹H NMR (400 MHz, CDCl₃): δ 13.48 (br s, 1H), 7.66 (dt, J=7.2, 1.4 Hz, 1H), 7.54 (t, J=7.8 Hz, 2H), 7.33 (d, J=7.8 Hz, 3H), 7.30-7.29 (m, 1H), 7.14 (td, J=7.2, 1.4 Hz, 1H), 7.07 (s, 2H), 7.05 (dd, J=8.2, 0.9 Hz, 2H), 6.83 (s, 1H), 6.53 (dd, J=7.8, 1.4 Hz, 1H), 6.43 (td, J=7.8, 1.4 Hz, 1H), 6.13 (s, 1H), 2.48 (quint, J=6.9 Hz, 2H), 2.44 (s, 3H), 2.08 (s, 6H), 1.16 (s, 9H), 1.13 (d, J=6.9 Hz, 6H), 0.99 (d, J=6.9 Hz, 6H); ¹³C NMR (100 MHz, CDCl₃): δ 158.4, 151.8, 149.5, 146.1, 145.9, 141.8, 140.9, 138.3, 137.3, 134.3, 133.2, 130.5, 130.3, 129.3, 128.5, 124.8, 124.7, 122.7, 121.2, 118.4, 118.4, 117.9, 117.8, 113.0, 108.7, 34.4, 31.2, 28.3, 24.8, 23.1, 20.8, 13.9.

### Synthesis of Compound 111

In a glove box, 2-(4-(3-(5-(4-(tert-butyl)-2,6-dimethylphenyl)-3-methyl-1H-pyrazol-1-yl)phenyl)-1-(2,6-diisopropylphenyl)-1H-imidazol-2-yl)phenol (2-5, 79.0 mg, 0.124 mmol), K₂PtCl₄ (77.2 mg, 0.186 mmol), and tetrabutylammonium bromide (4.00 mg, 0.0124 mmol) were added to a sealed tube, which was then sealed by using a rubber septa. Then, the sealed tube was taken out of the glove box. Nitrogen gas was blown through the sealed tube containing the reactants for 5 minutes, and then, 4.1 mL of degassed AcOH was added thereto. After the rubber septa was replaced with a sealed tube cap, the reaction vessel was completely sealed and the mixed solution was stirred at a temperature of 120° C. for 48 hours. After the temperature was lowered to room temperature, 10 mL of a saturated NaHCO₃ aqueous solution was added to terminate the reaction, followed by extraction using EtOAc (10×3 mL). MgSO₄ was added to the combined organic layers to remove water therefrom, and then, the filtrate obtained by filtration was concentrated. The concentrated reaction product was purified by silica gel column chromatography (hexanes:EtOAc=20:1) to obtain Compound 111 (85.0 mg, 0.102 mmol, 83%), which was a light yellow solid. ¹H NMR (400 MHz, CDCl₃): δ 7.58 (t, J=7.8 Hz, 1H), 7.38-7.35 (m, 3H), 7.25 (s, 2H), 7.23-7.19 (m, 2H), 7.02 (s, 1H), 6.88-6.83 (m, 2H), 6.26 (s, 1H), 6.23 (ddd, J=8.2, 6.9, 1.4 Hz, 1H), 5.84 (d, J=8.2 Hz, 1H), 2.90 (s, 3H), 2.63 (quint, J=6.9 Hz, 2H), 2.15 (s, 6H), 1.42 (s, 9H), 1.15 (d, J=6.9 Hz, 6H), 0.99 (d, J=6.9 Hz, 6H); ¹³C NMR (100 MHz, CDCl₃): δ 165.7, 153.1, 152.1, 146.1, 145.9, 143.6, 142.8, 141.9, 139.4, 137.6, 136.8, 135.1, 130.6, 130.1, 126.2, 125.7, 125.6, 124.8, 124.8, 122.9, 117.6, 117.3, 113.3, 112.6, 109.5, 106.7, 99.9, 34.6, 31.3, 28.4, 24.5, 23.1, 20.3, 12.9.

### Synthesis Example 3 (Compound 112)

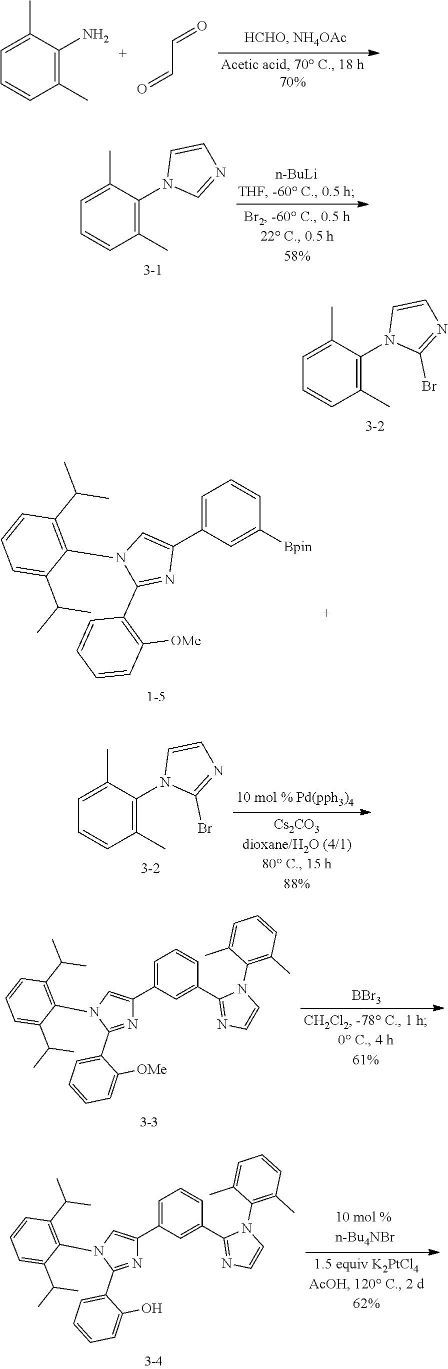

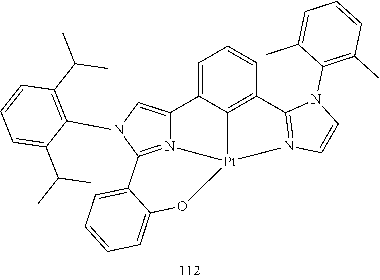

### Synthesis of Compound 3-1 (1-(2,6-dimethylphenyl)-1H-imidazole)

2 mL of glacial acetic acid, formaldehyde (37% in H₂O, 0.608 mL, 6.11 mmol), and glyoxal (40% in H₂O, 0.838 mL, 7.34 mmol) were added to a 25 mL round-bottom flask, and then, after a reflux cooler was connected thereto, the reactants were stirred at 70° C. A solution including 2,6-dimethylaniline (1.00 g, 8.25 mmol), ammonium acetate (0.635 g, 8.25 mmol), 0.250 mL of water, and 2 mL of glacial acetic acid was slowly added to the reaction mixture, and then, stirred at 70° C. for 18 hours. After the post-reaction solution was slowly cooled to room temperature, 5 mL of saturated NaHCO₃ aqueous solution was added thereto at 0° C. to terminate the reaction. Then, an extraction process was performed thereon using 5 mL of the saturated K₂CO₃ aqueous solution and CH₂Cl₂ (3×5 mL). MgSO₄ was added to the combined organic layers to remove water therefrom, followed by filtration and concentration of the filtrate. The concentrated reaction product was purified by silica gel column chromatography (CH₂Cl₂:MeOH=49:1) to obtain a white solid compound represented by Formula 3-1: 1-(2,6-dimethylphenyl)-1H-imidazole (0.745 g, 4.331 mmol, 70%). ¹H NMR (400 MHz, CDCl₃): δ 7.48 (s, 1H), 7.31-7.27 (m, 2H), 7.19 (d, J=8.0 Hz, 2H), 6.95 (s, 1H), 2.06 (s, 6H); ¹³C NMR (100 MHz, CDCl₃): δ 137.2, 135.9, 135.8, 129.6, 128.9, 128.3, 119.8, 17.4.

### Synthesis of Compound 3-2 (2-bromo-1-(2,6-dimethylphenyl)-1H-imidazole)

1-(2,6-dimethylphenyl)-1H-imidazole (3-1, 0.255 mg, 1.48 mmol) and a magnetic bar were added to a 25 mL round-bottom flask, and then, under nitrogen atmosphere, 2.5 mL of THE was added thereto. The reaction temperature was lowered to −60° C., and then, n-BuLi (2.5 M in hexanes, 0.622 mL, 1.56 mmol) was slowly added to the reaction mixture. Then, the temperature was slowly raised to −30° C. for 30 minutes, and then, cooled to −60° C. Then, Br₂ (0.080 mL, 1.557 mmol) was slowly added to the resultant solution and then stirred for 30 minutes. Then, the reaction temperature was raised to room temperature, followed by 30 minutes of further stirring. Then, the reaction was terminated by using 5 mL of sodium thiosulfate aqueous solution and 5 mL of saturated NaHCO₃ aqueous solution, and an extraction process was performed thereon using EtOAc (3×5 mL). MgSO₄ was added to the combined organic layers to remove water therefrom, followed by concentration by filtration. The concentrated reaction product was purified by silica gel column chromatography (hexanes:EtOAc=7:3) to obtain a light yellow solid represented by Formula 3-2: 2-bromo-1-(2,6-dimethylphenyl)-1H-imidazole (0.213 mg, 0.856 mmol, 58%). ¹H NMR (400 MHz, CDCl₃): δ 7.31 (t, J=8.0 Hz, 1H), 7.22-7.18 (m, 3H), 6.98 (d, J=1.4 Hz, 1H), 2.02 (s, 6H); ¹³C NMR (100 MHz, CDCl₃): δ 136.2, 135.3, 130.8, 129.6, 128.4, 122.4, 119.9, 17.6.

### Synthesis of Compound 3-3 (1-(2,6-diisopropylphenyl)-4-(3-(1-(2,6-dimethylphenyl)-1H-imidazol-2-yl)phenyl)-2-(2-methoxyphenyl)-1H-imidazole)

In a glove box, 1-(2,6-diisopropylphenyl)-2-(2-methoxyphenyl)-4-(3-(4,4,5,5-tetramethyl-1,3,2-dioxaborolan-2-yl)phenyl)-1H-imidazole (1-5, 100 mg, 0.187 mmol), 2-bromo-1-(2,6-dimethylphenyl)-1H-imidazole (3-2, 56.2 mg, 0.224 mmol), Pd(pph₃)₄ (21.5 mg, 0.0186 mmol), and Cs₂CO₃ (121 mg, 0.373 mmol) were added to a sealed tube and then sealed by using a rubber septa. Then, the sealed tube was taken out of the glove box. After nitrogen gas was blown through the sealed tube containing the reactants for 5 minutes, 2.0 mL of dioxane and 0.5 mL of degassed H₂O were added thereto. The reaction mixture was stirred at 80° C. for 15 hours. After the reaction, the solution was cooled to room temperature, 4 mL of H₂O was added thereto, and an extraction process was performed thereon using CH₂Cl₂ (3×2 mL). MgSO₄ was added to the combined organic layers to remove water therefrom, followed by filtration and concentration of the filtrate. The concentrated reaction product was purified by silica gel column chromatography (hexanes:EtOAc=4:1) to obtain a white solid compound represented by Formula 3-3: 1-(2,6-diisopropylphenyl)-4-(3-(1-(2,6-dimethylphenyl)-1H-imidazol-2-yl)phenyl)-2-(2-methoxyphenyl)-1H-imidazole (88.8 mg, 0.153 mmol, 88%). ¹H NMR (400 MHz, CDCl₃): δ 8.07-8.04 (dt, J=4.6, 1.5 Hz, 1H), 7.69 (t, J=1.6 Hz, 1H), 7.37-7.34 (m, 4H), 7.23-7.12 (m, 6H), 7.06 (dd, J=6.0, 1.8 Hz, 1H), 6.93 (t, J=1.3 Hz, 2H), 6.81 (d, J=8.2 Hz, 1H), 6.76 (td, J=6.6, 1.0 Hz, 1H), 3.69 (s, 3H), 2.66 (quint, J=6.8 Hz, 2H), 1.99 (s, 6H), 1.10 (d, J=6.9 Hz, 6H), 1.02 (d, J=6.9 Hz, 6H); ¹³C NMR (100 MHz, CDCl₃): δ 158.0, 146.2, 145.8, 137.5, 135.8, 134.3, 131.8, 130.5, 129.4, 128.9, 128.8, 128.6, 125.3, 125.1, 123.5, 122.9, 121.5, 119.6, 119.4, 118.5, 111.1, 55.6, 28.0, 26.3, 24.8, 22.4, 17.8.

### Synthesis of Compound 3-4 (2-(1-(2,6-diisopropylphenyl)-4-(3-(1-(2,6-dimethylphenyl)-1H-imidazol-2-yl)phenyl)-1H-imidazol-2-yl)phenol)

1-(2,6-diisopropylphenyl)-4-(3-(1-(2,6-dimethylphenyl)-1H-imidazol-2-yl)phenyl)-2-(2-methoxyphenyl)-1H-imidazole (3-3, 100 mg, 0.172 mmol) was added to a 10 mL round-bottom flask, and then, under nitrogen atmosphere, 2.2 mL of CH₂Cl₂ was added thereto, and then, at −78° C., BBr₃ (74.7 μL, 0.775 mmol) was slowly added thereto, followed by 1 hour of stirring. Then, the temperature was raised to 0° C., and then, the stirring was further performed for 4 hours. 3 mL of saturated aqueous NaHCO₃ solution was added to the reaction mixture at −78° C. to terminate the reaction. Then, the reaction temperature was slowly raised to room temperature, and then, the resultant mixture was further stirred for 30 minutes to terminate the reaction completely. The reaction mixture was extracted using CH₂Cl₂ (2×3 mL), and the combined organic layers were dried with MgSO₄ and then, the filtrate obtained by filtration was concentrated. The concentrated reaction product was purified by silica gel column chromatography (hexanes:EtOAc=4:1+1% Et₃N) to obtain a light yellow solid compound represented by Formula 3-4: 2-(1-(2,6-diisopropylphenyl)-4-(3-(1-(2,6-dimethylphenyl)-1H-imidazol-2-yl)phenyl)-1H-imidazol-2-yl)phenol (59.9 mg, 0.105 mmol, 61%). ¹H NMR (400 MHz, CDCl₃): δ 13.54 (br s, 1H), 7.87-7.83 (m, 2H), 7.56 (t, J=7.8 Hz, 1H), 7.37-7.34 (m, 5H), 7.24-7.21 (m, 1H), 7.18-7.16 (m, 3H), 7.04 (m, 1H), 6.97 (m, 2H), 6.51 (dd, J=6.5, 1.5 Hz, 1H), 6.44 (m, 1H), 2.49 (quint, J=6.8 Hz, 2H), 2.02 (s, 6H), 1.14 (d, J=6.8 Hz, 6H), 0.95 (d, J=6.8 Hz, 6H); ¹³C NMR (100 MHz, CDCl₃): δ 158.3, 146.0, 145.8, 138.1, 137.2, 135.7, 134.1, 132.6, 130.8, 130.4, 130.2, 129.4, 129.1, 128.7, 125.6, 124.9, 124.7, 124.6, 123.1, 121.7, 118.4, 117.9, 117.7, 113.0, 45.5, 28.2, 24.8, 23.0, 17.8.

### Synthesis of Compound 112

In a glove box, 2-(1-(2,6-diisopropylphenyl)-4-(3-(1-(2,6-dimethylphenyl)-1H-imidazol-2-yl)phenyl)-1H-imidazol-2-yl)phenol (3-4, 100 mg, 0.176 mmol), K₂PtCl₄ (110 mg, 0.265 mmol), and tetrabutylammonium bromide (5.7 mg, 0.0176 mmol) were added to a sealed tube, which was then sealed by using a rubber septa. Then, the sealed tube was taken out of the glove box. Nitrogen gas was blown through the sealed tube containing the reactants for 5 minutes, and then, 5.9 mL of degassed AcOH was added thereto. After the rubber septa was replaced with a sealed tube cap, the reaction vessel was completely sealed and the mixed solution was stirred at a temperature of 120° C. for 48 hours. After the temperature was lowered to room temperature, 20 mL of a saturated NaHCO₃ aqueous solution was added to terminate the reaction, followed by extraction using EtOAc (10×3 mL). MgSO₄ was added to the combined organic layers to remove water therefrom, and then, the filtrate obtained by filtration was concentrated. The concentrated reaction product was purified by silica gel column chromatography (hexanes:EtOAc=5:1) to obtain Compound 112 (83.1 mg, 0.109 mmol, 62%), which was a yellow solid. ¹H NMR (400 MHz, CDCl₃): δ 7.72 (t, J=1.6 Hz, 1H), 7.57 (t, J=8.0 Hz, 1H), 7.44-7.34 (m, 4H), 7.29 (d, J=7.8 Hz, 3H), 7.21 (ddd, J=8.7, 6.9, 1.8 Hz, 1H), 7.02 (t, J=2.1 Hz, 2H), 6.89-6.84 (m, 2H), 6.22 (ddd, J=8.2, 6.9, 1.4 Hz, 1H), 6.02 (d, J=7.8 Hz, 1H), 2.62 (quint, J=6.8 Hz, 2H), 2.09 (s, 6H), 1.14 (d, J=6.8 Hz, 6H), 0.99 (d, J=6.0 Hz, 6H): ¹³C NMR (100 MHz, CDCl₃): δ 165.4, 158.6, 154.2, 146.1, 145.6, 139.3, 136.4, 136.0, 135.2, 134.7, 132.5, 130.6, 130.1, 130.0, 129.4, 128.9, 125.9, 125.7, 124.8, 122.3, 120.4, 119.0, 118.8, 117.0, 113.4, 112.9, 28.4, 24.5, 23.1, 17.4.

### Evaluation Example 1: PL Spectrum Evaluation

Compound 110 was diluted at a concentration of 10 mM in toluene, and then, the PL spectrum thereof was measured by using an ISC PC1 spectrofluorometer having a Xenon lamp mounted thereon at room temperature. This process cycle was repeatedly performed on Compounds 2 and 3 and Compounds A and B. Results thereof are shown in Table 2.

TABLE 2

| | Maximum luminescence |
|---|---|
| Compound No. | wavelength (nm) |
| 110 | 457 nm |
| 111 | 449 nm |
| 112 | 470 nm |
| A | 492 nm |
| B | 498 nm |

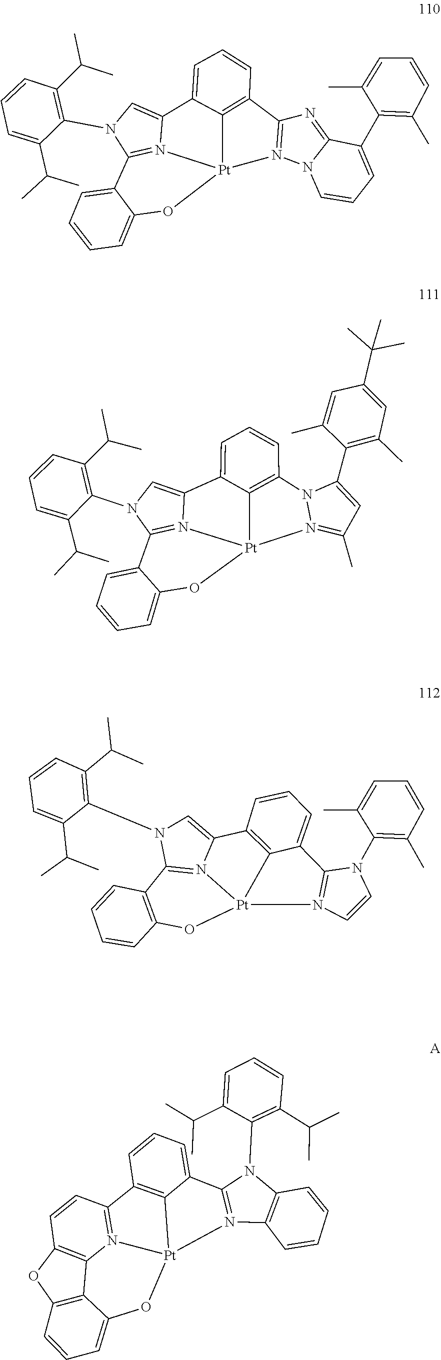

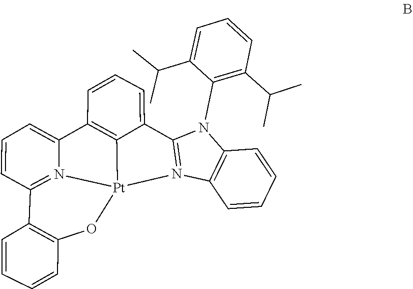

From the Table 2, it can be seen that Compounds 1 to 3 emit blue light. Example 1

A glass substrate with a 1500 Å-thick indium tin oxide (ITO) electrode (first electrode, anode) thereon was cleaned by distilled water ultrasonication. After the distilled water ultrasonication, ultrasonic cleaning was performed with isopropyl alcohol, acetone, and then, methanol, in this stated order, and the glass substrate was dried and transferred to a plasma cleaner. The glass substrate was cleaned by using oxygen plasma for 5 minutes, and then transferred to a vacuum laminator.

Compound HT3 was vacuum-deposited on the ITO electrode of the glass substrate to form a first hole injection layer having a thickness of 3500 Å, Compound HT-D1 was vacuum-deposited on the first hole injection layer to form a second hole injection layer having a thickness of 300 Å, and then, TAPC was vacuum-deposited on the second hole injection layer to form an electron blocking layer having a thickness of 100 Å, thereby completing the manufacture of a hole transport region.

Compound H52 and Compound 110 (dopant, 10%) were co-deposited on the hole transport region to form an emission layer having a thickness of 300 Å.

Compound ET3 was vacuum-deposited on the emission layer to form an electron transport layer having a thickness of 250 Å, and then, ET-D1 (Liq) was deposited on the electron transport layer to form an electron injection layer having a thickness of 5 Å, and then, an Al second electrode (cathode) having a thickness of 1000 Å was formed on the electron injection layer, thereby completing the manufacture of an organic light-emitting device.

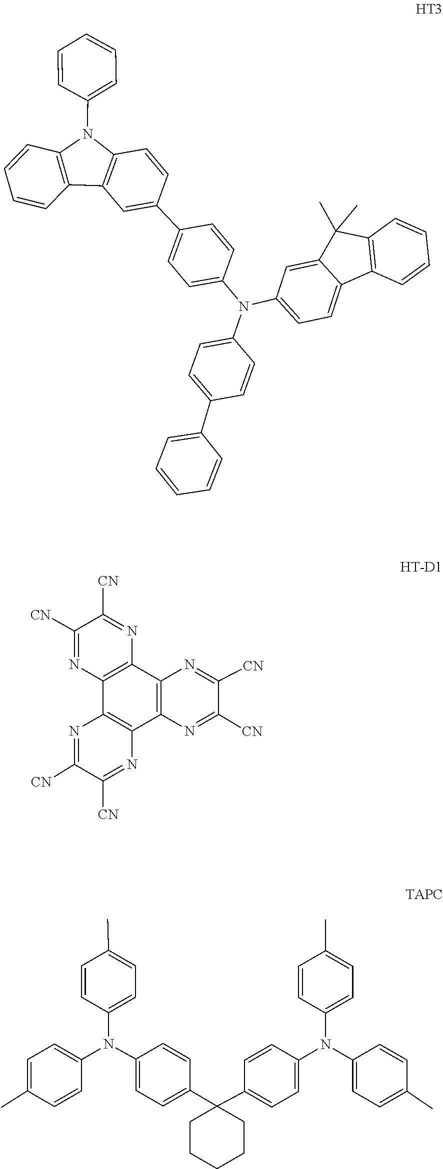

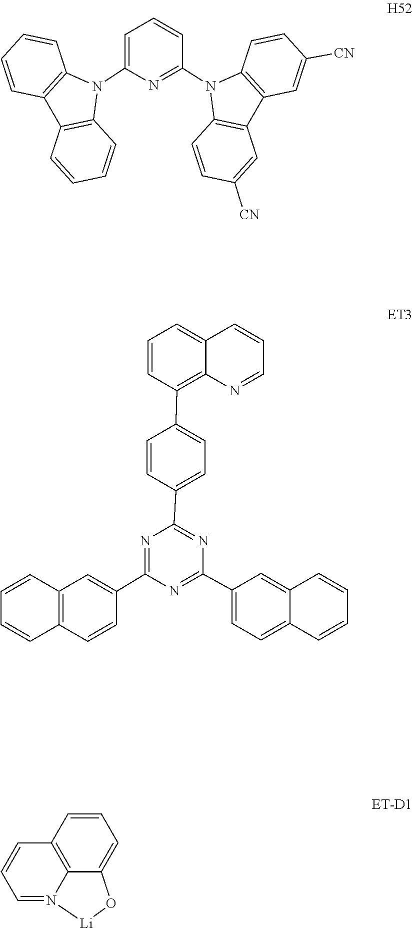

### Examples 2 to 3 and Comparative Examples A and B

Organic light-emitting devices were manufactured in the same manner as in Example 1, except that, in forming an emission layer, for use as a dopant, corresponding compounds shown in Table 3 were used instead of Compound 110. Evaluation of Example 2: Evaluation of Properties of Organic Light-Emitting Devices

For each of the organic light-emitting devices manufactured according to Examples 1 to 3 and Comparative Examples A and B, the maximum luminescence wavelength of the electroluminescence (EL) spectrum, driving voltage and external quantum luminescence efficiency were evaluated. Results are shown in Table 3. The maximum luminescence wavelength of the EL spectrum was evaluated from the EL spectrum (at 500 cd/m²) measured using a luminance meter (Minolta Cs-1000A) for each of the organic light-emitting devices. The driving voltage and the external quantum luminescence efficiency were evaluated using a current-voltmeter (Keithley 2400) and a luminance meter (Minolta Cs-1000 Å). The driving voltage and external quantum luminescence efficiency of the organic light-emitting devices of Examples 1 to 3 and Comparative Example B were expressed as relative values (%) of the driving voltage and external quantum luminescence efficiency of the organic light-emitting device of Comparative Example A.

TABLE 3

| | | | Driving | External quantum |
|---|---|---|---|---|
| | Dopant | Maximum | voltage | Emission |
| | com- | luminescence | (V) | efficiency EQE |
| | pound | wavelength | (Relative | (1000 cd/m²) |
| | No. | (nm) | value, %) | (Relative value, %) |
| Example 1 | 110 | 459 | 140 | 77.9 |
| Example 2 | 111 | 452 | 136 | 15.6 |
| Example 3 | 112 | 469 | 100 | 100 |
| Comparative | A | 493 | 145 | 71.8 |
| Example A | | | | |
| Comparative | B | 497 | 140 | 62.3 |
| Example B | | | | |

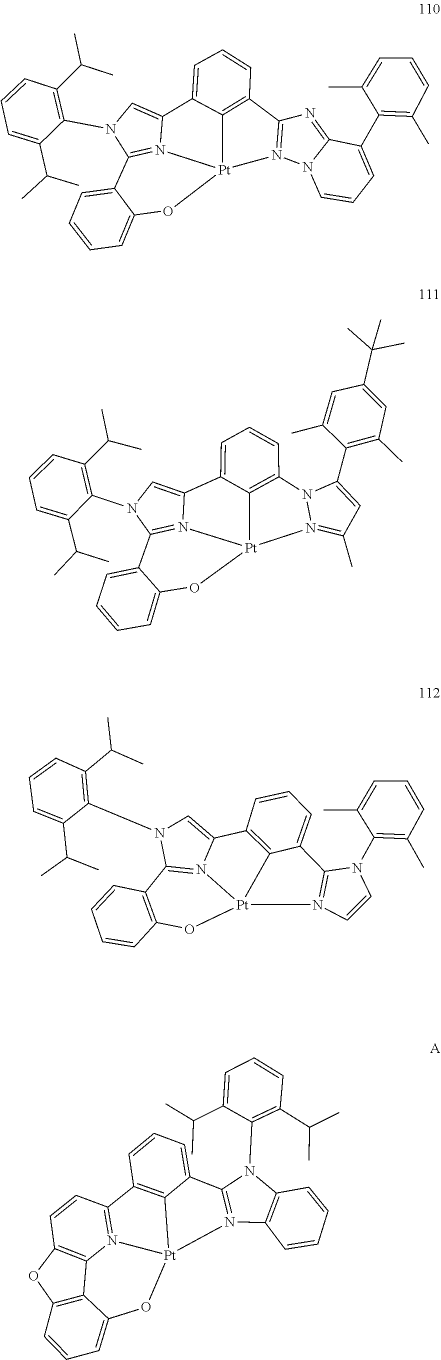

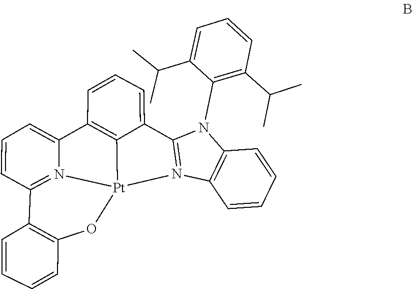

From Table 3, it can be seen that the organic light-emitting devices of Examples 1 to 3, while emitting blue light, have a low driving voltage and high quantum luminescence efficiency compared to the organic light-emitting devices of Comparative Examples A and B.

The organometallic compounds according to embodiments of the present disclosure have excellent electrical characteristics and/or thermal stability. Accordingly, an organic light-emitting device using the organometallic compounds can have improved characteristics in terms of luminescence efficiency, external quantum efficiency, roll-off ratio, and lifespan characteristics. Such organometallic compounds have excellent phosphorescent luminescent characteristics, and thus, when used, a diagnostic composition having a high diagnostic efficiency may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the FIGURES, it will be understood by those of ordinary skill in the art that various changes in form and details may be made therein without departing from the spirit and scope as defined by the following claims.

What is claimed is:

1. An organometallic compound represented by Formula 1: 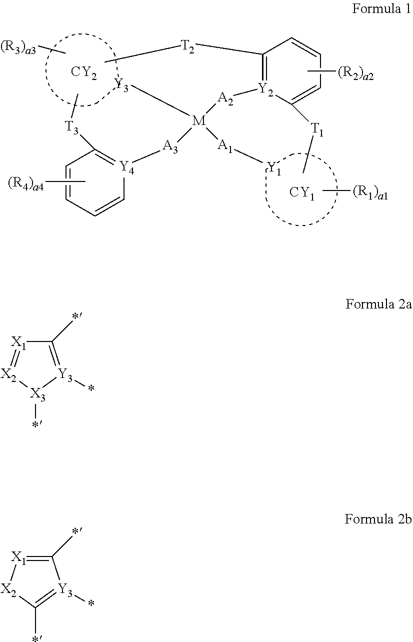
wherein, in Formulae 1, 2a, and 2b,
M is a transition metal,
Y₃ is N, and Y₁, Y₂, and Y₄ are each independently C or N,
ring CY₁ is a C₅-C₃₀ carbocyclic group or a C₁-C₃₀ heterocyclic group,
ring CY₂ is a group represented by Formula 2a or Formula 2b,
X₁, X₂, and X₃ are each independently C or N,
A₁, A₂, and A₃ are each independently a chemical bond, O, S, B(R₅), N(R₅), P(R₅), C(R₅)(R₆), Si(R₅)(R₅), Ge(R₅)(R₅), C(═O), or P(R₅)(R₅), wherein, when A₁ is a chemical bond, Y₁ and M are directly linked to each other, when A₂ is a chemical bond, Y₂ and M are directly linked to each other, and, when A₃ is a chemical bond, Y₄ and M are directly linked to each other,
at least one of A₁, A₂, and A₃ is O,
a bond between Y₃ and M is a coordination bond,
one of a bond between Y₁ or A₁ and M, a bond between Y₂ or A₂ and M, and a bond between Y₄ or A₃ and M is a coordination bond, and the other two bonds are each a covalent bond,
T₁, T₂, and T₃ are each independently a single bond, a double bond, *′—N(R₇)—*″, *′—B(R₇)—*″, *′—P(R₇)—*″, *′—C(R₇)(R₈)—*″, *′—Si(R₇)(R₈)—*″, *′—Ge(R₇)(R₈)—*″, *′—S—*″, *′—Se—*″, *′—O—*″, *′—C(═O)—*″, *′—S(═O)—*″, *′—S(═O)₂—*″, *′—C(R₇)=*″, *′=C(R₇)—*″*, *′—C(R₇)═C(R₈)—*″, *′—C(═S)—*″ or *′—C≡C—*″,
R₁ to R₈ are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —B(Q₁)(Q₂), or —P(═O)(Q₁)(Q₂),
a1 is an integer from 0 to 20,
a2 is an integer from 0 to 3,
a3 is an integer from 0 to 3,
a4 is an integer from 0 to 4,
two or more of a plurality of R₁(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
an R₁ and a N of ring CY₁ are optionally linked to each other to form a C₁-C₃₀ heterocyclic group that is unsubstituted or substituted with at least one R₁₀ₐ,
two or more of a plurality of R₂(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of R₄(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
at least one of a plurality of R₁, R₂, and R₃ and at least one of a plurality of R₄(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
R₁₀ₐ is the same as described in connection with R₁,
* indicates a binding site to metal M, and *′ and *″ each indicate a binding site to a neighboring atom, and
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), —P(═O)(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, and a monovalent non-aromatic condensed heteropolycyclic group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), —P(═O)(Q₂₈)(Q₂₉), or any combination thereof; or
—N(Q₃₁)(Q₃₂), —Si(Q₃₃)(Q₃₄)(Q₃₅), —B(Q₃₆)(Q₃₇), or —P(═O)(Q₃₈)(Q₃₉),
wherein Q₁ to Q₉, Q₁₁ to Q₁₉, Q₂₁ to Q₂₉ and Q₃₁ to Q₃₉ are each independently: hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one of a C₁-C₆₀ alkyl group, a C₆-C₆₀ aryl group, or a combination thereof, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group.

2. The organometallic compound of claim 1, wherein M is Pt, Pd, or Au.

3. The organometallic compound of claim 1, wherein Y₂ and Y₄ are each C,
Y₁ is C or N,
A₁ is a chemical bond, and one of A₂ and A₃ is O,
a bond between Y₂ or A₂ and M and a bond between Y₄ or A₃ and M are each a covalent bond, and
a bond between Y₁ and M is a coordination bond.

4. The organometallic compound of claim 1, wherein CY₁ is i) a first ring, ii) a condensed cyclic group in which two or more first rings are condensed with each other, or iii) a condensed cyclic group in which at least one first ring is condensed with at least one second ring,
the first ring is a cyclopentane group, a cyclopentadiene group, a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a 5-membered cyclic carbene group, a triazole group, a tetrazole group, an azasilole group, a diazasilole group, or a triazasilole group, and
the second ring is an adamantane group, a norbornane group, a norbornene group, a cyclohexane group, a cyclohexene group, a benzene group, a pyridine group, a pyrimidine group, a pyrazine group, a pyridazine group, a triazine group, an oxazine group, a thiazine group, a dihydropyrazine group, a dihydropyridine group, or a dihydroazasilane group.

5. The organometallic compound of claim 1, wherein one of A₂ and A₃ is O, the other one is a chemical bond, and A₁ is a chemical bond.

6. The organometallic compound of claim 1, wherein T₁, T₂, and T₃ are each a single bond.

7. The organometallic compound of claim 1, wherein at least one of X₁ and X₂ is N, and
X₃ is C or N.

8. The organometallic compound of claim 1, wherein R₁ to R₈ are each independently:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, or a C₁-C₂₀ alkoxy group;
a C₁-C₂₀ alkyl group or a C₁-C₂₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof; or
—N(Q₁)(Q₂), —Si(Q₃)(Q₄)(Q₅), —B(Q₆)(Q₇), or —P(═O)(Q₈)(Q₉),
wherein Q₁ to Q₉ are each independently:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CH₃, —CD₂CD₃, —CD₂CD₂H, or —CD₂CDH₂;
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group, each substituted with at least one deuterium, a C₁ to C₁₀ alkyl group, a phenyl group, or any combination thereof.

9. The organometallic compound of claim 1, wherein at least one of R₁(s) in the number of a1 and R₃(s) in the number of a3 is a substituted or unsubstituted C₁-C₆₀ alkyl group or a substituted or unsubstituted C₆-C₃₀ aryl group.

10. The organometallic compound of claim 1, wherein each of a2 and a4 is 0.

11. The organometallic compound of claim 1, wherein a group represented by 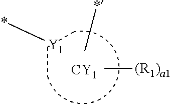
is represented by one of Formulae CY1-1 to CY1-48: 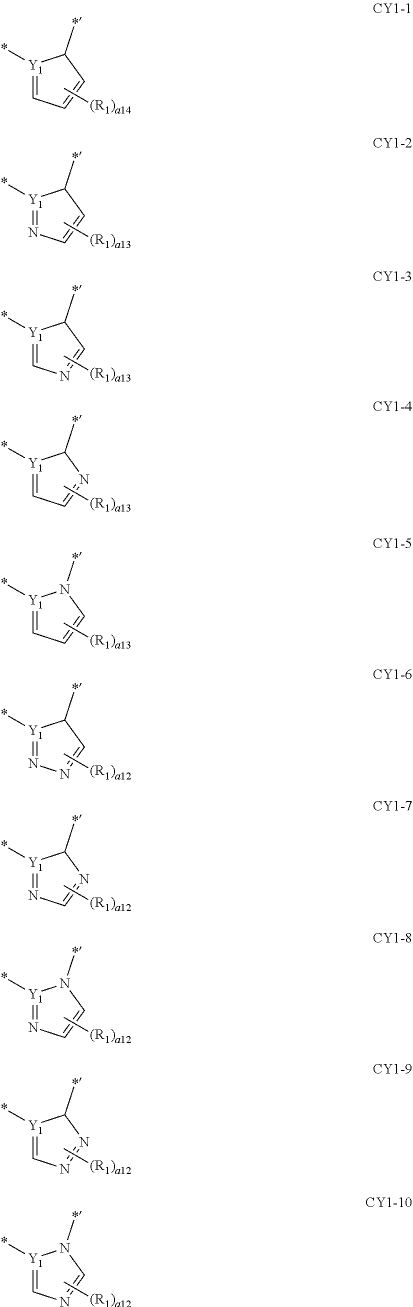 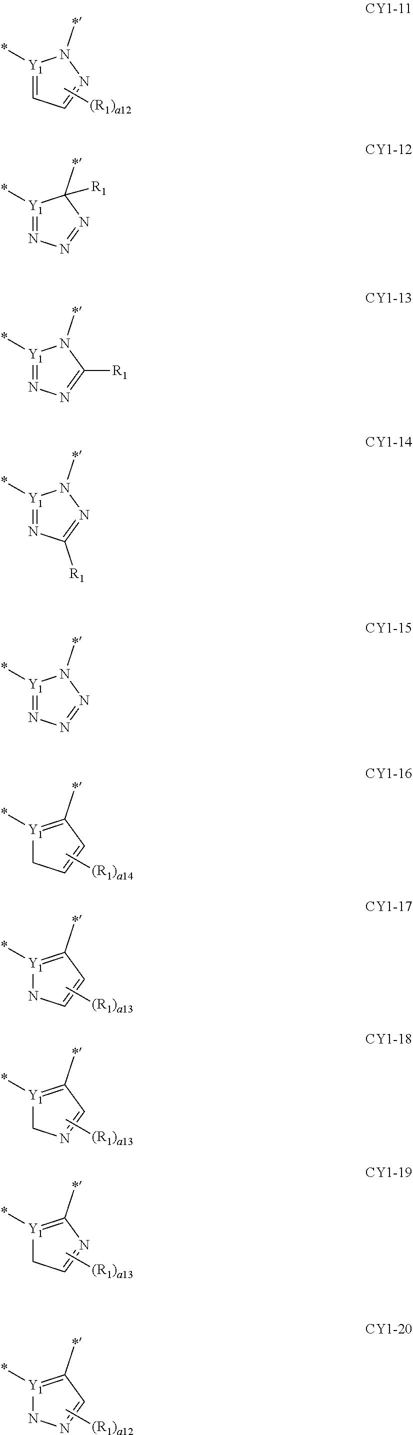 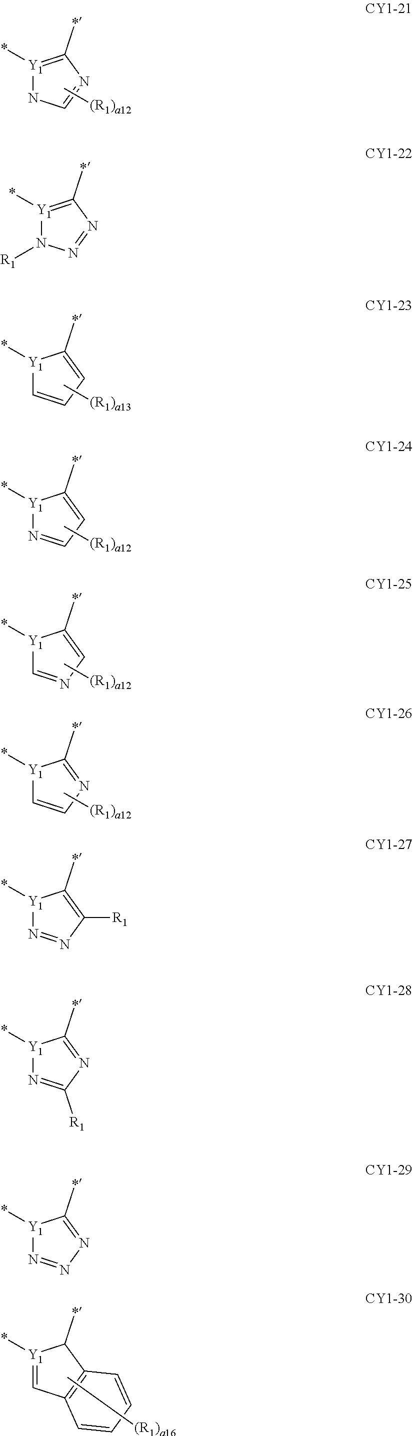 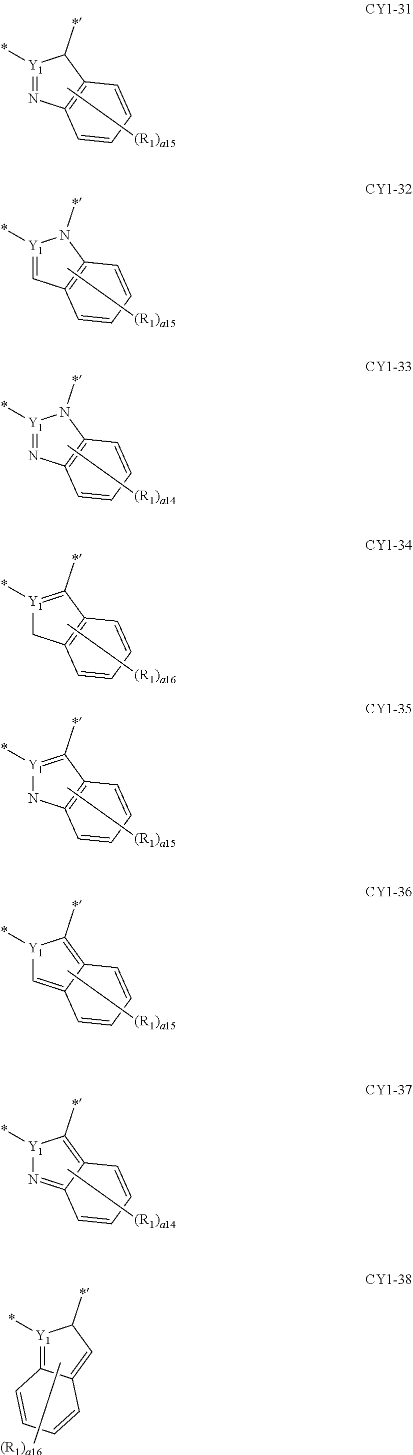 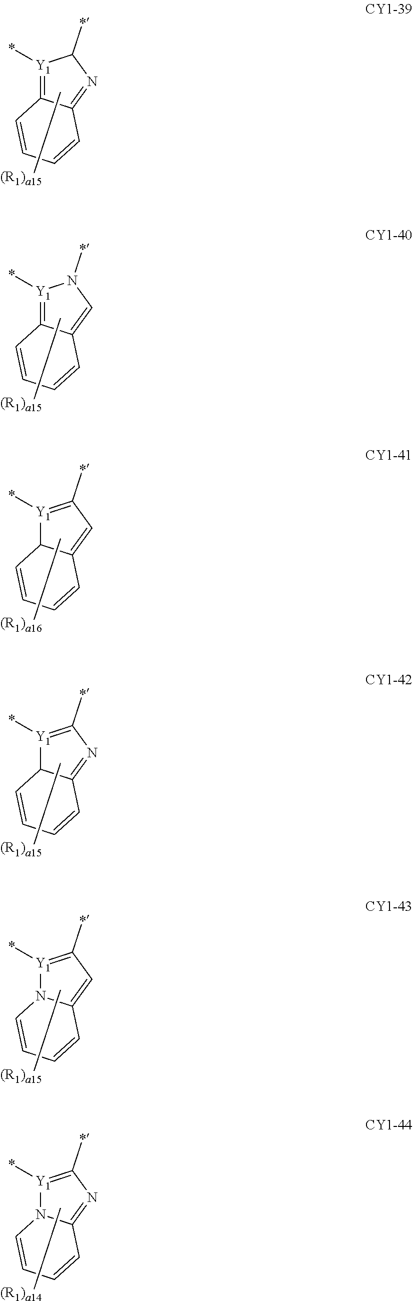 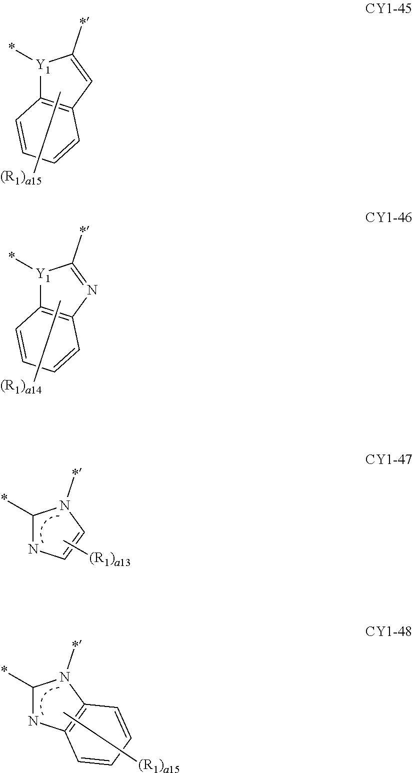
wherein, in Formulae CY1-1 to CY1-48,
Y₁ and R₁ are the same as described in connection with claim 1,
a12 is an integer from 0 to 2,
a13 is an integer from 0 to 3,
a14 is an integer from 0 to 4,
a15 is an integer from 0 to 5,
a16 is an integer from 0 to 6,
* indicates a binding site to M in Formula 1, and
*′ indicates a binding site to T₁ in Formula 1.

12. The organometallic compound of claim 1, wherein Formula 1 is represented by one of Formulae 2-1 to 2-5: 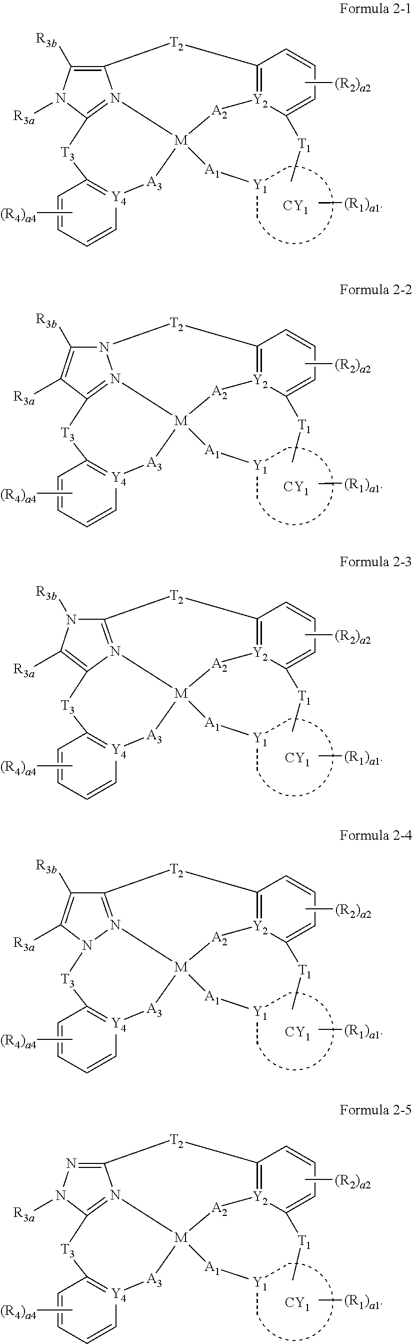
wherein, in Formulae 2-1 to 2-5,
CY₁, Y₁, Y₂, Y₄, A₁, A₂, A₃, T₁, T₂, T₃, R₁, R₂, R₄, a1, a2, and a4 are the same as described in connection with claim 1, and
R₃ₐ and R_{3b} are the same as described in connection with R₃ in claim 1.

13. The light-emitting device of claim 12, wherein A₃ is O,
A₁ and A₂ are each a chemical bond, and
CY₁ is a cyclopentane group, a cyclopentadiene group, a furan group, a benzofuran group, a thiophene group, a benzothiophene group, a pyrrole group, a benzopyrrole group, a silole group, a benzosilole group, an oxazole group, a benzoxazole group, an isoxazole group, a benzoisoxazole group, an oxadiazole group, a benzoxadiazole group, an isoxadiazole group, a benzoisoxadiazole group, an oxatriazole group, a benzoxatriazole group, an isoxatriazole group, a benzoisoxatriazole group, a thiazole group, a benzothiazole group, an isothiazole group, a benzoisothiazole group, a thiadiazole group, a benzothiadiazole group, isothiadiazole group, a benzoisothiadiazole group, a thiatriazole group, a benzothiatriazole group, an isothiatriazole group, a benzoisothiatriazole group, a pyrazole group, a benzopyrazole group, an imidazole group, a benzimidazole group, a 5-membered cyclic carbene group, a 5-membered benzocyclic carbene group, a triazole group, a benzotriazole group, a tetrazole group, a benzotetrazole group, an azasilole group, a benzoazasilole group, a diazasilole group, a benzodiazasilole group, a triazasilole group, or a benzotriazasilole group.

14. The organometallic compound of claim 1, wherein Formula 1 is represented by one of Formulae 3-1 to 3-10: 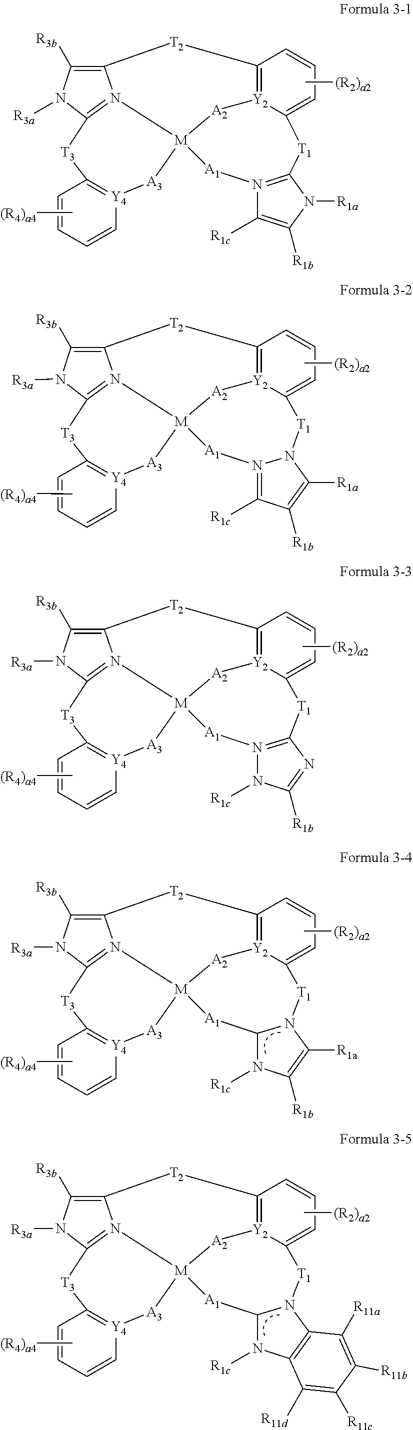 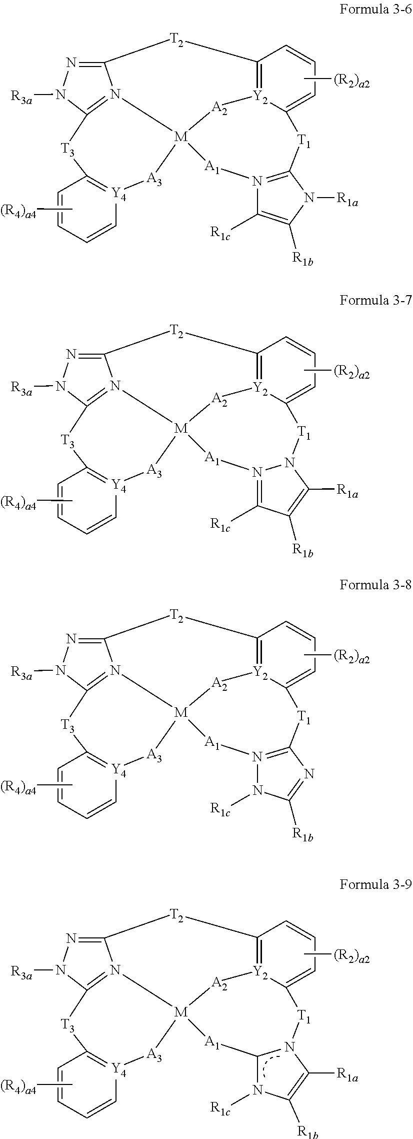 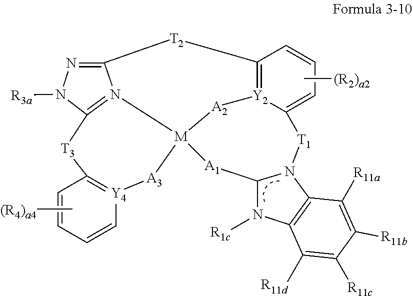
wherein, in Formulae 3-1 to 3-10,
Y₂, Y₄, A₁, A₂, A₃, T₁, T₂, T₃, R₂, R₄, a2, and a4 are the same as described in connection with claim 1,
R₃ₐ and R_{3b} are the same as described in connection with R₃ in claim 1, and
R₁ₐ, R_{1b}, R_{1c}, R₁₁ₐ, R_{11b}, R_{11c}, and R_{11d} are the same as described in connection with R₁ in claim 1.

15. The organometallic compound of claim 1, wherein the organometallic compound is one of Compounds 1 to 114:

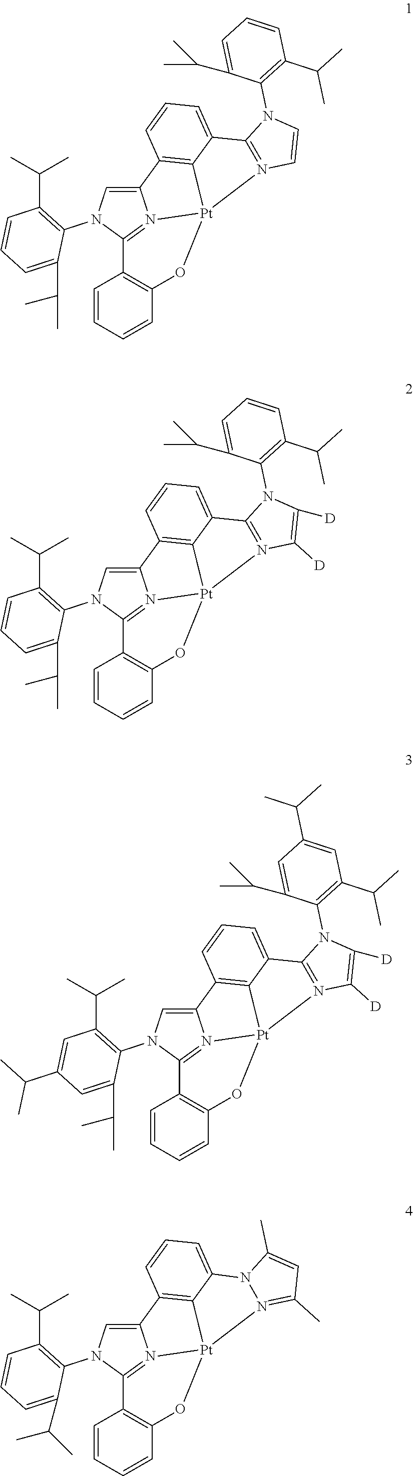

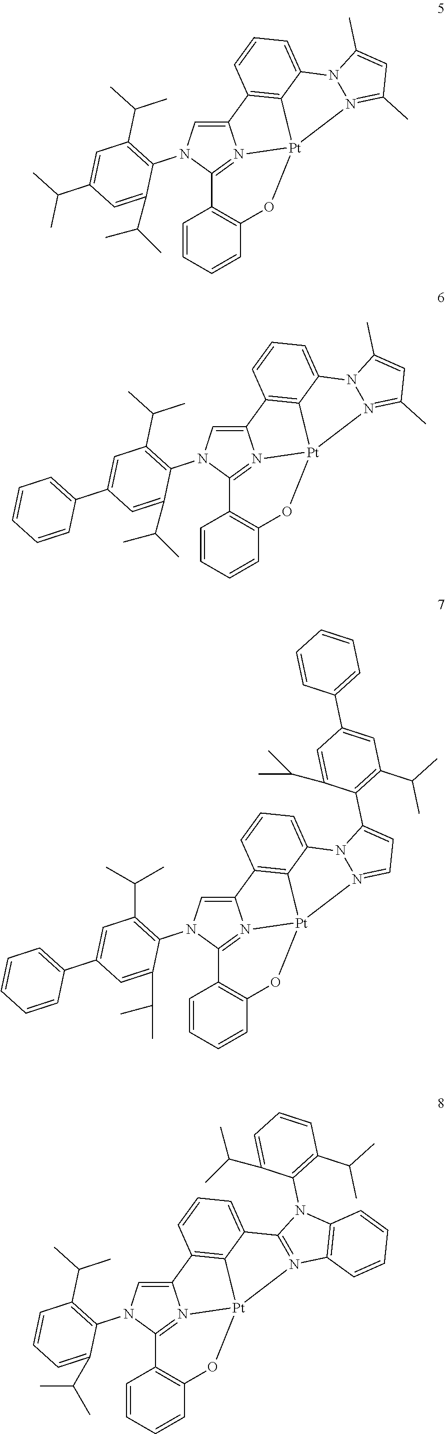

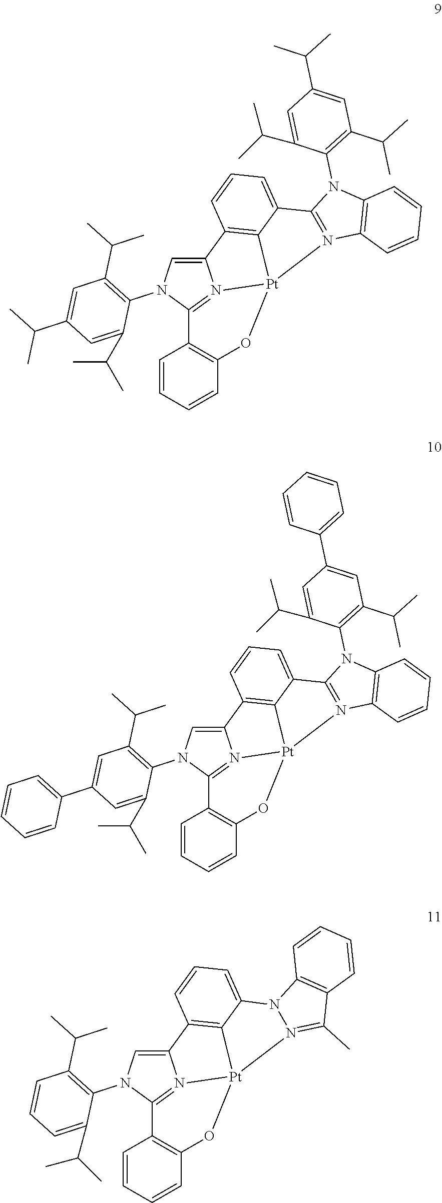

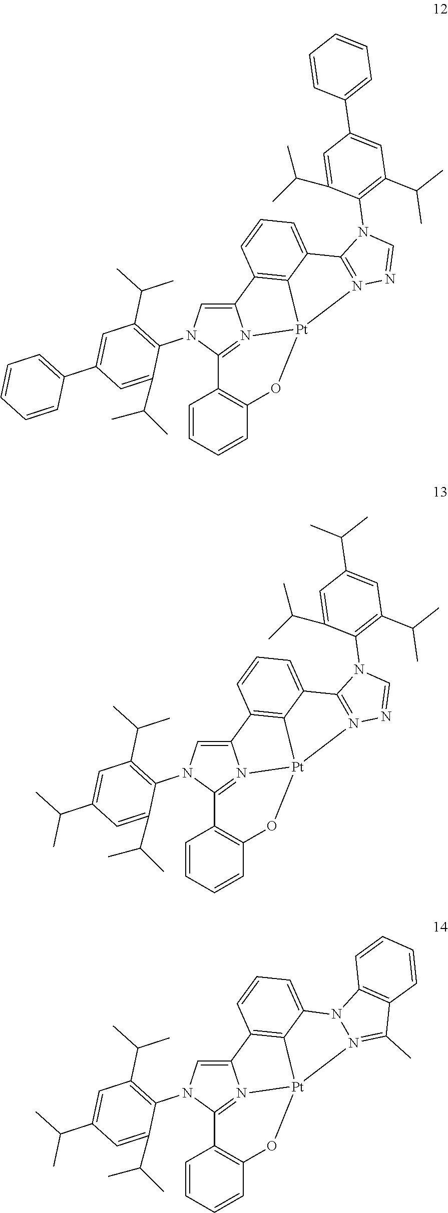

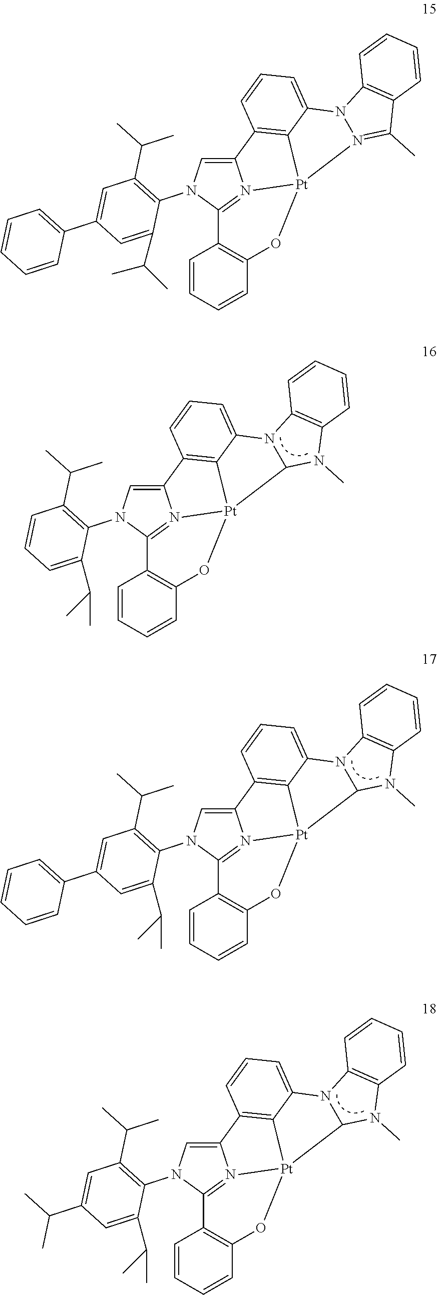

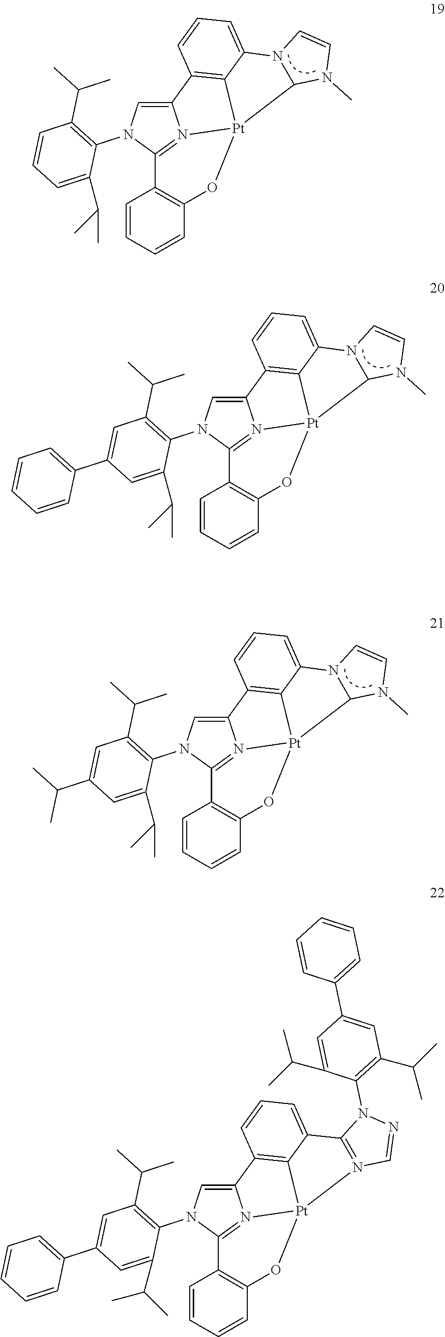

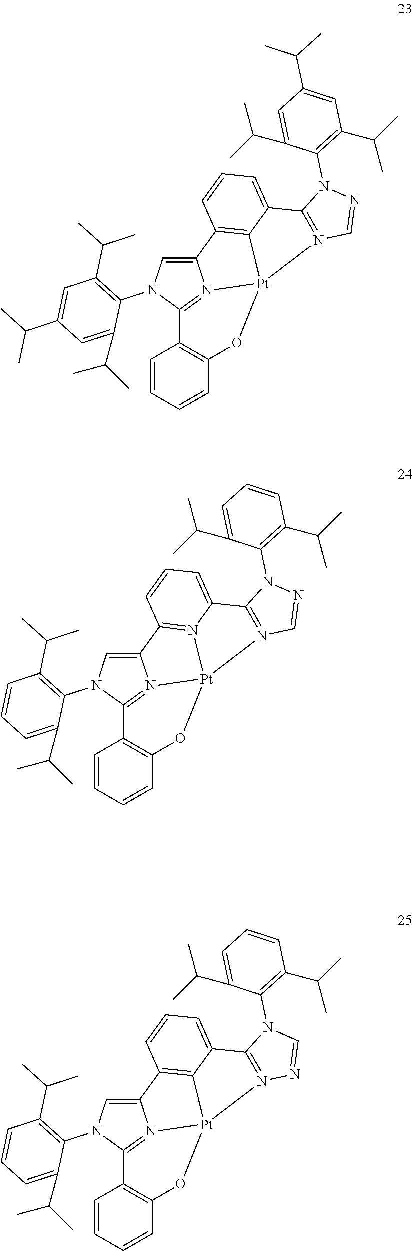

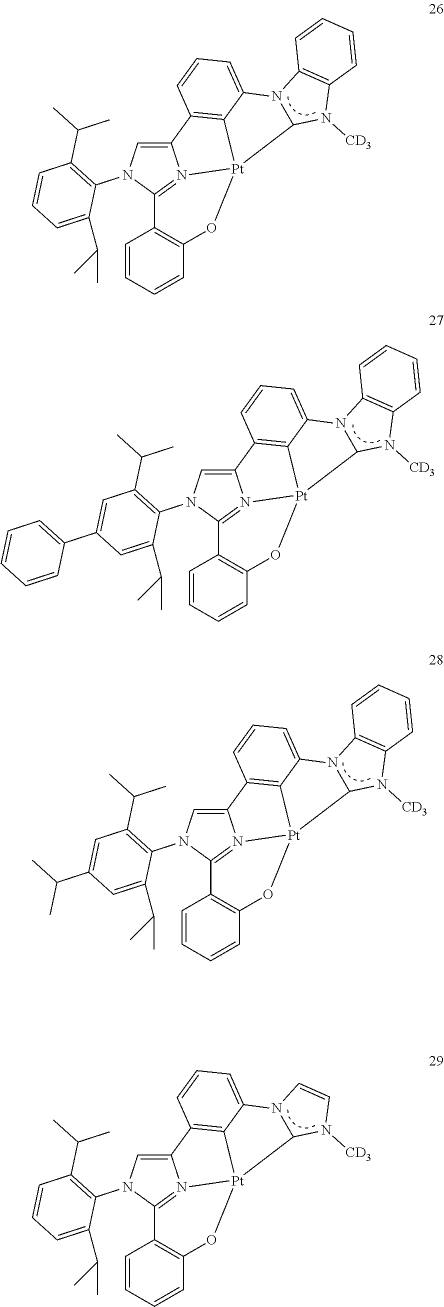

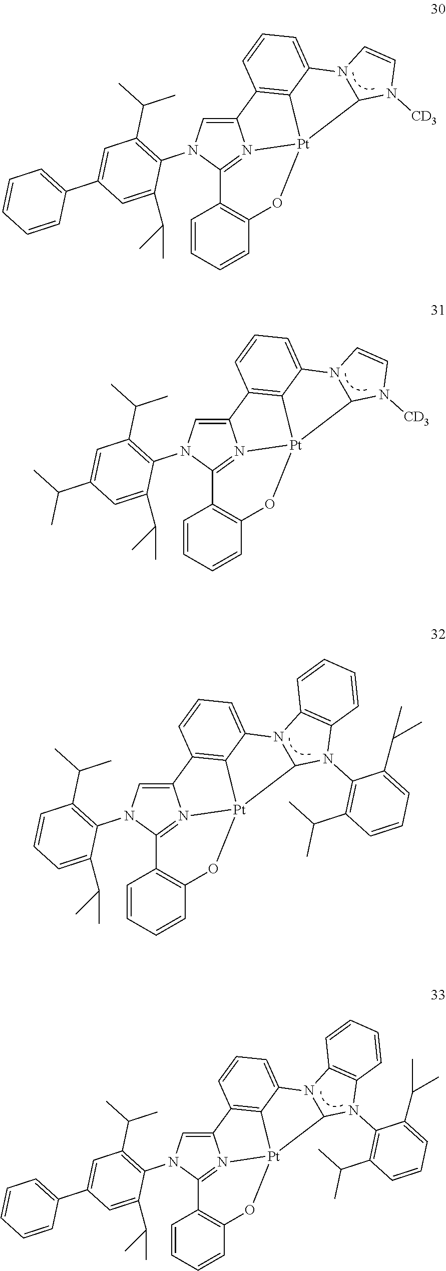

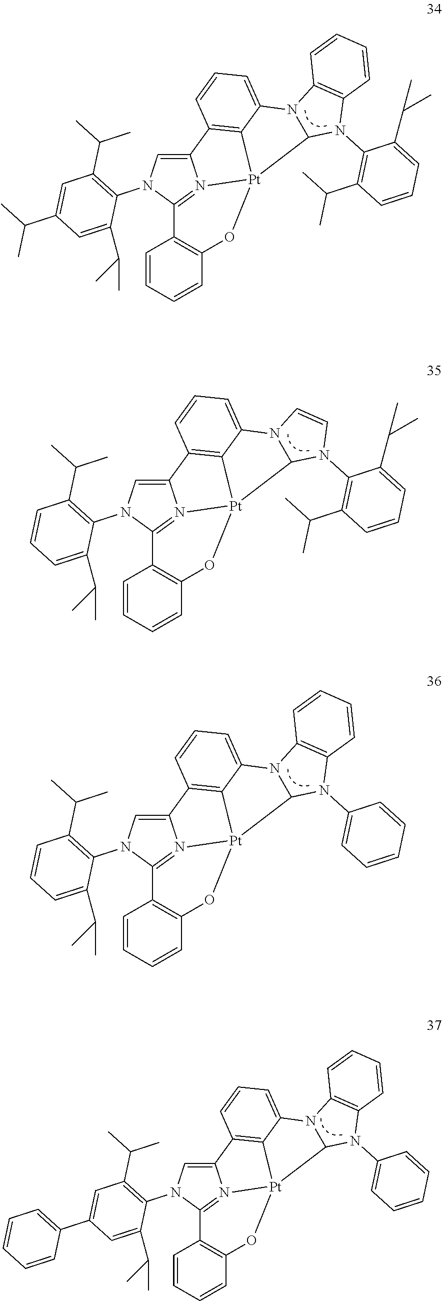

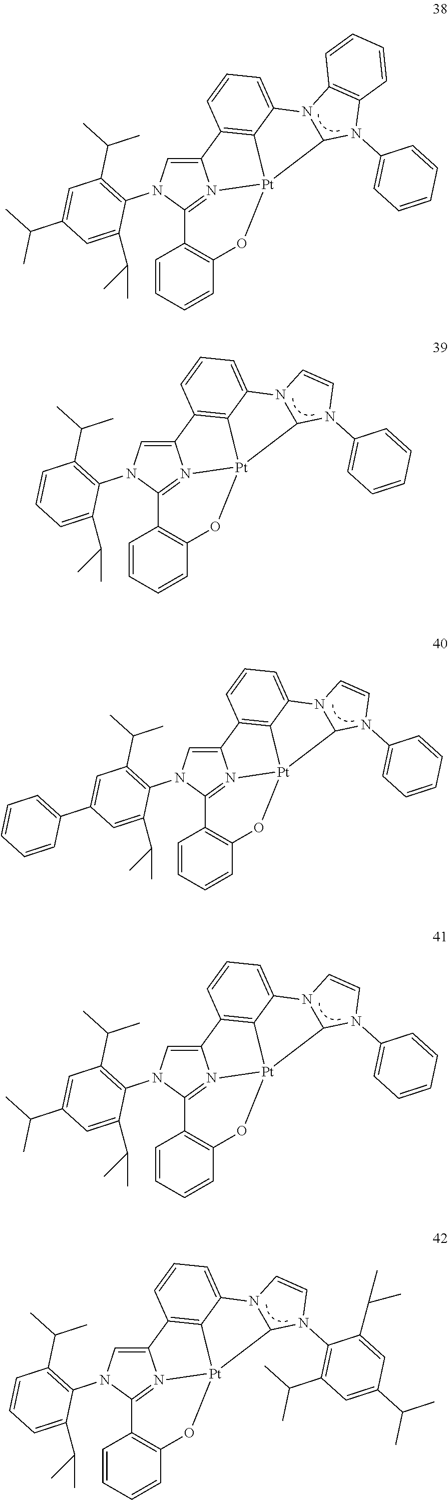

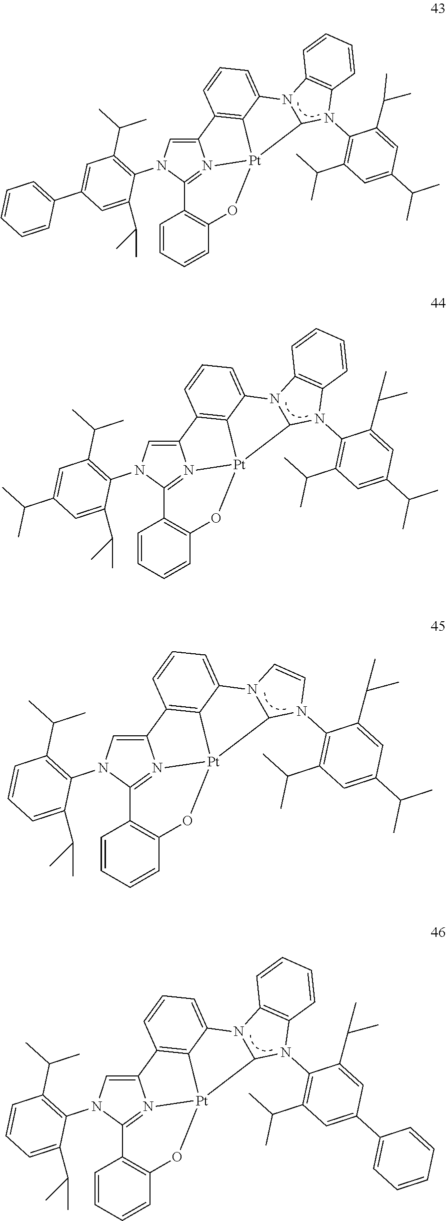

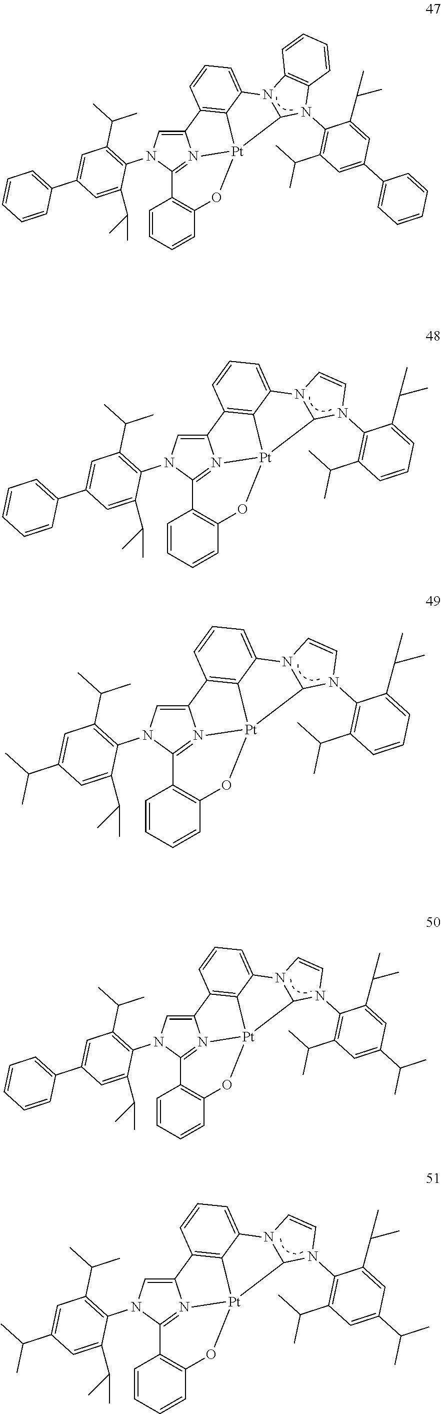

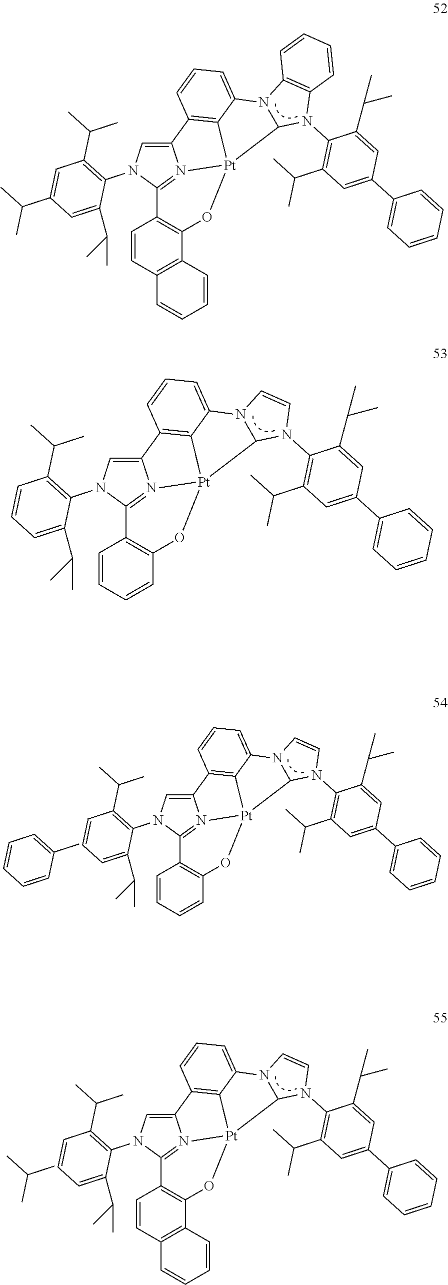

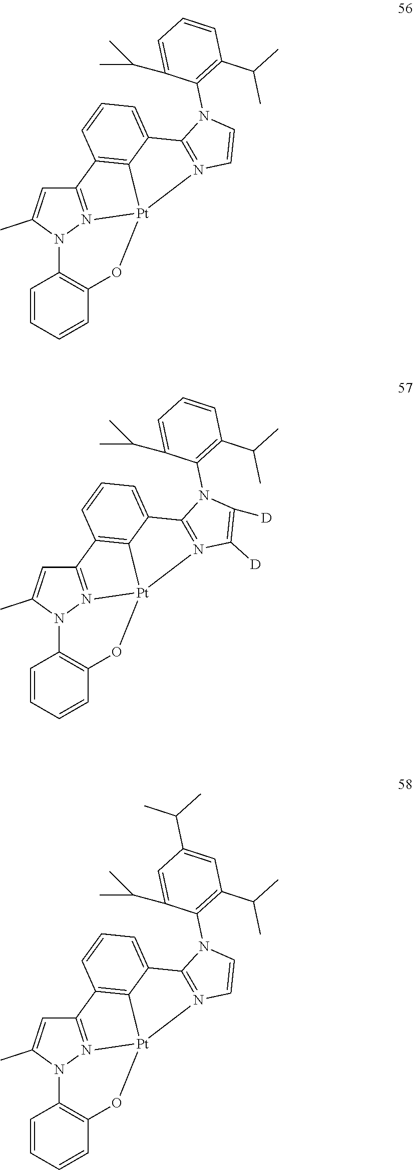

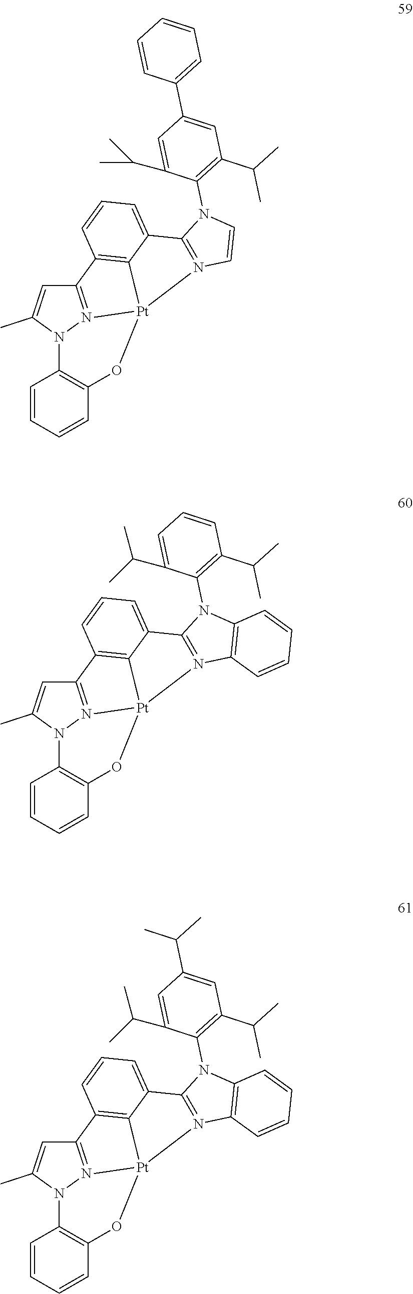

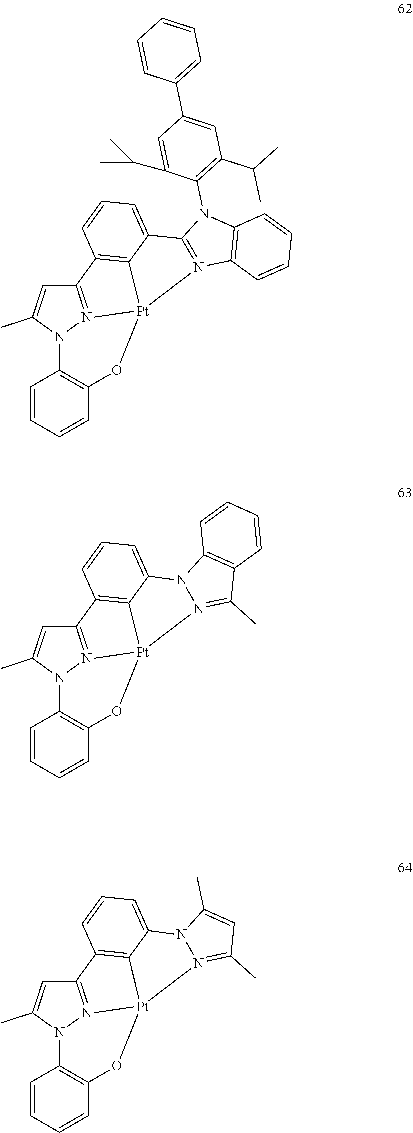

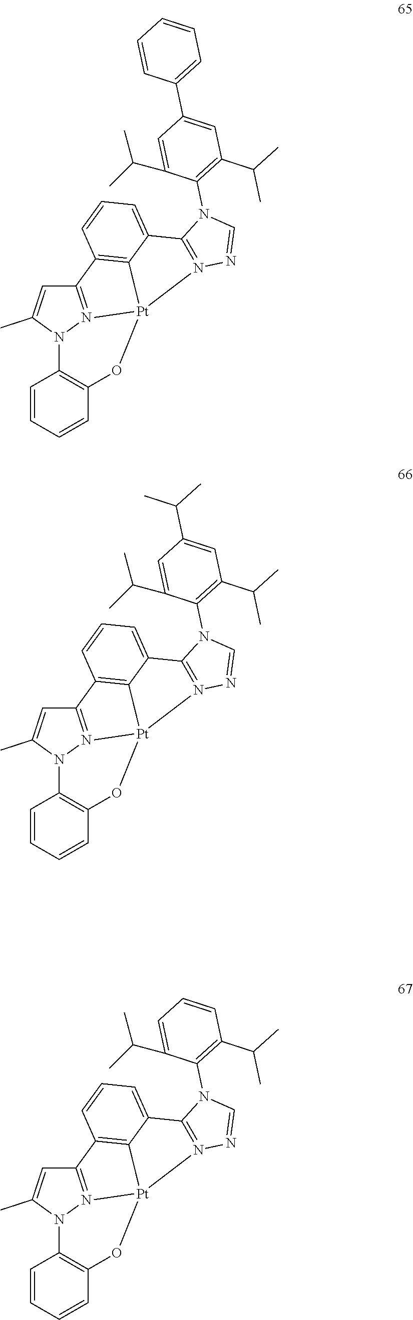

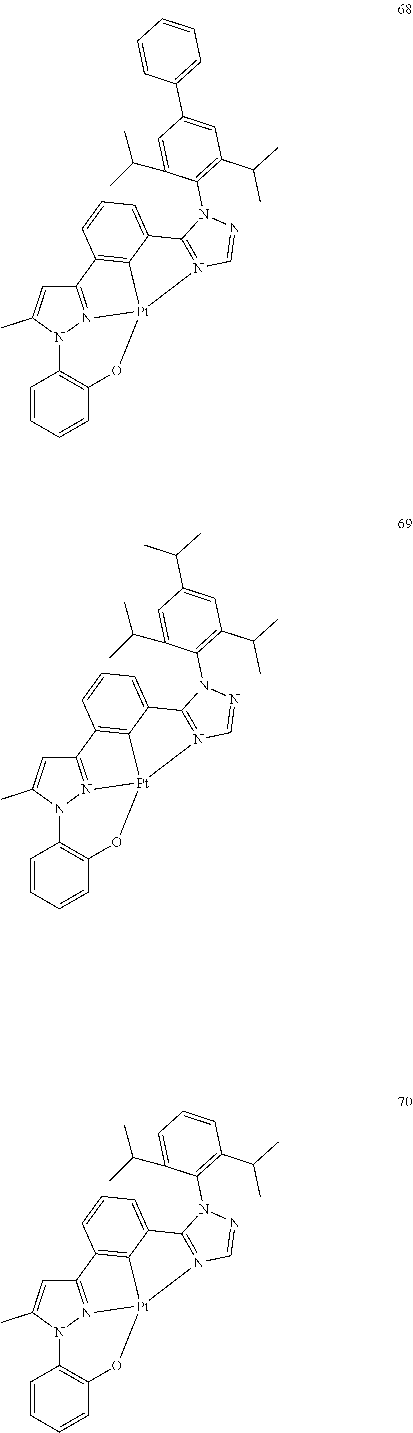

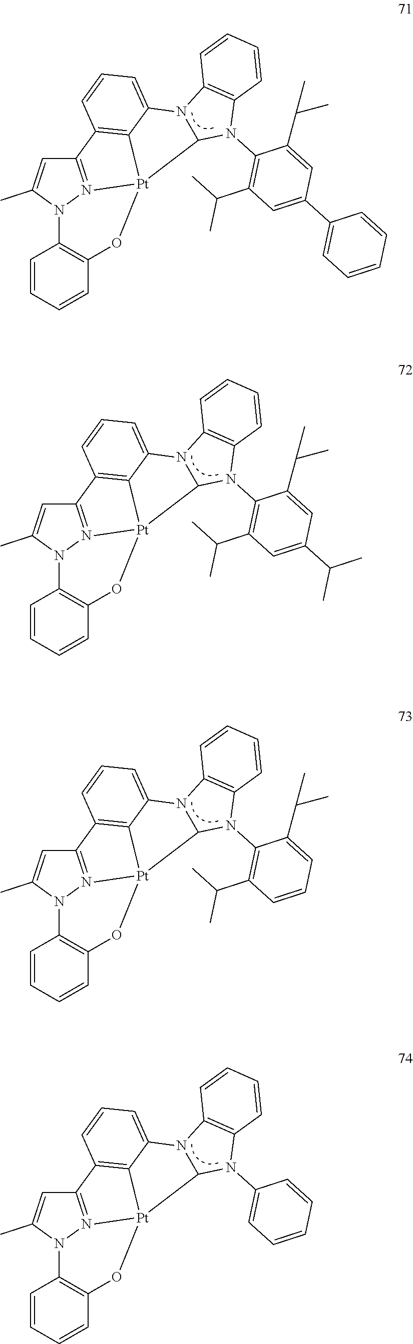

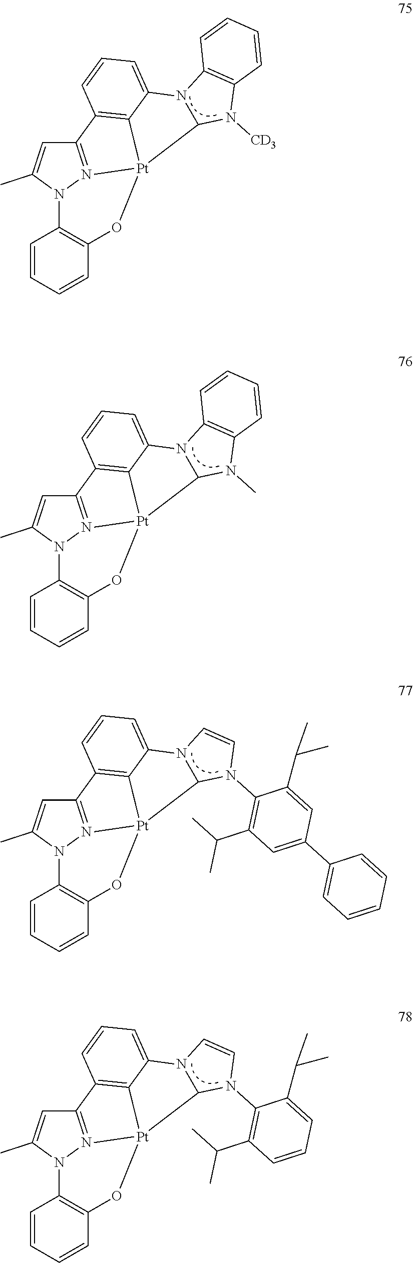

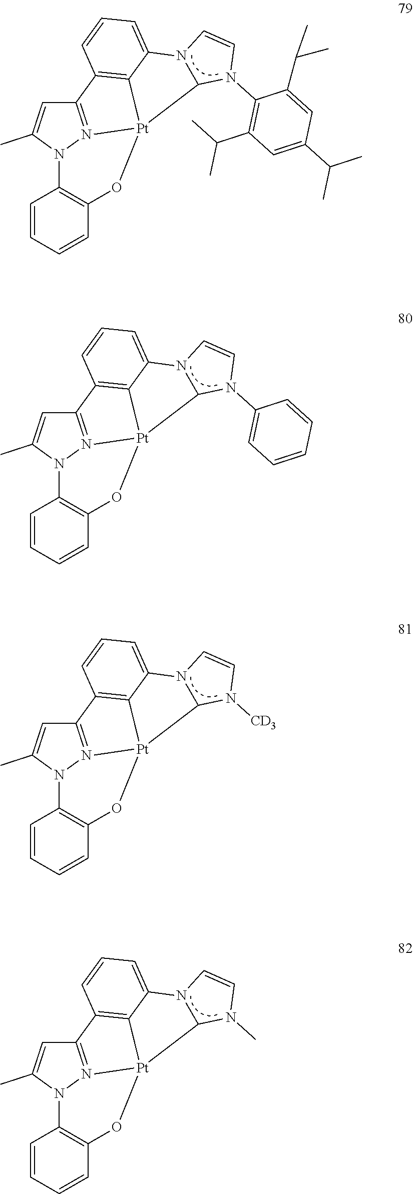

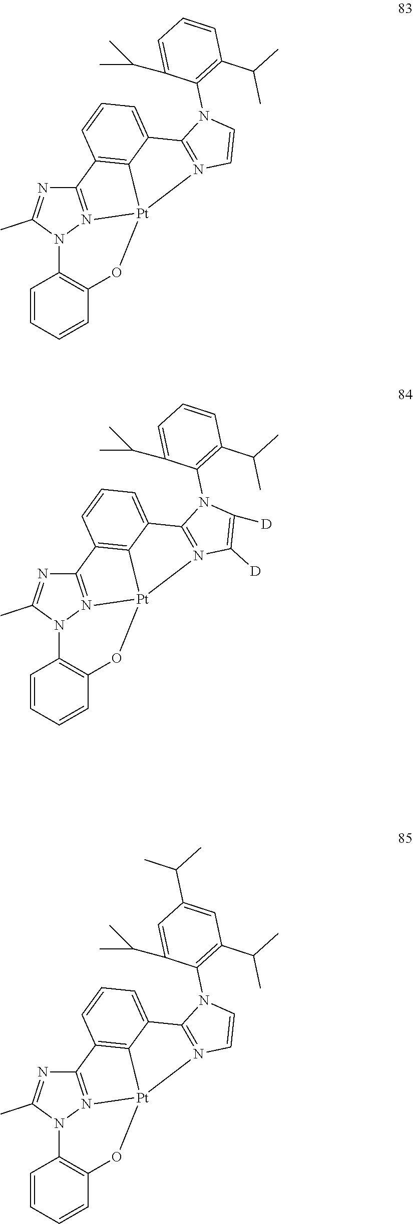

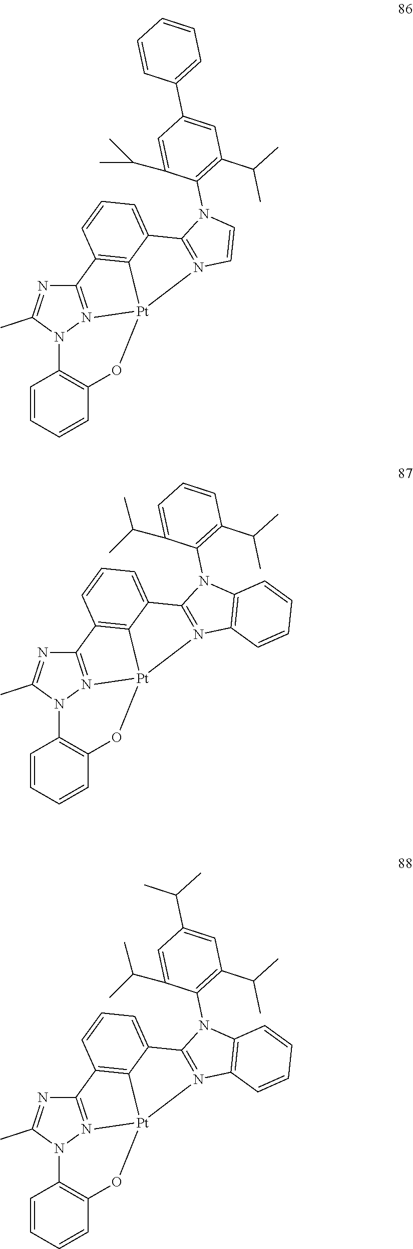

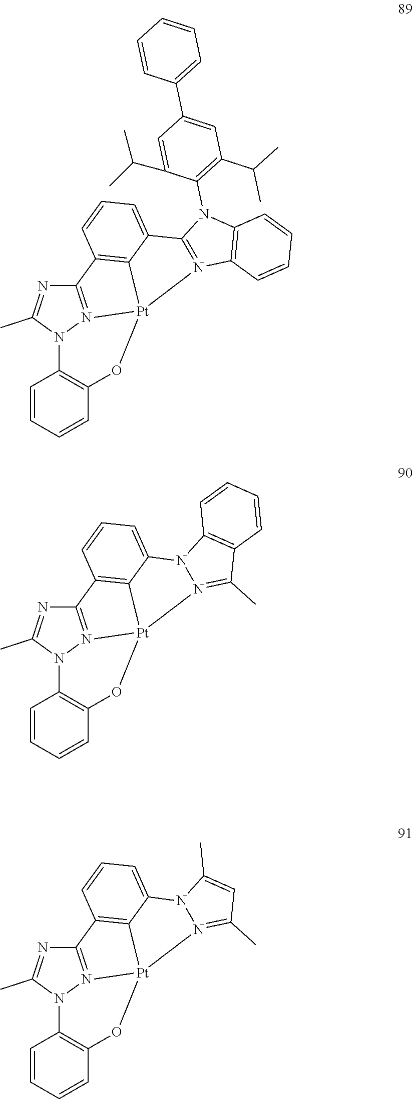

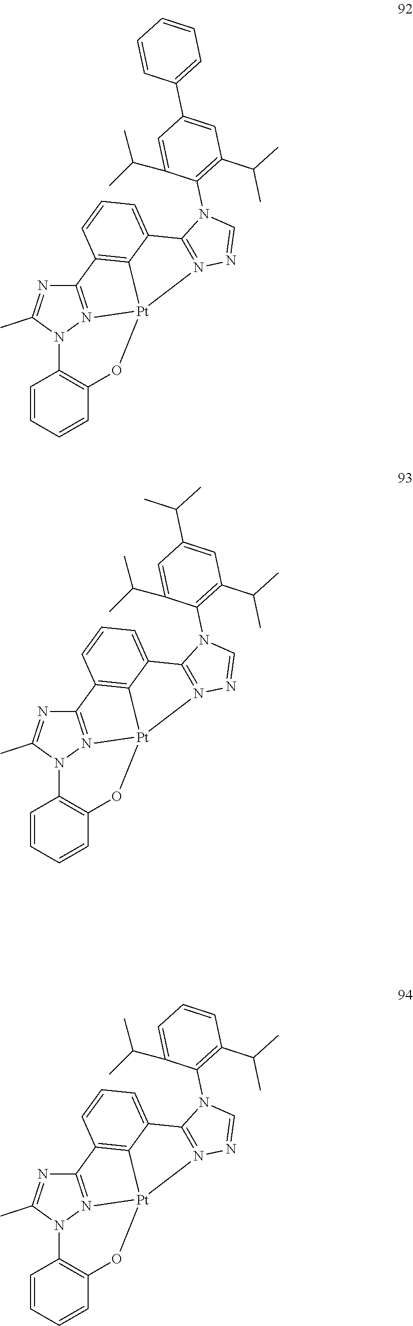

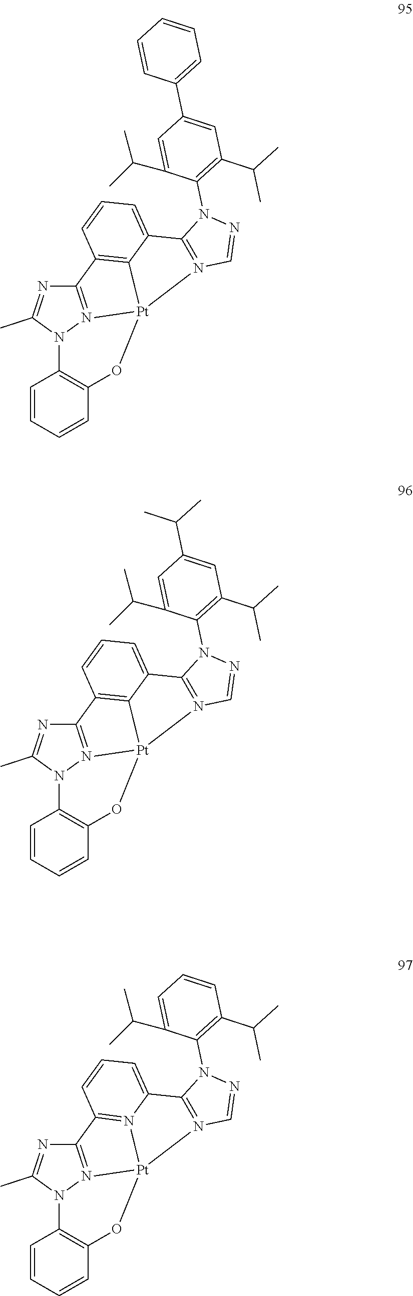

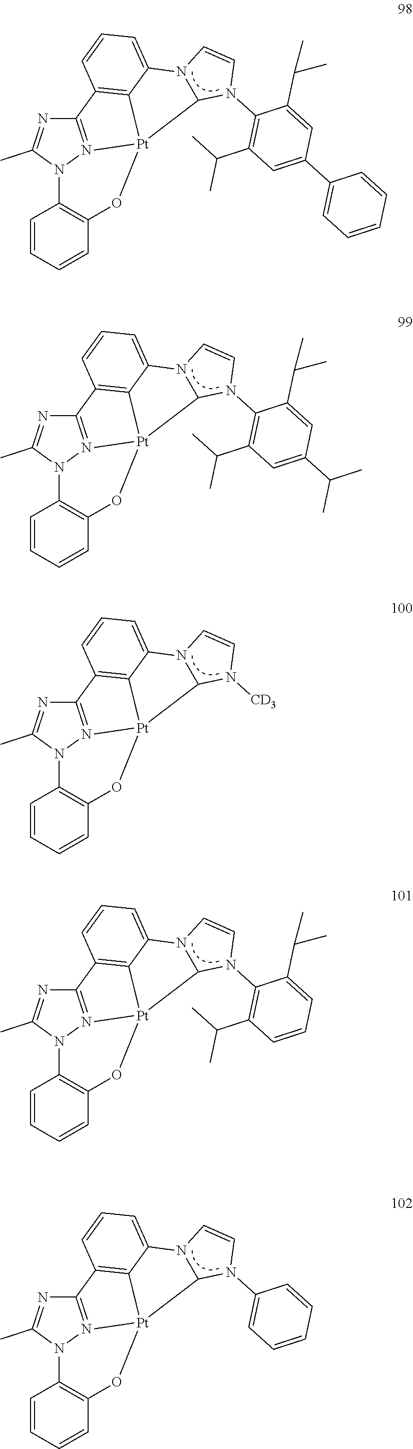

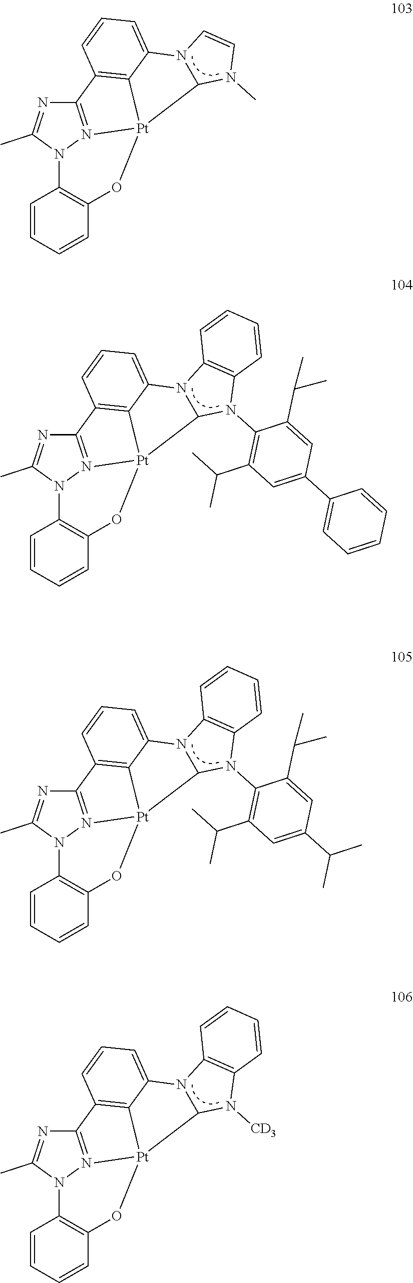

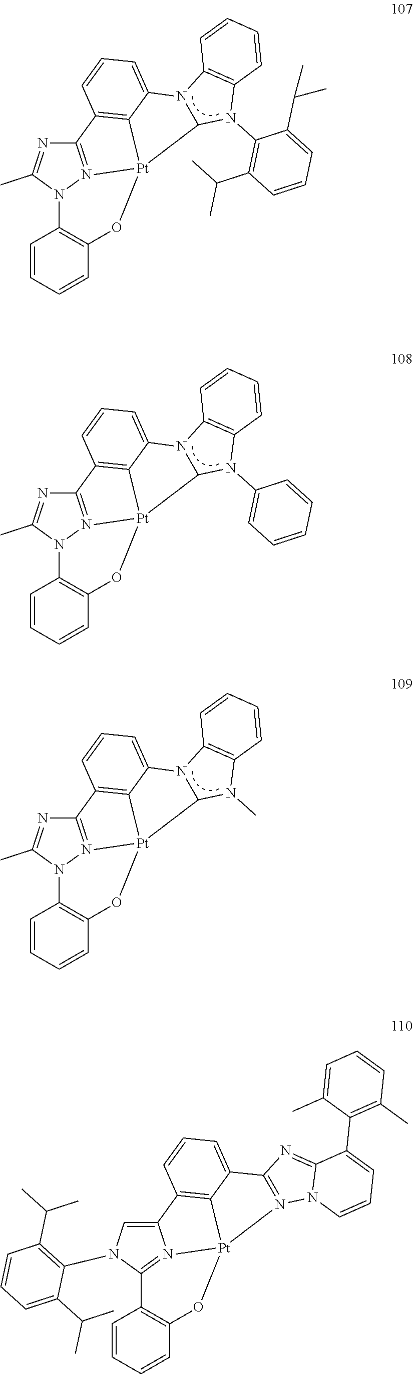

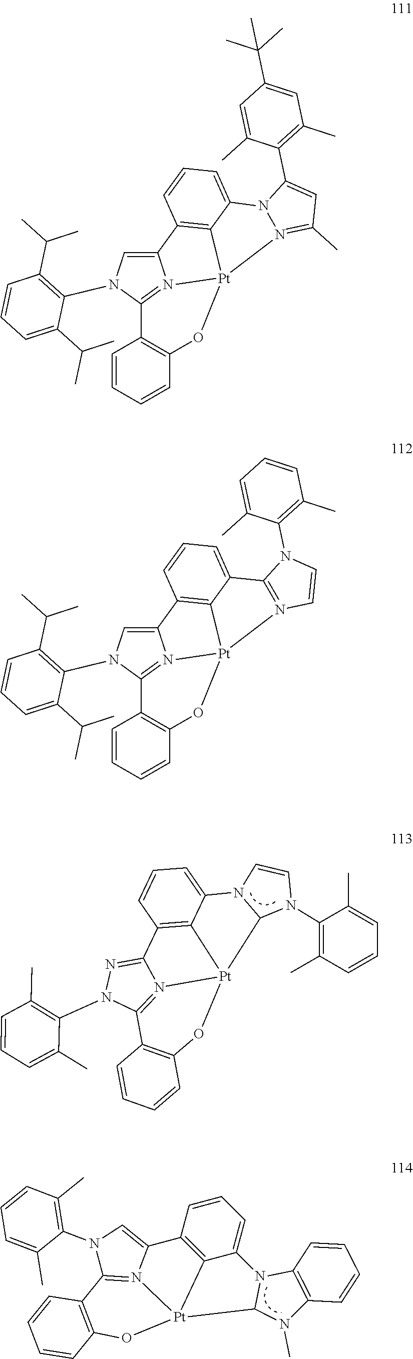

16. An organic light-emitting device comprising:
a first electrode,
a second electrode; and
an organic layer located between the first electrode and the second electrode and comprising an emission layer,
wherein the organic layer comprises at least one organometallic compound of claim 1.

17. The organic light-emitting device of claim 16, wherein the first electrode is an anode,
the second electrode is a cathode,
the organic layer further comprises a hole transport region between the first electrode and the emission layer and an electron transport region between the emission layer and the second electrode,
the hole transport region comprises a hole injection layer, a hole transport layer, an electron blocking layer, or any combination thereof, and
the electron transport region comprises a hole blocking layer, an electron transport layer, an electron injection layer, or any combination thereof.

18. The organic light-emitting device of claim 16, wherein the organometallic compound is included in the emission layer.

19. The organic light-emitting device of claim 18, wherein the emission layer emits blue light.

20. A diagnostic composition comprising at least one organometallic compound of claim 1.
